(19) United States
(12) Patent Application Publication
(10) Pub. No.: US 2016/0035865 A1
(43) Pub. Date: Feb. 4, 2016

(54) METHOD OF MANUFACTURING SEMICONDUCTOR DEVICE

(71) Applicant: Semiconductor Energy Laboratory Co., Ltd., Atsugi-shi (JP)

(72) Inventors: Sho NAGAMATSU, Isehara (JP); Tomoaki MORIWAKA, Isehara (JP)

(21) Appl. No.: 14/804,932

(22) Filed: Jul. 21, 2015

(30) Foreign Application Priority Data
Jul. 31, 2014 (JP) 2014-156746

(51) Int. Cl. H01L 29/66; H01L 21/4763; H01L 27/12; H01L 29/786; H01L 21/02

(52) U.S. Cl. CPC H01L 29/66969; H01L 29/7869; H01L 29/78603; H01L 21/02178; H01L 21/02164; H01L 27/1207; H01L 21/47635; H01L 29/66568

(57) ABSTRACT

A first conductor is formed over a substrate. A first insulator is formed over the first conductor. A second insulator including aluminum oxide is formed over the first insulator. A third insulator is formed in contact with a top surface of the second insulator. A first opening portion reaching the first conductor is provided in the first to third insulators. A second conductor is formed over the third insulator and in the first opening portion. A third conductor is formed in the first opening portion by removing part of the second conductor over the third insulator so that a surface of the third conductor is parallel to a bottom surface of the substrate. A first transistor including an oxide semiconductor is formed over the third insulator.

### TECHNICAL FIELD

The present invention relates to an object, a method, or a manufacturing method. Furthermore, the present invention relates to a process, a machine, manufacture, or a composition of matter. In particular, the present invention relates to, for example, a semiconductor, a semiconductor device, a display device, a light-emitting device, a lighting device, a power storage device, a mirror image device, a memory device, or a processor. The present invention relates to a method of manufacturing a semiconductor, a semiconductor device, a display device, a light-emitting device, a lighting device, a power storage device, a mirror image device, a memory device, or a processor. The present invention relates to a method of driving a semiconductor device, a display device, a light-emitting device, a lighting device, a power storage device, a mirror image device, a memory device, or a processor.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

### BACKGROUND ART

A technique in which a transistor is formed using a semiconductor material has attracted attention. The transistor is applied to a wide range of electronic devices such as an integrated circuit (IC) or an image display device (also simply referred to as a display device). As semiconductor materials applicable to the transistor, silicon-based semiconductor materials have been widely used, but oxide semiconductors have been attracting attention as alternative materials.

In recent years, demand for integrated circuits in which semiconductor elements such as miniaturized transistors are integrated with high density has risen with increased performance and reductions in the size and weight of electronic appliances.

A transistor including an oxide semiconductor is known to have an extremely low leakage current in an off state. For example, a low-power-consumption CPU utilizing the low leakage current of the transistor including an oxide semiconductor is disclosed (see Patent Document 1).

### REFERENCE

### [Patent Document]

Patent Document 1: Japanese Published Patent Application No. 2012-257187

### DISCLOSURE OF INVENTION

An object is to provide a method of forming a wiring having excellent electrical characteristics. Another object is to provide a method of forming a wiring having stable electrical characteristics. Another object is to provide a method of embedding a conductor into an insulator containing aluminum oxide.

Another object is to provide a method of manufacturing a semiconductor device having excellent electrical characteristics. Another object is to provide a method of manufacturing a semiconductor device having stable electrical characteristics. Another object is to provide a method of manufacturing a highly reliable semiconductor device. Another object is to provide a method of manufacturing a semiconductor device with a high yield.

Another object is to provide a method of manufacturing a semiconductor device including a transistor having stable electrical characteristics. Another object is to provide a method of manufacturing a semiconductor device including a transistor with a low off-state current. Another object is to provide a method of manufacturing a durable semiconductor device. Another object is to provide a method of manufacturing a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

### Means for Solving the Problems

One embodiment of the present invention is a method of manufacturing a semiconductor device, which includes the steps of forming a first conductor over a substrate, forming a first insulator over the first conductor, forming a second insulator comprising aluminum oxide over the first insulator, forming a third insulator in contact with a top surface of the second insulator, providing an opening portion reaching the first conductor in the first insulator, the second insulator and the third insulator, forming a second conductor over the third insulator and in the opening portion, forming a third conductor in the opening portion by removing part of the second conductor so that an upper surface of the third conductor is parallel to a bottom surface of the substrate, and forming a first transistor comprising an oxide semiconductor over the third insulator.

In the above structure, preferably, the third insulator has a crystalline structure. In addition, preferably, a chemical mechanical polishing method is used for the removal of part of the second conductor.

The removal of the second conductor such that the upper surface of the third conductor is parallel to the bottom surface of the substrate means removal performed while planarizing the second conductor, for example. For example, the removal may be performed such that the surface of the third conductor is “substantially parallel to” the bottom surface of the substrate. Furthermore, the third conductor preferably fills the first opening portion.

Another embodiment of the present invention is a method of manufacturing a semiconductor device, which includes the steps of forming a first transistor comprising an oxide semiconductor over a substrate, forming a first insulator over the first transistor, forming a second insulator comprising aluminum oxide over the first insulator, forming a third insulator in contact with a top surface of the second insulator, providing an opening portion in the first insulator, the second insulator, and the third insulator, forming a second conductor over the third insulator and in the opening portion, forming a third conductor in the opening portion by removing part of the second conductor over the third insulator so that an upper surface of the third conductor is parallel to a bottom surface of the substrate, and forming a fourth conductor over the third insulator. In addition, preferably, a chemical mechanical polishing method is used for the removal of the second conductor.

Another embodiment of the present invention is a method of manufacturing a semiconductor device, which includes the steps of forming a second transistor over a substrate, forming a first insulator over the second transistor, forming a second insulator comprising aluminum oxide over the first insulator, forming a third insulator in contact with a top surface of the second insulator, providing an opening portion in the first insulator, the second insulator, and the third insulator, forming a second conductor over the third insulator and in the opening portion, forming a third conductor in the opening portion by removing part of the first conductor over the third insulator so that an upper surface of the third conductor is parallel to a bottom surface of the substrate, and forming a first transistor comprising an oxide semiconductor over the third insulator. In any of the above structures, the second transistor preferably comprises silicon. In addition, preferably, a chemical mechanical polishing method is used for the removal of the second conductor.

In any of the above structures, preferably, the third insulator comprises aluminum oxide, and a density of the third insulator is higher than a density of the second insulator. In any of the above structures, preferably, the third insulator comprises aluminum oxide, and the third insulator comprises crystallinity.

In any of the above structures, preferably, the second insulator comprises an amorphous structure.

In any of the above structures, preferably, a density of the second insulator is greater than or equal to 2.5 g/cm³ and less than 3.2 g/cm³.

In any of the above structures, preferably, the third insulator comprises silicon oxide.

A method of forming a wiring having excellent electrical characteristics can be provided. A method of forming a wiring having stable electrical characteristics can be provided. A method of embedding a conductor into an insulator containing aluminum oxide can be provided.

A method of manufacturing a semiconductor device having excellent electrical characteristics can be provided. A method of manufacturing a semiconductor device having stable electrical characteristics can be provided. A method of manufacturing a highly reliable semiconductor device can be provided. A method of manufacturing a semiconductor device with a high yield can be provided.

A method of manufacturing a semiconductor device including a transistor having stable electrical characteristics can be provided. A method of manufacturing a semiconductor device including a transistor with a low off-state current can be provided. A method of manufacturing a durable semiconductor device can be provided. A method of manufacturing a novel semiconductor device can be provided.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF DRAWINGS

In the accompanying drawings:

FIG. 1 is a cross-sectional view illustrating a semiconductor device according to one embodiment of the present invention;

FIG. 2 is a cross-sectional view illustrating a semiconductor device according to one embodiment of the present invention;

FIG. 3 is a cross-sectional view illustrating a semiconductor device according to one embodiment of the present invention;

FIGS. 4A to 4E illustrate a method of forming a wiring according to one embodiment of the present invention;

FIGS. 5A to 5C are cross-sectional views illustrating a method of manufacturing a semiconductor device according to one embodiment of the present invention;

FIGS. 6A to 6C are cross-sectional views illustrating a method of manufacturing a semiconductor device according to one embodiment of the present invention;

FIGS. 7A to 7C are cross-sectional views illustrating a method of manufacturing a semiconductor device according to one embodiment of the present invention;

FIGS. 8A and 8B are cross-sectional views illustrating a method of manufacturing a semiconductor device according to one embodiment of the present invention;

FIGS. 9A and 9B are a top view and a cross-sectional view which illustrate a transistor according to one embodiment of the present invention;

FIGS. 10A and 10B are a top view and a cross-sectional view which illustrate a transistor according to one embodiment of the present invention;

FIGS. 11A and 11B are a top view and a cross-sectional view which illustrate a transistor according to one embodiment of the present invention;

FIGS. 12A and 12B are a top view and a cross-sectional view which illustrate a transistor according to one embodiment of the present invention;

FIGS. 13A to 13C are cross-sectional views each illustrating a transistor according to one embodiment of the present invention;

FIGS. 14A and 14B are a top view and a cross-sectional view which illustrate a transistor according to one embodiment of the present invention;

FIGS. 15A and 15B are a top view and a cross-sectional view which illustrate a transistor according to one embodiment of the present invention;

FIGS. 16A and 16B are cross-sectional views each illustrating a transistor according to one embodiment of the present invention;

FIGS. 17A and 17B are a top view and a cross-sectional view which illustrate a transistor according to one embodiment of the present invention;

FIGS. 18A and 18B are a top view and a cross-sectional view which illustrate a transistor according to one embodiment of the present invention;

FIGS. 19A and 19B are cross-sectional views illustrating a method of manufacturing a transistor according to one embodiment of the present invention;

FIGS. 20A and 20B are cross-sectional views illustrating a method of manufacturing the transistor according to one embodiment of the present invention;

FIGS. 21A, 21B, 21C1, and 21C2 are cross-sectional views illustrating a method of manufacturing the transistor according to one embodiment of the present invention;

FIGS. 22A and 22B are a top view and a cross-sectional view which illustrate a transistor according to one embodiment of the present invention;

FIGS. 23A and 23B are a top view and a cross-sectional view which illustrate a transistor according to one embodiment of the present invention;

FIGS. 24A and 24B are cross-sectional views each illustrating a transistor according to one embodiment of the present invention;

FIGS. 25A to 25C are a cross-sectional view of stacked semiconductor layers and diagrams of a band structure;

FIG. 26 is a cross-sectional view illustrating a semiconductor device according to one embodiment of the present invention;

FIG. 27 is a cross-sectional view illustrating a semiconductor device according to one embodiment of the present invention;

FIG. 28 is a cross-sectional view illustrating a semiconductor device according to one embodiment of the present invention;

FIG. 29 is a cross-sectional view illustrating a semiconductor device according to one embodiment of the present invention;

FIGS. 30A and 30B are each a circuit diagram of a semiconductor device according to one embodiment of the present invention;

FIGS. 31A and 31B are each a circuit diagram of a memory device according to one embodiment of the present invention;

FIG. 32 is a block diagram of an RF tag according to one embodiment of the present invention;

FIGS. 33A to 33F illustrate application examples of an RF tag according to one embodiment of the present invention;

FIG. 34 is a block diagram illustrating a CPU according to one embodiment of the present invention;

FIG. 35 is a circuit diagram of a memory element according to one embodiment of the present invention;

FIGS. 36A to 36C are a top view and circuit diagrams of a display device according to one embodiment of the present invention;

FIG. 37 illustrates a display module according to one embodiment of the present invention;

FIGS. 38A to 38F each illustrate an electronic device according to one embodiment of the present invention;

FIGS. 39A1, 39A2, 39A3, 39B1, 39B2, 39C1, and 39C2 each illustrate an electronic device according to one embodiment of the present invention; and

FIGS. 40A and 40B are cross-sectional TEM images according to one embodiment of the present invention.

### BEST MODE FOR CARRYING OUT THE INVENTION

Hereinafter, embodiments of the present invention will be described in detail with reference to the drawings. However, the present invention is not limited to the description below, and it is easily understood by those skilled in the art that modes and details disclosed herein can be modified in various ways. Furthermore, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in diagrams may be exaggerated for clarity.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

The term voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for the sake of convenience and do not denote the order of steps or the stacking order of layers. Therefore, for example, the term “first” can be replaced with the term “second”, “third”, or the like as appropriate. In addition, the ordinal numbers in this specification and the like are not necessarily the same as the ordinal numbers used to specify one embodiment of the present invention.

Note that a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Furthermore, a “semiconductor” includes characteristics of a “conductor” in some cases when the conductivity is sufficiently high, for example. Furthermore, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. When the semiconductor is an oxide semiconductor, examples of an impurity which changes the characteristics of the semiconductor include Group 1 elements, Group 2 elements, Group 14 elements, Group 15 elements, and transition metals other than the main components; specifically, there are hydrogen (including water), lithium, sodium, silicon, boron, phosphorus, carbon, and nitrogen, for example. When the semiconductor is an oxide semiconductor, oxygen vacancies may be formed by entry of impurities such as hydrogen, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

Note that in the embodiments described below, an insulator may be formed to have, for example, a single-layer structure or a stacked-layer structure including an insulator containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum unless otherwise specified. A resin may be used as the insulator. For example, a resin containing polyimide, polyamide, acrylic, silicone, or the like may be used. The use of a resin does not need planarization treatment performed on a top surface of the insulator in some cases. By using a resin, a thick film can be formed in a short time; thus, the productivity can be increased. The insulator may be preferably formed to have a single-layer structure or a stacked-layer structure including an insulator containing aluminum oxide, silicon nitride oxide, silicon nitride, gallium oxide, yttrium oxide, zirconium oxide, lanthanum oxide, neodymium oxide, hafnium oxide, or tantalum oxide.

Furthermore, in the embodiments described below, a conductor may be formed to have, for example, a single-layer structure or a stacked-layer structure including a conductor containing one or more of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten unless otherwise specified. For example, an alloy or a compound containing the above element may be used: a conductor containing aluminum, a conductor containing copper and titanium, a conductor containing copper and manganese, a conductor containing indium, tin, and oxygen, a conductor containing titanium and nitrogen, or the like may be used.

In this specification, the phrase “A has a region with a concentration B” includes, for example, the case where the concentration of the whole of a region of A in the depth direction is B, the case where the average concentration in a region of A in the depth direction is B, the case where the median value of a concentration in a region of A in the depth direction is B, the case where the maximum value of a concentration in a region of A in the depth direction is B, the case where the minimum value of a concentration in a region of A in the depth direction is B, the case where a convergence value of a concentration in a region of A in the depth direction is B, and the case where a concentration in a region in which a probable value of A is obtained in measurement is B.

In this specification, the phrase “A has a region with a size B, a length B, a thickness B, a width B, or a distance B” includes, for example, the case where the whole of a region of A has a size B, a length B, a thickness B, a width B, or a distance B, the case where the average value in a region of A has a size B, a length B, a thickness B, a width B, or a distance B, the case where the median value in a region of A has a size B, a length B, a thickness B, a width B, or a distance B, the case where the maximum value in a region of A has a size B, a length B, a thickness B, a width B, or a distance B, the case where the minimum value in a region of A has a size B, a length B, a thickness B, a width B, or a distance B, the case where a convergence value in a region of A has a size B, a length B, a thickness B, a width B, or a distance B, and the case where a region in which a probable value of A is obtained in measurement has a size B, a length B, a thickness B, a width B, or a distance B″.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

### Embodiment 1

In this embodiment, a method of forming a conductor connecting a plurality of wiring layers is described.

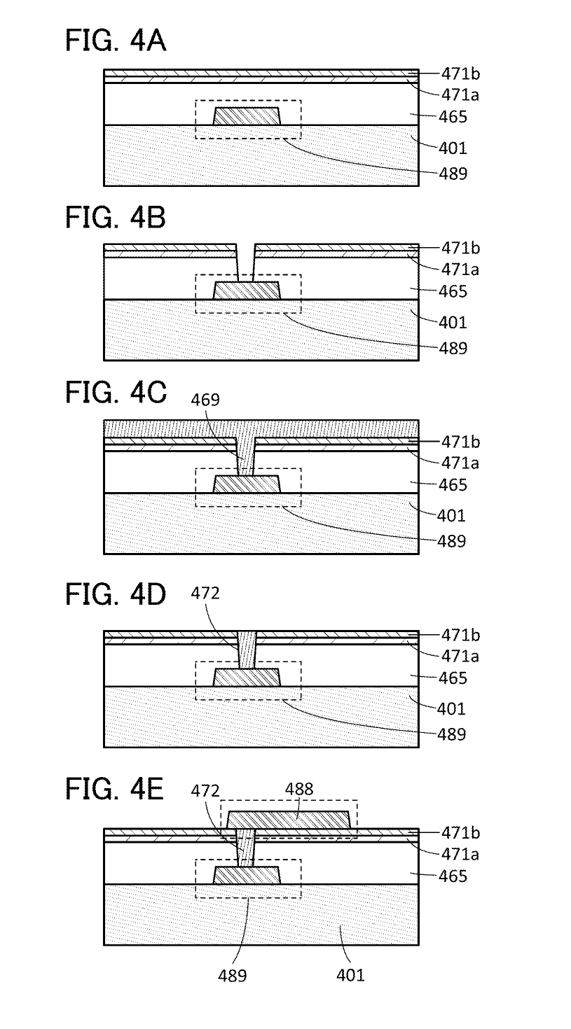

A cross-sectional view of the conductor connecting a plurality of wiring layers is illustrated in FIG. 4E. A structure illustrated in FIG. 4E includes a wiring layer 489 over a substrate 401, an insulator 465 provided over the wiring layer 489 and the substrate, an insulator 471a over the insulator 465, an insulator 471b over the insulator 471a, a conductor 472 embedded in the insulators 465, 471a, and 471b, and a wiring layer 488 over the conductor 472 and the insulator 471b. The conductor 472 has a function of electrically connecting the wiring layer 489 and the wiring layer 488.

Although not illustrated in FIG. 4E, an element or a circuit connected to the wiring layer 489 may be provided between the substrate 401 and the wiring layer 489. Examples of the element are a resistor, a capacitor, a transistor, a sensor, and the like. Examples of the circuit are a circuit including two or more of such elements and the like.

Although not illustrated in FIG. 4E, an element or a circuit connected to the wiring layer 488 may be provided over the wiring layer 488. Examples of the element are a resistor, a capacitor, a transistor, a sensor, and the like. Examples of the circuit are a circuit including two or more of such elements and the like.

The insulator 471b preferably functions as a stopper film during a step of removing a conductor 469 which is described later.

In the structure illustrated in FIG. 4E, between the wiring layers 488 and 489, an insulator having a function of blocking hydrogen, oxygen, and the like is preferably provided. An example of the insulator having a function of blocking hydrogen, oxygen, and the like is aluminum oxide. Aluminum oxide can be used as the insulator 471a or the insulator 471b, for example.

In the case where aluminum oxide is used as the insulator 471b, the insulator 471a might be omitted.

Preferably, aluminum oxide is used as the insulator 471a and the insulator 471b functioning as a stopper film is provided over the insulator 471a, in which case the function of blocking hydrogen and oxygen might be improved and the structure might be easy to process. Details are described below.

The insulator 471a preferably contains aluminum oxide. Aluminum oxide has a function of blocking hydrogen, oxygen, and the like and might have a function of blocking an impurity contained in the substrate 401 or the like.

Hydrogen, oxygen, an impurity contained in the substrate 401 or the like, and the like might adversely affect characteristics of the above-described elements, for example.

The use of an insulator containing aluminum oxide as the insulator 471a can reduce the arrival of an impurity contained in the substrate or the like, for example, at the wiring layer 488 formed over the insulator 471a or the element or circuit connected to the wiring layer 488, for example. Such use can also reduce the arrival of oxygen or hydrogen at the wiring layer 488 or the element or circuit connected to the wiring layer 488 from the wiring layer 489 or an element or a circuit connected to the wiring layer 489, for example. Consequently, characteristics of the element or the circuit might be less degraded and made excellent, for example.

Furthermore, the arrival of oxygen or hydrogen at the wiring layer 489 or the element or circuit connected to the wiring layer 489 from the wiring layer 488 or the element or circuit connected the wiring layer 488 can be reduced. Consequently, characteristics of the element or the circuit might be less degraded and made excellent, for example.

As the substrate 401, an SOI substrate, a glass substrate, a quartz substrate, a plastic substrate, a metal substrate, a stainless steel substrate, a substrate containing stainless steel foil, a tungsten substrate, a substrate containing tungsten foil, a flexible substrate, an attachment film, paper containing a fibrous material, a base film, or the like can be used. Alternatively, for the substrate 401, a single-material semiconductor of silicon, germanium, or the like or a compound semiconductor of silicon carbide, silicon germanium, gallium arsenide, gallium nitride, indium phosphide, zinc oxide, gallium oxide, or the like may be used, for example. For the substrate 401, an amorphous semiconductor or a crystalline semiconductor can be used, and examples of a crystalline semiconductor include a single crystal semiconductor, a polycrystalline semiconductor, and a microcrystalline semiconductor.

As the insulator 471a, for example, a single layer or stacked layers of aluminum oxide, aluminum oxynitride, gallium oxide, gallium oxynitride, yttrium oxide, yttrium oxynitride, hafnium oxide, hafnium oxynitride, tantalum oxide, zirconium oxide, lead zirconate titanate (PZT), strontium titanate (SrTiO₃), (Ba, Sr)TiO₃ (BST), or the like can be used. Alternatively, an insulating film of any of such materials may be subjected to nitriding treatment to be an oxynitride film. Aluminum oxide is particularly preferable because of its excellent barrier property against water, hydrogen, and oxygen.

The case of using aluminum oxide as the insulator 471a is described. The aluminum oxide without clear grain boundaries might have higher capability to block hydrogen and the like than the aluminum oxide having crystallinity. This is because, in the aluminum oxide having crystallinity, hydrogen and the like are probably likely to diffuse through grain boundaries. Examples of the aluminum oxide without clear grain boundaries are aluminum oxide having an amorphous structure and the like. Thus, preferably, aluminum oxide is used as the insulator 471a and the aluminum oxide has an amorphous structure, for example. Further, the aluminum oxide preferably has no clear grain boundaries, for example. In the case where the aluminum oxide is used as the insulator 471a, the density of the insulator 471a is preferably greater than or equal to 2.5 g/cm³ and less than 3.2 g/cm³, for example. If the density is too low, for example, the capability to block an impurity might be insufficient. In addition, if the density is too low, control of processing speed or processing shape might be difficult in processing, for example.

As the insulator 471a, for example, the aluminum oxide in which no clear grain boundaries are observed with a transmission electron microscope may be used.

As the insulator 471b, for example, any material that has an insulating property and is difficult to etch during a step of forming the conductor 472 may be used.

As the insulator 471b, for example, aluminum oxide is preferably used. Alternatively, silicon oxide may be used as the insulator 471b.

In the case where aluminum oxide is used as the insulator 471b, the insulator 471b preferably has crystallinity. In the case where aluminum oxide is used as each of the insulators 471a and 471b, the density of the insulator 471b is preferably higher than that of the insulator 471a. For example, the density of the insulator 471b is preferably greater than or equal to 3.2 g/cm³, more preferably greater than or equal to 3.4 g/cm³. As the aluminum oxide having crystallinity, for example, polycrystalline aluminum oxide may be used.

The insulator 471b may have a function of blocking hydrogen and oxygen. Preferably, the insulator 471a has a more excellent function of blocking hydrogen and oxygen than the insulator 471b.

Next, a method of fabricating the conductor connecting the plurality of wiring layers illustrated in FIG. 4E is described.

First, a conductor to be the wiring layer 489 is deposited over the substrate 401 and then etched using a mask or the like to form the wiring layer 489. Then, the insulator 465 is deposited over the substrate 401 and the wiring layer 489. The insulator 471a is then deposited over the insulator 465. The insulator 471b is then deposited over the insulator 471a (see FIG. 4A).

The insulators 471a and 471b can be deposited by a sputtering method, a CVD method (including a thermal CVD method, an MOCVD method, a PECVD method, and the like), an MBE method, an ALD method, a PLD method, or the like, for example.

As the insulator 471a, for example, aluminum oxide is preferably used. The insulator 471a preferably has no clear grain boundaries. Further, the insulator 471a preferably has an amorphous structure. For example, here, the aluminum oxide having an amorphous structure is deposited by an ALD method. In the case of using an ALD method, the aluminum oxide can be deposited, for example, using a source gas obtained by vaporizing a solvent and liquid containing an aluminum precursor compound (e.g., trimethylaluminum (TMA)) and a gas such as ozone or oxygen as an oxidizer. Owing to the use of an ALD method, a thin film can be formed to a thickness preferably less than or equal to 20 nm, more preferably less than or equal to 10 nm, further preferably less than or equal to 5 nm, still further preferably less than or equal to 2 nm, for example, and the thickness can be highly uniform in the plane of a sample.

Alternatively, preferably, no clear crystallinity is observed in the insulator 471a with a transmission electron microscope, for example.

The density of the aluminum oxide having an amorphous structure is lower than that of the aluminum oxide having crystallinity such as polycrystallinity in some cases, in which case the aluminum oxide having an amorphous structure can easily be removed in the step of removing the conductor 469 which is described later. That is, in the step of removing the conductor 469, the insulator 471a might be thinned or eliminated. Therefore, over the insulator 471a, the insulator 471b functioning as a stopper film during the step of processing the conductor 469 is preferably provided. Here, as the insulator 471b, the aluminum oxide having a crystalline structure is formed by a sputtering method, for example. Here, in a sputtering method, for example, use of aluminum oxide as a target and oxygen as a deposition gas might facilitate crystallization of the aluminum oxide.

The stopper film is described here. For example, the case where a second material to be processed is provided over a first material serving as the stopper film is considered. The first material that is processed more slowly than the second material or is not processed during the processing step of the second material is referred to as a stopper film during the processing step of the second material. The stopper film has a function of protecting a material below the stopper film when a material to be provided above the stopper film is processed, for example. The insulator 471b serves as the stopper film during the processing step, a polishing step here, of the conductor 469. The polishing rate of the insulator 471b is preferably less than or equal to one-fifth, more preferably less than or equal to one-tenth, further preferably less than or equal to one-twentieth, still further preferably less than or equal to one-thirtieth of the polishing rate of the conductor 469, for example.

As the insulator 471b, a material containing silicon oxide may be used. Silicon oxide is preferable because it might function as an excellent stopper film during the removal of the conductor 472.

Next, an opening portion is formed in the insulators 465, 471a, and 471b (see FIG. 4B). In the opening portion, preferably, the wiring layer 489 or the like is exposed. To form the opening portion, for example, a mask is formed by a lithography method or the like, an unnecessary portion is removed by dry etching or the like, and then the mask is removed. As the mask, a hard mask formed of an inorganic film or a metal film may be used.

To remove the aluminum oxide, for example, a gas such as boron trichloride is used.

Here, in the case where the aluminum oxide used as the insulator 471a is removed by dry etching, for example, the etching rate thereof might be lower than that of other insulators such as silicon oxide or silicon oxynitride. The low etching rate allows the mask to recede in the etching step, which might increase the area of the opening portion and result in reduced integration of the semiconductor device.

Therefore, when the aluminum oxide is used as the insulator 471a, its thickness is preferably small. For example, the thickness of the insulator 471a is preferably less than or equal to one-third, more preferably less than or equal to one-fifth, more preferably less than or equal to one-tenth, further preferably less than or equal to one-fiftieth, still further preferably less than or equal to one-hundredth of the thickness of the insulator 465.

Furthermore, when the aluminum oxide is used as the insulator 471b, its thickness is preferably small. For example, the thickness of the insulator 471b is preferably less than or equal to one-third, more preferably less than or equal to one-fifth, more preferably less than or equal to one-tenth, further preferably less than or equal to one-fiftieth, still further preferably less than or equal to one-hundredth of the thickness of the insulator 465.

Next, the conductor 469 is deposited in the opening portion and over the insulator 471b (see FIG. 4C). As the conductor 469, a metal selected from tantalum, tungsten, titanium, molybdenum, chromium, niobium, and the like, or an alloy material or a compound material including any of the metals as its main component is preferably used. Alternatively, polycrystalline silicon to which an impurity such as phosphorus is added can be used. Still alternatively, a stacked-layer structure including a metal nitride film and a film of any of the above metals may be used. As the metal nitride, tungsten nitride, molybdenum nitride, or titanium nitride can be used. The metal nitride film can increase adhesiveness of the metal film and prevent separation.

The conductor 469 can be deposited by a sputtering method, an evaporation method, a CVD method, an MBE method, or the like. A thermal CVD method, an MOCVD method, or an ALD method is preferably used to reduce plasma damage.

Next, part of the conductor 469 is removed to form the conductor 472 with an upper surface parallel to a bottom surface of the substrate 401, or the surface of the conductor 469 is planarized and removed, whereby part of the conductor 469 is left in the opening portion; thus, the conductor 472 and the like are formed (see FIG. 4D). The conductor 469 is preferably removed so as to expose the insulator 471b, for example. For the removal of the conductor 469, a polishing method such as a chemical mechanical polishing (CMP) method is preferably used. When a polishing method such as a CMP method is used, the polishing rate of the conductor 469 might have a distribution in the plane of a sample. In this case, in a region where the polishing rate is high, a period during which the insulator 471b is exposed might be long. The polishing rate of the insulator 471b is preferably lower than that of the conductor 469. The low polishing rate of the insulator 471b allows it to serve as a polishing stopper film during the polishing step of the conductor 469, and further can increase the planarity of a surface of the insulator 471b.

Here, the CMP method is a method in which a surface of an object to be processed is planarized by a combination of chemical and mechanical actions. Specifically, a polishing cloth is attached to a polishing stage, the polishing stage and the object to be processed are each rotated or swung while slurry (abrasives) is supplied between the object to be processed and the polishing cloth, and the surface of the object to be processed is polished by chemical reaction between the slurry and the surface of the object to be processed and by action of mechanical polishing of the object to be processed with the polishing cloth.

As the polishing cloth for the CMP method, for example, polyurethane foam, nonwoven fabric, suede, or the like can be used. As abrasive particles, for example, silica (silicon oxide), cerium oxide, manganese oxide, aluminum oxide, or the like can be used. As silica, for example, fumed silica or colloidal silica can be used.

The pH of the slurry used for the CMP method may be adjusted in view of removability of the object to be processed or stability of the slurry solution. For example, in the case where acidic slurry is used, the insulator 471b serving as the stopper film preferably has high resistance to acid. Alternatively, in the case where alkaline slurry is used, the insulator 471b preferably has high resistance to alkali.

As an oxidizer in the slurry, for example, hydrogen peroxide or the like may be used.

Here, an example of the case where the conductor 469 contains tungsten is described. In the slurry, fumed silica or colloidal silica, for example, is preferably used as the abrasive particles. For example, acidic slurry is preferably used, and, for example, aqueous hydrogen peroxide is preferably used as an oxidizer.

Next, a conductor to be the wiring layer 488 is formed over the insulator 471b, the conductor 472, and the like. Next, a mask is formed over the conductor by a photolithography method or the like.

Here, a method of processing a film to be processed into the conductor and the like is described. In the case of finely processing the film to be processed, a variety of fine processing techniques can be used. For example, a method in which a resist mask formed by a photolithography process or the like is subjected to slimming treatment may be used. Alternatively, a method may be used in which a dummy pattern is formed by a photolithography process or the like, the dummy pattern is provided with a sidewall and is then removed, and the film to be processed is etched using the remaining sidewall as a resist mask. In order to obtain a high aspect ratio, anisotropic dry etching is preferably used for etching of the film to be processed. Alternatively, a hard mask formed of an inorganic film or a metal film may be used.

As light used to form the resist mask, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Exposure may be performed by liquid immersion exposure technique. As the light for the exposure, extreme ultra-violet light (EUV) or X-rays may be used. Instead of the light for the exposure, an electron beam can be used. It is preferable to use extreme ultra-violet light (EUV), X-rays, or an electron beam because extremely fine processing can be performed. Note that in the case of performing exposure by scanning of a beam such as an electron beam, a photomask is not needed.

An organic resin film having a function of improving adhesion between the film to be processed and a resist film may be formed before the resist film serving as a resist mask is formed. The organic resin film can be formed to planarize a surface by covering a step under the film by a spin coating method or the like, and thus can reduce variation in the thickness of the resist mask over the organic resin film. In the case of fine processing, in particular, a material serving as a film having a function of preventing reflection of light for the exposure is preferably used for the organic resin film. Examples of the organic resin film having such a function include a bottom anti-reflection coating (BARC) film. The organic resin film may be removed at the same time as the removal of the resist mask or after the removal of the resist mask.

The surface of the insulator 471b and surfaces of the conductor 472 and the like embedded in the insulators 465, 471a, and 471b preferably have planarity. The planarity of the surface of the insulator 471b and the surfaces of the conductor 472 and the like makes a conductor to be the wiring layer 488 have high planarity. When the mask is formed over the conductor, the planarity of the surface of the conductor can reduce variation of light exposure or the like, for example, so that a finer pattern can be easily formed. For example, as the planarity of the surface of the insulator 471b, the average surface roughness (Ra) is preferably less than or equal to 5 nm, more preferably less than or equal to 2 nm, further preferably less than or equal to 1 nm, still further preferably less than or equal to 0.5 nm, further preferably less than or equal to 0.3 nm when measured with an atomic force microscope (AFM).

An unnecessary portion of the conductor to be the wiring layer 488 is removed, and the mask is removed, whereby the wiring layer 488 is formed. Thus, the structure whose cross section is illustrated in FIG. 4E can be formed.

At least part of this embodiment can be implemented in combination with any of the embodiments described in this specification as appropriate.

### Embodiment 2

In this embodiment, a semiconductor device of one embodiment of the present invention is described.

### <Structure of Semiconductor Device>

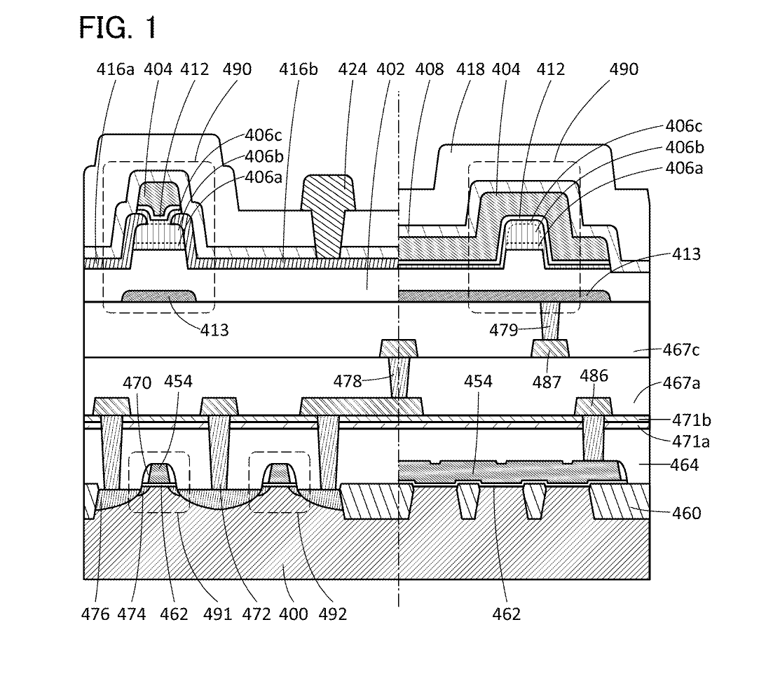

FIG. 1 is a cross-sectional view of the semiconductor device of one embodiment of the present invention. FIG. 1 shows different cross sections on the left side and the right side of the dashed-dotted line.

The semiconductor device illustrated in FIG. 1 includes a transistor 491, the insulator 464 over the transistor 491, the insulator 471a over the insulator 464, the insulator 471b over the insulator 471a, and a transistor 490 over the insulator 471b. The insulator 471a has a function of blocking oxygen and hydrogen.

The transistor 491 includes an insulator 462 over the semiconductor substrate 400, a conductor 454 over the insulator 462, an insulator 470 in contact with a side surface of the conductor 454, a region 476 which is positioned in the semiconductor substrate 400 and does not overlap with the conductor 454 and the insulator 470, and a region 474 which overlaps with the insulator 470.

The semiconductor device includes an insulator 467a over the insulator 471b and an insulator 467c over the insulator 467a. Over the insulator 467c, the transistor 490 is provided. Preferably, the conductor 472 fills an opening portion in the insulators 464, 471a and 471b; a conductor 478 fills an opening portion in the insulator 467a; and a conductor 479 fills an opening portion in the insulator 467c.

For the semiconductor substrate 400, a single-material semiconductor of silicon, germanium, or the like or a compound semiconductor of silicon carbide, silicon germanium, gallium arsenide, gallium nitride, indium phosphide, zinc oxide, gallium oxide, or the like may be used, for example. For the semiconductor substrate 400, an amorphous semiconductor or a crystalline semiconductor may be used, and examples of a crystalline semiconductor include a single crystal semiconductor, a polycrystalline semiconductor, and a microcrystalline semiconductor.

The insulator 462 serves as a gate insulator of the transistor 491. The conductor 454 serves as a gate electrode of the transistor 491. The insulator 470 serves as a sidewall insulator (also referred to as a sidewall) of the conductor 454. The region 476 serves as a source region or a drain region of the transistor 491. The region 474 serves as a lightly doped drain (LDD) region of the transistor 491.

The region 474 can be formed by adding an impurity using the conductor 454 as a mask. After that, the insulator 470 is formed and an impurity is added using the conductor 454 and the insulator 470 as masks, so that the region 476 can be formed. Thus, when the region 474 and the region 476 are formed using the same kind of impurities, the region 474 has a lower impurity concentration than the region 476.

When the transistor 491 includes the region 474, a short-channel effect can be suppressed. Therefore, such a structure is suitable for miniaturization.

The transistor 491 is kept away from another transistor provided in the semiconductor substrate 400 by an insulator 460 or the like. Although FIG. 1 illustrates an example where the insulator 460 is formed by a shallow trench isolation (STI) method, one embodiment of the present invention is not limited thereto. For example, instead of the insulator 460, an insulator formed by a local oxidation of silicon (LOCOS) method may be used so that the transistors are separated from each other.

FIG. 1 illustrates an example where the transistor 492 having the same conductivity type as the transistor 491 is provided to be adjacent to the transistor 491. Furthermore, in FIG. 1, the transistor 491 and the transistor 492 are electrically connected to each other through the region 476. Note that the transistor 491 and the transistor 492 may have different conductivity types. In that case, the transistors 491 and 492 are separated from each other by the insulator 460, the transistors 491 and 492 differ from each other in the kinds of impurities contained in the region 474 and the region 476, and well regions having different conductivity types are formed in part of a region of the semiconductor substrate 400 over which the conductor serving as one or both of gate electrodes of the transistors 491 and 492.

When the transistors 491 and 492 have different conductivity types, a complementary metal oxide semiconductor (CMOS) can be formed. With a CMOS, power consumption of the semiconductor device can be reduced. Furthermore, operation speed can be increased.

The insulators 471a and 471b illustrated in FIG. 1 are provided between the transistors 491 and 492 etc. and the transistor 490 etc. The insulators 471a and 471b are stacked, and the insulator 471b is in contact with a top surface of the insulator 471a.

The insulator 471a preferably has a function of blocking hydrogen, oxygen, and the like. The insulator 471a may further have a function of blocking an impurity. For the insulator 471a, refer to the description of the insulator 471a in Embodiment 1.

For example, in the case where the transistors 491 and the 492 are silicon transistors, electrical characteristics of the transistors may be improved because dangling bonds of silicon can be reduced by supplying hydrogen from the outside. The supply of hydrogen may be performed by heat treatment under an atmosphere containing hydrogen, for example. Alternatively, for example, an insulator containing hydrogen is provided in the vicinity of the transistors 491 and 492 and heat treatment is performed, so that the hydrogen may be diffused and supplied to the transistors 491 and 492. Specifically, the insulator 464 over the transistors 491 and 492 is preferably an insulator containing hydrogen. For the insulator 464, for example, silicon oxide, silicon oxynitride, silicon nitride oxide, silicon nitride, or the like can be used. Note that the insulator 464 may have a single-layer structure or a stacked-layer structure. For example, a stacked-layer structure including silicon oxynitride or silicon oxide, and silicon nitride oxide or silicon nitride may be used.

An insulator containing hydrogen may release hydrogen, the amount of which is larger than or equal to 1×10¹⁸ atoms/cm³, larger than or equal to 1×10¹⁹ atoms/cm³, or larger than or equal to 1×10²⁰ atoms/cm³ in TDS analysis (converted into the number of hydrogen atoms) in the range of a surface temperature of 100° C. to 700° C. or 100° C. to 500° C.

Hydrogen diffused from the insulator 464 might reach the vicinity of the transistor 490 through the conductor 472 in the opening portion in the insulator 464, a conductor 486 over the insulator 464, the conductor 478, a conductor 487, the conductor 479, or the like; however, since the insulator 471a has a function of blocking hydrogen, the amount of hydrogen which reaches the transistor 490 is small. Hydrogen serves as a carrier trap or a carrier generation source in an oxide semiconductor and causes deterioration of electrical characteristics of the transistor 490 in some cases. Therefore, blocking hydrogen by the insulator 471a is important to improve performance and reliability of the semiconductor device. Note that the conductor filling the opening portion, e.g., the conductor 472, has a function of electrically connecting elements such as transistors and capacitors.

On the other hand, for example, by supplying oxygen to the transistor 490 from the outside, oxygen vacancies in the oxide semiconductor can be reduced; thus, electrical characteristics of the transistor are improved in some cases. The supply of oxygen may be performed by heat treatment under an atmosphere containing oxygen, for example. Alternatively, for example, an insulator containing excess oxygen (oxygen) is provided in the vicinity of the transistor 490 and heat treatment is performed, so that the oxygen may be diffused and supplied to the transistor 490. Here, as the insulator 402 of the transistor 490, an insulator containing excess oxygen is used.

Diffused oxygen might reach the transistors 491 and 492 through layers; however, since the insulator 471a has a function of blocking oxygen, the amount of oxygen which reaches the transistors 491 and 492 is small. In the case where the transistors 491 and 492 are silicon transistors, entry of oxygen into silicon might be a factor of decreasing crystallinity of silicon or inhibiting carrier movement. Therefore, blocking oxygen by the insulator 471a is important to improve performance and reliability of the semiconductor device.

Conductors such as the conductor 472 are embedded in the insulators 464, 471a, and 471b. An example of a formation method of the conductors such as the conductor 472 is described. First, the opening portion is formed in the insulators 464, 471a, and 471b. Next, the conductor 469 to be the conductor 472 and the like is deposited in the opening portion and over the insulator 471b, and then removed to form the conductor 472 with an upper surface parallel to the substrate, here the bottom surface of the semiconductor substrate 400. Thus, the insulator 471b is exposed, and the conductor 472 and the like are formed. As described in Embodiment 1, the insulator 471b preferably functions as the stopper film when the conductor 472 is formed.

As the insulator 471b, any material that has an insulating property and is difficult to etch during the step of forming the conductor 472 may be used. For the insulator 471b, refer to the description of the insulator 471b in Embodiment 1.

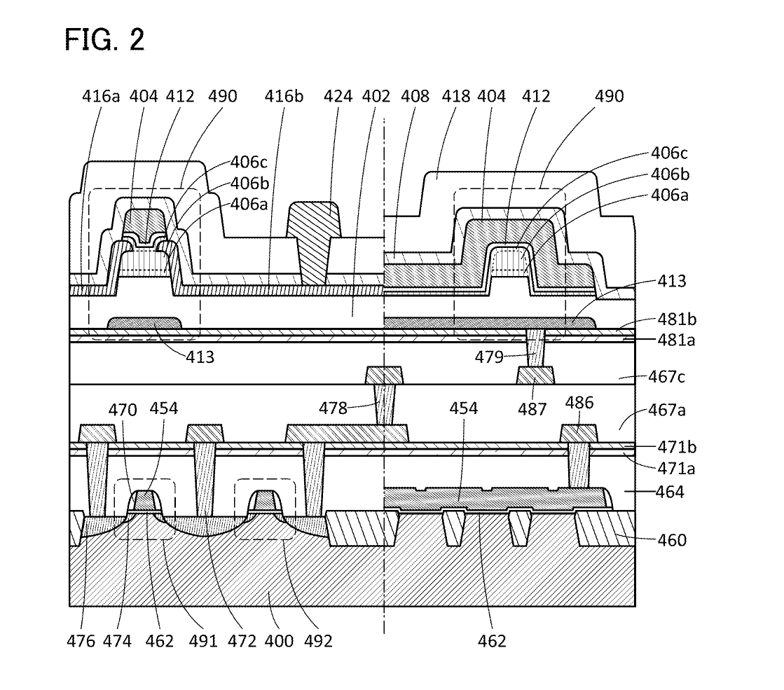

As illustrated in FIG. 2, the semiconductor device may include the transistor 491, the insulator 464 over the transistor 491, the insulator 471a over the insulator 464, the insulator 471b over the insulator 471a, an insulator 481a over the insulator 471b, an insulator 481b over the insulator 481a, and the transistor 490 over the insulator 481b. For the insulator 481a, refer to the description of the insulator 471a. For the insulator 481b, refer to the description of the insulator 471b. The insulators 471a and 481a are insulators blocking oxygen and hydrogen.

In FIG. 2, the insulators 481a and 481b are provided over the insulator 467c. The insulator 467a may be provided between the insulators 471b and 467c.

The insulator 481a included in the semiconductor device can block hydrogen released from the insulator 467a or the insulator 467c, for example. Two or more layers of insulators blocking oxygen and hydrogen between the insulator 464 and the transistor 490 can improve the blocking function.

In FIG. 1 and the like, the semiconductor device preferably includes an insulator 408 over the transistor 490. The insulator 408 has a function of blocking oxygen and hydrogen. For the insulator 408, refer to the description of the insulator 471a. Alternatively, the insulator 408 has, for example, a higher capability to block oxygen and hydrogen than the semiconductor 406a and/or the semiconductor 406c.

When the semiconductor device includes the insulator 408, outward diffusion of oxygen from the transistor 490 can be suppressed. Consequently, excess oxygen (oxygen) contained in the insulator 402 and the like can be effectively supplied to the transistor 490. Since the insulator 408 blocks entry of impurities including hydrogen from layers above the insulator 408 or the outside of the semiconductor device, deterioration of the electrical characteristics of the transistor 490 due to the entry of impurities can be suppressed.

The semiconductor device may include an insulator 418 over the insulator 408. The semiconductor device may further include, for example, a conductor 424, which is provided in an opening portion in the insulator 418 and electrically connected to the transistor 490 through a conductor 416b or the like.

Although the insulator 481a and/or the insulator 408 is described separately from the transistor 490 with reference to FIG. 2 for convenience, the insulator 481a and/or the insulator 408 may be part of the transistor 490.

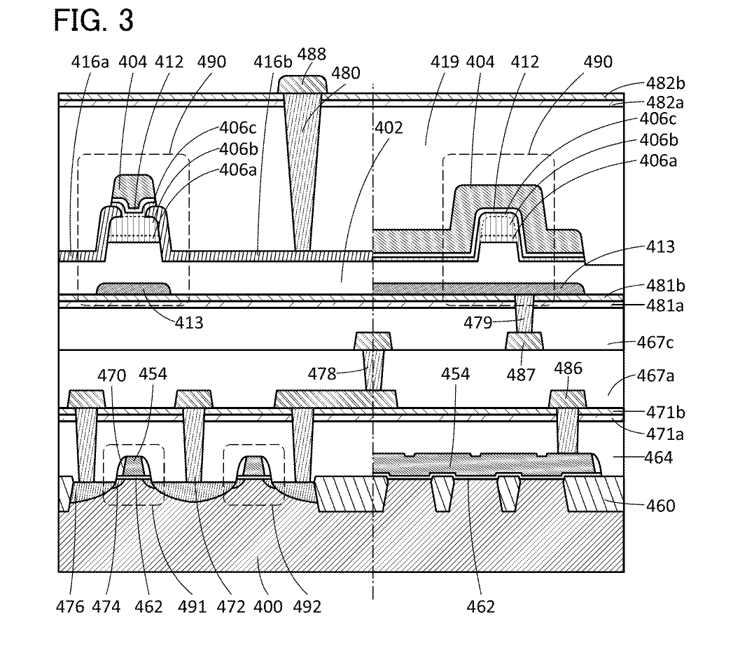

As illustrated in FIG. 3, the semiconductor device may include the transistor 491, the insulator 471a over the transistor 491, the insulator 471b over the insulator 471a, the insulator 481a over the insulator 471b, an insulator 481b over the insulator 481a, the transistor 490 over the insulator 481b, an insulator 482a over the transistor 490, and an insulator 482b over the insulator 482a. For the insulator 482a, refer to the description of the insulator 471a. For the insulator 482b, refer to the description of the insulator 471b. The insulators 471a, 481a, and 482a are insulators blocking oxygen and hydrogen.

As illustrated in FIG. 3, the semiconductor device includes an insulator 419 over the transistor 490. The insulator 482a is provided over the insulator 419, and the insulator 482b is provided over the insulator 482a. Although omitted in the example in FIG. 3, the insulators 408 and 418 over the transistor 490 may be provided over the transistor 490.

A conductor 480 fills an opening portion in the insulators 419, 482a, and 482b.

When the semiconductor device includes the insulator 482a, outward diffusion of oxygen from the transistor 490 can be suppressed. The insulator 482a can also suppress entry of impurities including hydrogen from a layer above the insulator 482a or from the outside of the semiconductor device. In addition, parasitic capacitance might be formed by the transistor 490 and a wiring above the transistor 490, and when a material with a high dielectric constant is used as the insulator 482a, the parasitic capacitance might be increased. Here, the structure in FIG. 3 in which the insulator 419 is provided between the insulator 482a and the transistor 490, for example, can reduce the parasitic capacitance formed by the transistor 490 and the wiring.

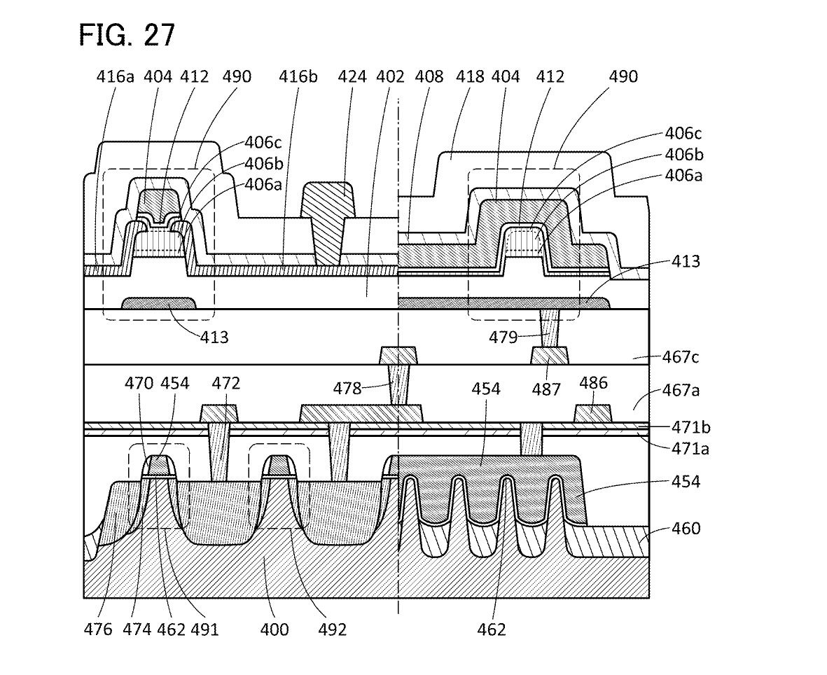

Note that the structures of the transistors 491 and 492 are not limited to the structures illustrated in FIGS. 1 to 3. For example, a structure where the semiconductor substrate 400 has a projection (also referred to as a protrusion or a fin), like the transistors 491 and 492 illustrated in FIG. 27, may be used. In the structures of the transistors 491 and 492 illustrated in FIG. 27, an effective channel width with respect to the occupation area can be increased as compared with those illustrated in FIG. 1. Thus, the on-state currents of the transistors 491 and 492 can be increased.

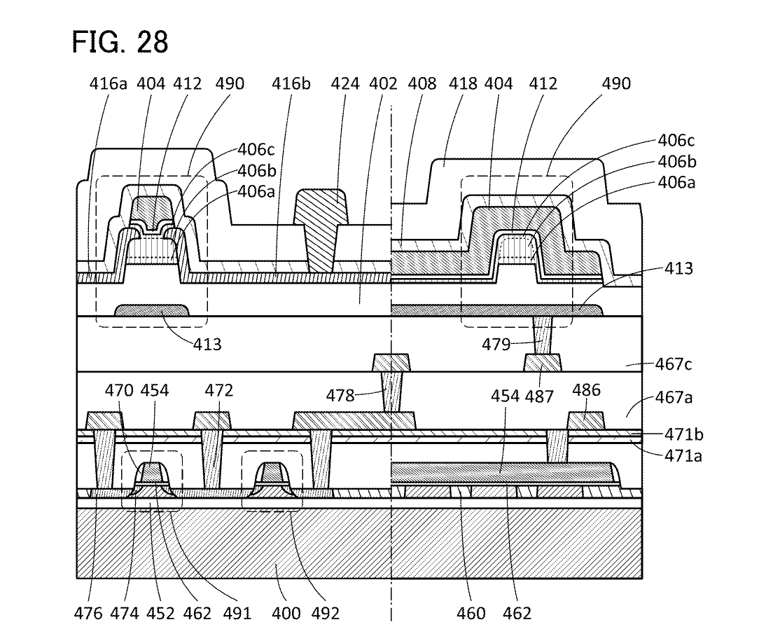

Alternatively, for example, a structure where an insulator region 452 is provided in the semiconductor substrate 400, like the transistors 491 and 492 illustrated in FIG. 28, may be used. With the structures of the transistors 491 and 492 illustrated in FIG. 28, transistors which independently operate can be separated from each other more surely and thus, leakage current can be suppressed. Consequently, the off-state currents of the transistors 491 and 492 can be low. Furthermore, the on-state currents of the transistors 491 and 492 can be high.

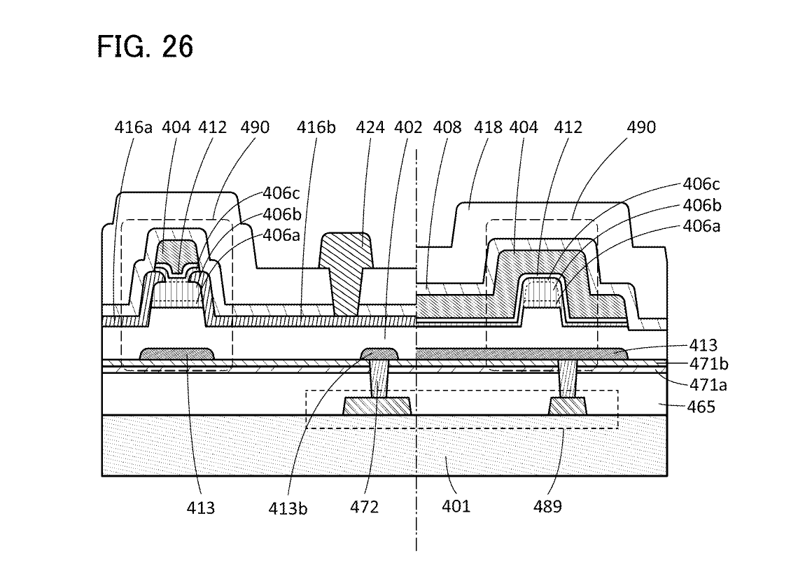

The semiconductor device illustrated in FIG. 26 includes the substrate 401, the wiring layer 489 over the substrate 401, the insulator 471a over the wiring layer 489, the insulator 471b over the insulator 471a, and the transistor 490 over the insulator 471b. The insulator 408 is provided over the transistor 490.

The wiring layer 489 is electrically connected to a conductor 413 and a conductor 413b through the conductor 472 filling opening portions in the insulators 465, 471a, and 471b, and the like.

For the substrate 401, refer to the description of the substrate 401 in Embodiment 1.

The use of an insulator having a function of blocking an impurity as the insulator 471a can suppress entry of an impurity contained in the substrate 401 to the transistor 490, for example, and prevent degradation of characteristics. The insulator 471a has a function of blocking hydrogen and oxygen. Therefore, entry of hydrogen contained in the insulator 465 or the like to the transistor 490 can be suppressed. In addition, the outward diffusion of oxygen from the transistor 490 can be suppressed.

### <Structure of Transistor Using Oxide Semiconductor>

The transistor 490 illustrated in FIG. 1 includes the following: the conductor 413; the insulator 402 over the conductor 413; the semiconductor 406a over the insulator 402; the semiconductor 406b over the semiconductor 406a; a conductor 416a and the conductor 416b in contact with side surfaces of the semiconductor 406a and a top surface and side surfaces of the semiconductor 406b; the semiconductor 406c in contact with the side surfaces of the semiconductor 406a, the top surface and the side surfaces of the semiconductor 406b, a top surface and side surfaces of the conductor 416a, and a top surface and side surfaces of the conductor 416b; an insulator 412 over the semiconductor 406c; and a conductor 404 over the insulator 412. Although the conductor 413 is part of the transistor 490 here, one embodiment of the present invention is not limited thereto. For example, the conductor 413 may be a component independent of the transistor 490.

The conductor 413 serves as a gate electrode of the transistor 490. The insulator 402 serves as a gate insulator of the transistor 490. The conductor 416a and the conductor 416b serve as a source electrode and a drain electrode of the transistor 490. The insulator 412 serves as a gate insulator of the transistor 490. The conductor 404 serves as a gate electrode of the transistor 490.

The conductor 413 and the conductor 404 serve as gate electrodes of the transistor 490, and may be supplied with different potentials. For example, by applying a negative or positive gate voltage to the conductor 413, the threshold voltage of the transistor 490 may be controlled. Alternatively, the conductor 413 and the conductor 404 may be electrically connected to each other through the conductor 473 or the like and thus may be supplied with the same potential. In this case, the on-state current of the transistor 490 can be increased because the effective channel width can be increased. By the conductor 413, an electric field can be supplied to also a region that cannot easily be reached by an electric field in the case of using only the conductor 404; thus, the subthreshold swing value (also referred to as an S value) of the transistor 490 can be small. Accordingly, the off-state current of the transistor 490 can be low.

The insulator 402 is preferably an insulator containing excess oxygen.

The insulator containing excess oxygen means an insulator from which oxygen is released by heat treatment, for example. The silicon oxide containing excess oxygen means silicon oxide which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406a.

The insulator containing excess oxygen has a function of reducing oxygen vacancies in the semiconductor 406b in some cases. Such oxygen vacancies form DOS in the semiconductor 406b and serve as hole traps or the like. In addition, hydrogen comes into the site of such oxygen vacancies and forms electrons serving as carriers. Therefore, by reducing the oxygen vacancies in the semiconductor 406b, the transistor 490 can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in thermal desorption spectroscopy (TDS) analysis in the range of a surface temperature of 100° C. to 700° C. or 100° C. to 500° C.

Here, the method of measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}=N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value α is a coefficient affecting the ion intensity in the TDS analysis. Refer to Japanese Published Patent Application No. H6-275697 for details of the above formula. The amount of released oxygen was measured with a thermal desorption spectroscopy apparatus produced by ESCO Ltd., EMD-WA1000S/W using a silicon substrate containing hydrogen atoms at 1×10¹⁶ atoms/cm² as the reference sample.

Furthermore, in the TDS analysis, oxygen is partly detected as an oxygen atom. The ratio between oxygen molecules and oxygen atoms can be calculated from the ionization rate of the oxygen molecules. Note that, since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X}(X>2)). In the oxygen-excess silicon oxide (SiO_{X}(X>2)), the number of oxygen atoms per unit volume is more than twice the number of silicon atoms per unit volume. The number of silicon atoms and the number of oxygen atoms per unit volume are measured by Rutherford backscattering spectrometry (RBS).

As illustrated in FIG. 1, the side surfaces of the conductors 416a and 416b are in contact with the side surfaces of the semiconductor 406b. The semiconductor 406b can be electrically surrounded by an electric field of the conductor 404 (a structure in which a semiconductor is electrically surrounded by an electric field of a conductor is referred to as a surrounded channel (s-channel) structure). Therefore, a channel is formed in the entire semiconductor 406b (bulk) in some cases. In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm and the channel width of the transistor is preferably less than or equal to 40 nm, more preferably less than or equal to 30 nm, still more preferably less than or equal to 20 nm.

The term channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The term channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width and an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

### <Structure of Oxide Semiconductor>

A structure of an oxide semiconductor which can be used as the semiconductor 406a, the semiconductor 406b, the semiconductor 406c, or the like is described below. In this specification, the trigonal and rhombohedral crystal systems are included in the hexagonal crystal system.

An oxide semiconductor is classified into a non-single-crystal oxide semiconductor and a single crystal oxide semiconductor. Alternatively, an oxide semiconductor is classified into, for example, a crystalline oxide semiconductor and an amorphous oxide semiconductor.

Examples of a non-single-crystal oxide semiconductor include a c-axis aligned crystalline oxide semiconductor (CAAC-OS), a polycrystalline oxide semiconductor, a microcrystalline oxide semiconductor, and an amorphous oxide semiconductor. In addition, examples of a crystalline oxide semiconductor include a single crystal oxide semiconductor, a CAAC-OS, a polycrystalline oxide semiconductor, and a microcrystalline oxide semiconductor.

First, a CAAC-OS is described.

A CAAC-OS is one of oxide semiconductors having a plurality of c-axis aligned crystal parts.

In a combined analysis image (also referred to as a high-resolution TEM image) of a bright-field image and a diffraction pattern of a CAAC-OS, which is obtained using a transmission electron microscope (TEM), a plurality of crystal parts can be observed. However, in the high-resolution TEM image, a boundary between crystal parts, that is, a grain boundary is not clearly observed. Thus, in the CAAC-OS, a reduction in electron mobility due to the grain boundary is less likely to occur.

In the high-resolution cross-sectional TEM image of the CAAC-OS observed in a direction substantially parallel to the sample surface, metal atoms are arranged in a layered manner in the crystal parts. Each metal atom layer has a morphology reflecting a surface over which the CAAC-OS is formed (hereinafter, a surface over which the CAAC-OS is formed is referred to as a formation surface) or a top surface of the CAAC-OS, and is arranged parallel to the formation surface or the top surface of the CAAC-OS.

In the high-resolution planar TEM image of the CAAC-OS observed in a direction substantially perpendicular to the sample surface, metal atoms arranged in a triangular or hexagonal configuration are seen in the crystal parts. However, there is no regularity in arrangement of metal atoms between different crystal parts.

A CAAC-OS is subjected to structural analysis with an X-ray diffraction (XRD) apparatus. For example, when the CAAC-OS including an InGaZnO₄ crystal is analyzed by an out-of-plane method, a peak appears when the diffraction angle (2θ) is around 31°. Since this peak is derived from the (009) plane of the InGaZnO₄ crystal, it can also be confirmed that crystals in the CAAC-OS have c-axis alignment and that the c-axes are aligned in a direction substantially perpendicular to the formation surface or the top surface of the CAAC-OS.

Note that in analysis of the CAAC-OS including an InGaZnO₄ crystal by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS, a peak appear when 2θ is around 31° and that a peak not appear when 2θ is around 36°.

The CAAC-OS is an oxide semiconductor with a low impurity concentration. The impurity means an element other than the main components of the oxide semiconductor, such as hydrogen, carbon, silicon, or a transition metal element. An element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity. Additionally, the impurity contained in the oxide semiconductor might serve as a carrier trap or a carrier generation source.

Moreover, the CAAC-OS is an oxide semiconductor having a low density of defect states. For example, oxygen vacancies in the oxide semiconductor serve as carrier traps or serve as carrier generation sources when hydrogen is captured therein.

The state in which the impurity concentration is low and the density of defect states is low (the number of oxygen vacancies is small) is referred to as a “highly purified intrinsic” or “substantially highly purified intrinsic” state. A highly purified intrinsic or substantially highly purified intrinsic oxide semiconductor has few carrier generation sources, and thus can have a low carrier density. Thus, a transistor including the oxide semiconductor rarely has negative threshold voltage (rarely has normally-on characteristics). The highly purified intrinsic or substantially highly purified intrinsic oxide semiconductor has few carrier traps. Consequently, the transistor including the oxide semiconductor has little variation in electrical characteristics and high reliability. Electric charge trapped by the carrier traps in the oxide semiconductor takes a long time to be released and might behave like fixed electric charge. Thus, the transistor including the oxide semiconductor having high impurity concentration and a high density of defect states has unstable electrical characteristics in some cases.

In a transistor using the CAAC-OS, change in electrical characteristics due to irradiation with visible light or ultraviolet light is small.

Next, a microcrystalline oxide semiconductor is described.

A microcrystalline oxide semiconductor has a region in which a crystal part is observed and a region in which a crystal part is not clearly observed in a high-resolution TEM image. In most cases, the size of a crystal part included in the microcrystalline oxide semiconductor is greater than or equal to 1 nm and less than or equal to 100 nm, or greater than or equal to 1 nm and less than or equal to 10 nm. An oxide semiconductor including a nanocrystal that is a microcrystal with a size greater than or equal to 1 nm and less than or equal to 10 nm, or a size greater than or equal to 1 nm and less than or equal to 3 nm is specifically referred to as a nanocrystalline oxide semiconductor (nc-OS). In a high-resolution TEM image of the nc-OS, for example, a grain boundary is not clearly observed in some cases.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different crystal parts in the nc-OS. Thus, the orientation of the whole film is not ordered. Accordingly, the nc-OS cannot be distinguished from an amorphous oxide semiconductor, depending on an analysis method. For example, when the nc-OS is subjected to structural analysis by an out-of-plane method with an XRD apparatus using an X-ray having a diameter larger than the size of a crystal part, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a crystal part (the electron diffraction is also referred to as selected-area electron diffraction). Meanwhile, spots appear in a nanobeam electron diffraction pattern of the nc-OS when an electron beam having a probe diameter close to or smaller than the size of a crystal part is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

The nc-OS is an oxide semiconductor that has high regularity as compared with an amorphous oxide semiconductor. Therefore, the nc-OS is likely to have a lower density of defect states than an amorphous oxide semiconductor. Note that there is no regularity of crystal orientation between different crystal parts in the nc-OS. Therefore, the nc-OS has a higher density of defect states than the CAAC-OS.

Next, an amorphous oxide semiconductor is described.

The amorphous oxide semiconductor is an oxide semiconductor having disordered atomic arrangement and no crystal part and exemplified by an oxide semiconductor which exists in an amorphous state as quartz.

In a high-resolution TEM image of the amorphous oxide semiconductor, crystal parts cannot be found.

When the amorphous oxide semiconductor is subjected to structural analysis by an out-of-plane method with an XRD apparatus, a peak which shows a crystal plane does not appear. A halo pattern is observed when the amorphous oxide semiconductor is subjected to electron diffraction. Furthermore, a spot is not observed and a halo pattern appears when the amorphous oxide semiconductor is subjected to nanobeam electron diffraction.

Note that an oxide semiconductor may have a structure having physical properties intermediate between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be observed. Furthermore, in the high-resolution TEM image, there are a region where a crystal part is clearly observed and a region where a crystal part is not observed. Growth of the crystal part occurs due to the crystallization of the a-like OS, which is induced by a slight amount of electron beam employed in the TEM observation. In contrast, crystallization by a slight amount of electron beam used for TEM observation is less observed in the nc-OS having good quality.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Thus, focusing on lattice fringes in the high-resolution TEM image, each of lattice fringes in which the lattice spacing therebetween is greater than or equal to 0.28 nm and less than or equal to 0.30 nm corresponds to the a-b plane of the InGaZnO₄ crystal.

Furthermore, the density of an oxide semiconductor varies depending on the structure in some cases. For example, when the composition of an oxide semiconductor is determined, the structure of the oxide semiconductor can be expected by comparing the density of the oxide semiconductor with the density of a single crystal oxide semiconductor having the same composition as the oxide semiconductor. For example, the density of the a-like OS is higher than or equal to 78.6% and lower than 92.3% of the density of the single crystal oxide semiconductor having the same composition. For example, the density of each of the nc-OS and the CAAC-OS is higher than or equal to 92.3% and lower than 100% of the density of the single crystal oxide semiconductor having the same composition. Note that an oxide semiconductor having a density lower than 78% of the density of the single crystal oxide semiconductor is difficult to form by a deposition method or the like.

Specific examples of the above description are given. For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

Note that an oxide semiconductor may be a stacked film including two or more films of an amorphous oxide semiconductor, an a-like OS, a microcrystalline oxide semiconductor, and a CAAC-OS, for example.

The above oxide semiconductor can be used as the semiconductor 406a, the semiconductor 406b, the semiconductor 406c, or the like.

### <Other Components of Semiconductor>

Next, the other components of a semiconductor which can be used as the semiconductor 406a, the semiconductor 406b, the semiconductor 406c, or the like are described.

Here, the semiconductor 406b is an oxide semiconductor containing indium, for example. The semiconductor 406b has a high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having a high bonding energy with oxygen, for example. The element M is an element whose bonding energy with oxygen is higher than that of indium. The element M is an element that can increase the energy gap of the oxide semiconductor, for example. Further, the semiconductor 406b preferably contains zinc. When the oxide semiconductor contains zinc, the oxide semiconductor is easily to be crystallized, for example.

Note that the semiconductor 406b is not limited to the oxide semiconductor containing indium. The semiconductor 406b may be, for example, an oxide semiconductor that does not contain indium and contains zinc, an oxide semiconductor that does not contain indium and contains gallium, or an oxide semiconductor that does not contain indium and contains tin, e.g., a zinc tin oxide or a gallium tin oxide.

For the semiconductor 406b, an oxide with a wide energy gap may be used. For example, the energy gap of the semiconductor 406b is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the semiconductor 406a and the semiconductor 406c include one or more, or two or more elements other than oxygen included in the semiconductor 406b. Since the semiconductor 406a and the semiconductor 406c each include one or more, or two or more elements other than oxygen included in the semiconductor 406b, an interface state is less likely to be formed at the interface between the semiconductor 406a and the semiconductor 406b and the interface between the semiconductor 406b and the semiconductor 406c.

The semiconductor 406a, the semiconductor 406b, and the semiconductor 406c preferably include at least indium. In the case of using an In-M-Zn oxide as the semiconductor 406a, when the summation of In and M is assumed to be 100 atomic %, the proportions of In and M are preferably set to be less than 50 atomic % and greater than or equal to 50 atomic %, respectively, more preferably less than 25 atomic % and greater than or equal to 75 atomic %, respectively. In the case of using an In-M-Zn oxide as the semiconductor 406b, when the summation of In and M is assumed to be 100 atomic %, the proportions of In and M are preferably set to be greater than or equal to 25 atomic % and less than 75 atomic %, respectively, more preferably greater than or equal to 34 atomic % and less than 66 atomic %, respectively. In the case of using an In-M-Zn oxide as the semiconductor 406c, when the summation of In and M is assumed to be 100 atomic %, the proportions of In and M are preferably set to be less than 50 atomic % and greater than or equal to 50 atomic %, respectively, more preferably less than 25 atomic % and greater than or equal to 75 atomic %, respectively. Note that the semiconductor 406c and the semiconductor 406a may be formed using the same type of oxide.

As the semiconductor 406b, an oxide having an electron affinity higher than those of the semiconductors 406a and 406c is used. For example, as the semiconductor 406b, an oxide having an electron affinity higher than those of the semiconductors 406a and 406c by 0.07 eV or higher and 1.3 eV or lower, preferably 0.1 eV or higher and 0.7 eV or lower, more preferably 0.15 eV or higher and 0.4 eV or lower is used. Note that the term electron affinity refers to an energy difference between the vacuum level and the bottom of the conduction band.

An indium gallium oxide has a small electron affinity and a high oxygen-blocking property. Therefore, the semiconductor 406c preferably includes an indium gallium oxide. The gallium atomic ratio [In/(In+Ga)] is, for example, higher than or equal to 70%, preferably higher than or equal to 80%, more preferably higher than or equal to 90%.

At this time, when an electric field is applied to a gate electrode, a channel is formed in the semiconductor 406b having the highest electron affinity in the semiconductor 406a, the semiconductor 406b, and the semiconductor 406c.

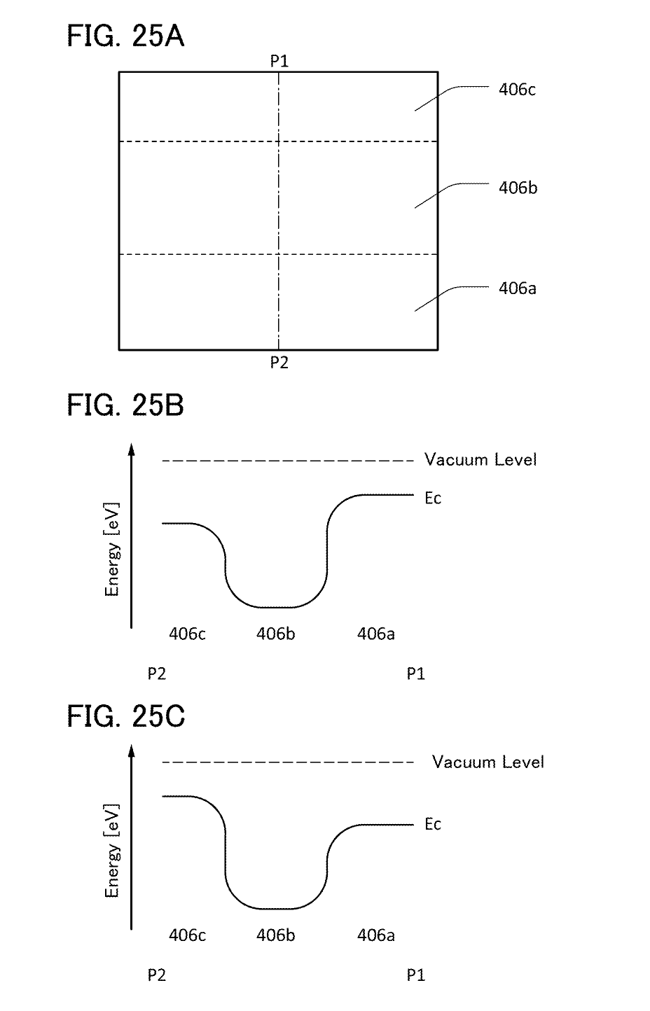

Here, in some cases, there is a mixed region of the semiconductor 406a and the semiconductor 406b between the semiconductor 406a and the semiconductor 406b. Furthermore, in some cases, there is a mixed region of the semiconductor 406b and the semiconductor 406c between the semiconductor 406b and the semiconductor 406c. The mixed region has a low interface state density. For that reason, the stack of the semiconductor 406a, the semiconductor 406b, and the semiconductor 406c has a band diagram where energy at each interface and in the vicinity of the interface is changed continuously (continuous junction). Note that FIG. 25A is a cross-sectional view in which the semiconductor 406a, the semiconductor 406b, and the semiconductor 406c are stacked in this order. FIG. 25B shows energy (Ec) of the bottom of the conduction band corresponding to dashed-dotted line P1-P2 in FIG. 25A when the semiconductor 406c has a higher electron affinity than the semiconductor 406a. FIG. 25C shows the case where the semiconductor 406c has a lower electron affinity than the semiconductor 406a.

At this time, electrons move mainly in the semiconductor 406b, not in the semiconductor 406a and the semiconductor 406c. As described above, when the interface state density at the interface between the semiconductor 406a and the semiconductor 406b and the interface state density at the interface between the semiconductor 406b and the semiconductor 406c are decreased, electron movement in the semiconductor 406b is less likely to be inhibited and the on-state current of the transistor 490 can be increased.

As factors of inhibiting electron movement are decreased, the on-state current of the transistor 490 can be increased. For example, in the case where there is no factor of inhibiting electron movement, electrons are assumed to be efficiently moved. Electron movement is inhibited, for example, in the case where physical unevenness is large.

Therefore, to increase the on-state current of the transistor 490, for example, root mean square (RMS) roughness with a measurement area of 1 μm×1 μm of a top surface or a bottom surface of the semiconductor 406b (a formation surface; here, the semiconductor 406a) is less than 1 nm, preferably less than 0.6 nm, more preferably less than 0.5 nm, still more preferably less than 0.4 nm. The average surface roughness (also referred to as Ra) with the measurement area of 1 μm×1 μm is less than 1 nm, preferably less than 0.6 nm, more preferably less than 0.5 nm, still more preferably less than 0.4 nm. The maximum difference (P−V) with the measurement area of 1 μm×1 μm is less than 10 nm, preferably less than 9 nm, more preferably less than 8 nm, still more preferably less than 7 nm. Note that RMS roughness, Ra, and P−V can be measured using SPA-500 manufactured by SII Nano Technology Inc.

The electron movement is also inhibited, for example, in the case where the density of defect states is high in a region where a channel is formed.

For example, in the case where the semiconductor 406b contains oxygen vacancies (also denoted by V_{O}), donor levels are formed by entry of hydrogen into sites of oxygen vacancies in some cases. A state in which hydrogen enters sites of oxygen vacancies are denoted by V_{O}H in the following description in some cases. The state V_{O}H is a factor of decreasing the on-state current of the transistor 490 because V_{O}H scatters electrons. Note that sites of oxygen vacancies become more stable by entry of oxygen than by entry of hydrogen. Thus, by decreasing oxygen vacancies in the semiconductor 406b, the on-state current of the transistor 490 can be increased in some cases.

To decrease oxygen vacancies in the semiconductor 406b, for example, there is a method in which excess oxygen in the insulator 402 is moved to the semiconductor 406b through the semiconductor 406a. In this case, the semiconductor 406a is preferably a layer having an oxygen-transmitting property (a layer through which oxygen passes or is transmitted).

Oxygen is released from the insulator 402 and taken into the semiconductor 406a by heat treatment or the like. In some cases, oxygen exists and is apart from atomics in the semiconductor 406a, or exists and is bonded to oxygen or the like. As the density becomes lower, i.e., the number of spaces between the atoms becomes larger, the semiconductor 406a has a higher oxygen-transmitting property. For example, in the case where the semiconductor 406a has a layered crystal structure and oxygen movement in which oxygen crosses the layer is less likely to occur, the semiconductor 406a is preferably a layer having low crystallinity as appropriate.

The semiconductor 406a preferably has crystallinity such that excess oxygen (oxygen) is transmitted so that excess oxygen (oxygen) released from the insulator 402 reaches the semiconductor 406b. For example, in the case where the semiconductor 406a is a CAAC-OS, a structure in which a space is partly provided in the layer is preferably employed because when the whole layer becomes CAAC, excess oxygen (oxygen) cannot be transmitted. For example, the proportion of CAAC of the semiconductor 406a is lower than 100%, preferably lower than 98%, more preferably lower than 95%, still more preferably lower than 90%. Note that to reduce the interface state density at the interface between the semiconductor 406a and the semiconductor 406b, the proportion of CAAC of the semiconductor 406a is higher than or equal to 10%, preferably higher than or equal to 20%, more preferably higher than or equal to 50%, still more preferably higher than or equal to 70%.

In the case where the transistor 490 has an s-channel structure, a channel is formed in the whole of the semiconductor 406b. Therefore, as the semiconductor 406b has a larger thickness, a channel region becomes larger. In other words, the thicker the semiconductor 406b is, the larger the on-state current of the transistor 490 is. For example, the semiconductor 406b includes a region with a thickness greater than or equal to 20 nm, preferably greater than or equal to 40 nm, more preferably greater than or equal to 60 nm, still more preferably greater than or equal to 100 nm. Note that the semiconductor 406b includes a region with a thickness, for example, less than or equal to 300 nm, preferably less than or equal to 200 nm, more preferably less than or equal to 150 nm because the productivity of the semiconductor device might be decreased.

Moreover, the thickness of the semiconductor 406c is preferably as small as possible to increase the on-state current of the transistor 490. The semiconductor 406c includes a region with a thickness less than 10 nm, preferably less than or equal to 5 nm, more preferably less than or equal to 3 nm, for example. Meanwhile, the semiconductor 406c has a function of blocking entry of elements other than oxygen (such as hydrogen and silicon) included in the adjacent insulator into the semiconductor 406b where a channel is formed. For this reason, it is preferable that the semiconductor 406c have a certain thickness. The semiconductor 406c includes a region with a thickness greater than or equal to 0.3 nm, preferably greater than or equal to 1 nm, more preferably greater than or equal to 2 nm, for example. The semiconductor 406c preferably has an oxygen blocking property to suppress outward diffusion of oxygen released from the insulator 402 and the like.

To improve reliability, preferably, the thickness of the semiconductor 406a is large and the thickness of the semiconductor 406c is small. For example, the semiconductor 406a includes a region with a thickness, for example, greater than or equal to 10 nm, preferably greater than or equal to 20 nm, more preferably greater than or equal to 40 nm, still more preferably greater than or equal to 60 nm. When the thickness of the semiconductor 406a is made large, a distance from an interface between the adjacent insulator and the semiconductor 406a to the semiconductor 406b in which a channel is formed can be large. Since the productivity of the semiconductor device might be decreased, the semiconductor 406a includes a region with a thickness, for example, less than or equal to 200 nm, preferably less than or equal to 120 nm, more preferably less than or equal to 80 nm.

For example, a region with a silicon concentration lower than 1×10¹⁹ atoms/cm³, preferably lower than 5×10¹⁸ atoms/cm³, more preferably lower than 2×10¹⁸ atoms/cm³ which is measured by secondary ion mass spectrometry (SIMS) is provided between the semiconductor 406b and the semiconductor 406a. A region with a silicon concentration lower than 1×10¹⁹ atoms/cm³, preferably lower than 5×10¹⁸ atoms/cm³, more preferably lower than 2×10¹⁸ atoms/cm³ which is measured by SIMS is provided between the semiconductor 406b and the semiconductor 406c.

It is preferable to reduce the concentration of hydrogen in the semiconductor 406a and the semiconductor 406c in order to reduce the concentration of hydrogen in the semiconductor 406b. The semiconductor 406a and the semiconductor 406c each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of nitrogen in the semiconductor 406a and the semiconductor 406c in order to reduce the concentration of nitrogen in the semiconductor 406b. The semiconductor 406a and the semiconductor 406c each have a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The above three-layer structure is an example. For example, a two-layer structure without the semiconductor 406a or the semiconductor 406c may be employed. A four-layer structure in which any one of the semiconductors described as examples of the semiconductor 406a, the semiconductor 406, and the semiconductor 406c is provided below or over the semiconductor 406a or below or over the semiconductor 406c may be employed. An n-layer structure (n is an integer of 5 or more) in which any one of the semiconductors described as examples of the semiconductor 406a, the semiconductor 406, and the semiconductor 406c is provided at two or more of the following positions: over the semiconductor 406a, below the semiconductor 406a, over the semiconductor 406c, and below the semiconductor 406c.

At least part (or all) of the conductor 416a (and/or the conductor 416b) is provided on at least part (or all) of a surface, a side surface, a top surface, and/or a bottom surface of a semiconductor, e.g., the semiconductor 406b.

Alternatively, at least part (or all) of the conductor 416a (and/or the conductor 416b) is in contact with at least part (or all) of a surface, a side surface, a top surface, and/or a bottom surface of a semiconductor, e.g., the semiconductor 406b. Alternatively, at least part (or all) of the conductor 416a (and/or the conductor 416b) is in contact with at least part (or all) of a semiconductor, e.g., the semiconductor 406b.

Alternatively, at least part (or all) of the conductor 416a (and/or the conductor 416b) is electrically connected to at least part (or all) of a surface, a side surface, a top surface, and/or a bottom surface of a semiconductor, e.g., the semiconductor 406b. Alternatively, at least part (or all) of the conductor 416a (and/or the conductor 416b) is electrically connected to at least part (or all) of a semiconductor, e.g., the semiconductor 406b.

Alternatively, at least part (or all) of the conductor 416a (and/or the conductor 416b) is provided near at least part (or all) of a surface, a side surface, a top surface, and/or a bottom surface of a semiconductor, e.g., the semiconductor 406b. Alternatively, at least part (or all) of the conductor 416a (and/or the conductor 416b) is provided near at least part (or all) of a semiconductor, e.g., the semiconductor 406b.

Alternatively, at least part (or all) of the conductor 416a (and/or the conductor 416b) is provided to be adjacent to at least part (or all) of a surface, a side surface, a top surface, and/or a bottom surface of a semiconductor, e.g., the semiconductor 406b. Alternatively, at least part (or all) of the conductor 416a (and/or the conductor 416b) is provided to be adjacent to at least part (or all) of a semiconductor, e.g., the semiconductor 406b.

Alternatively, at least part (or all) of the conductor 416a (and/or the conductor 416b) is provided obliquely above at least part (or all) of a surface, a side surface, a top surface, and/or a bottom surface of a semiconductor, e.g., the semiconductor 406b. Alternatively, at least part (or all) of the conductor 416a (and/or the conductor 416b) is provided obliquely above at least part (or all) of a semiconductor, e.g., the semiconductor 406b.

Alternatively, at least part (or all) of the conductor 416a (and/or the conductor 416b) is provided above at least part (or all) of a surface, a side surface, a top surface, and/or a bottom surface of a semiconductor, e.g., the semiconductor 406b. Alternatively, at least part (or all) of the conductor 416a (and/or the conductor 416b) is provided above at least part (or all) of a semiconductor, e.g., the semiconductor 406b.

### <Modification Example of Transistor Using Oxide Semiconductor>

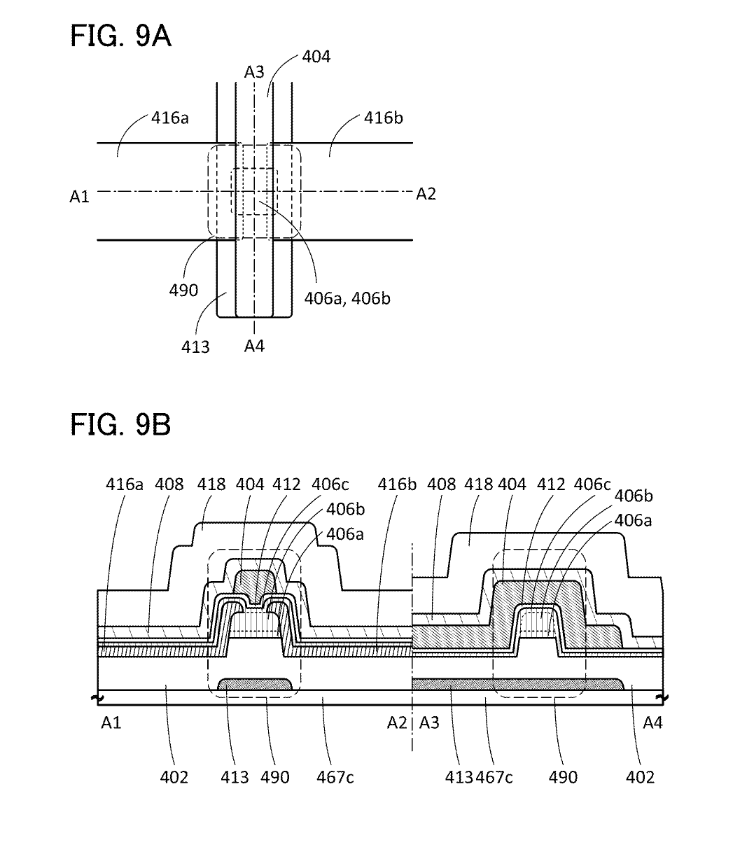

The transistor 490 can have any of a variety of structures. For easy understanding, only the transistor 490 and the vicinity thereof are illustrated in FIGS. 9A and 9B, FIGS. 10A and 10B, FIGS. 11A and 11B, FIGS. 12A and 12B, FIGS. 13A to 13C, FIGS. 14A and 14B, FIGS. 15A and 15B, FIGS. 16A and 16B, FIGS. 17A and 17B, FIGS. 18A and 18B, FIGS. 22A and 22B, and FIGS. 23A and 23B.

FIG. 9A is an example of a top view of the transistor 490. FIG. 9B is an example of a cross-sectional view taken along dashed-dotted line A1-A2 and dashed-dotted line A3-A4 in FIG. 9A. Note that some components such as an insulator are omitted in FIG. 9A for easy understanding.

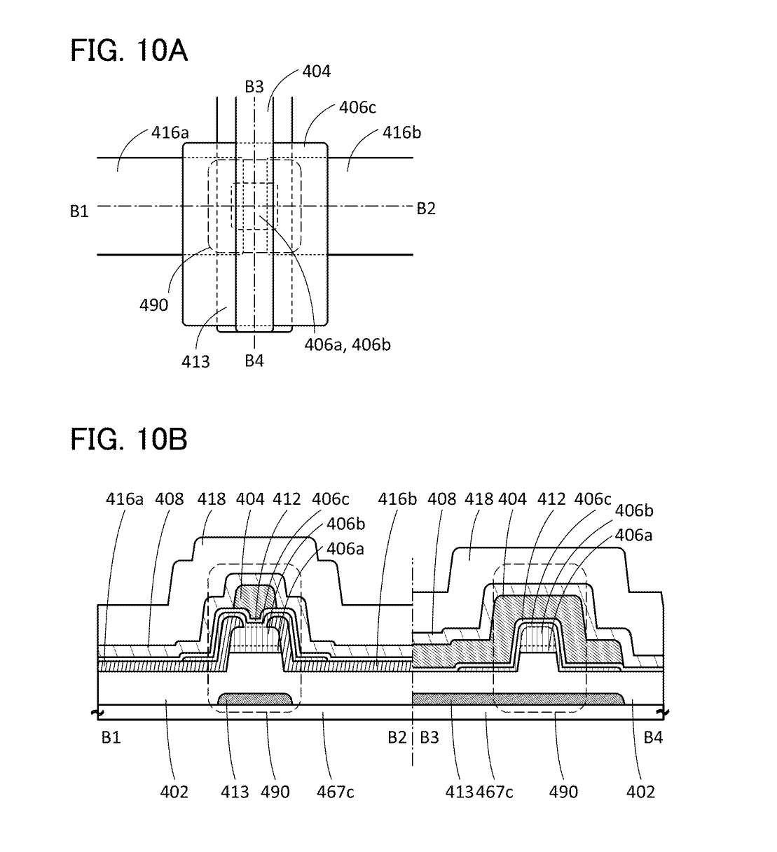

FIG. 10A is another example of the top view of the transistor 490. FIG. 10B is an example of a cross-sectional view taken along dashed-dotted line B1-B2 and dashed-dotted line B3-B4 in FIG. 10A. Note that some components such as an insulator are omitted in FIG. 10A for easy understanding.

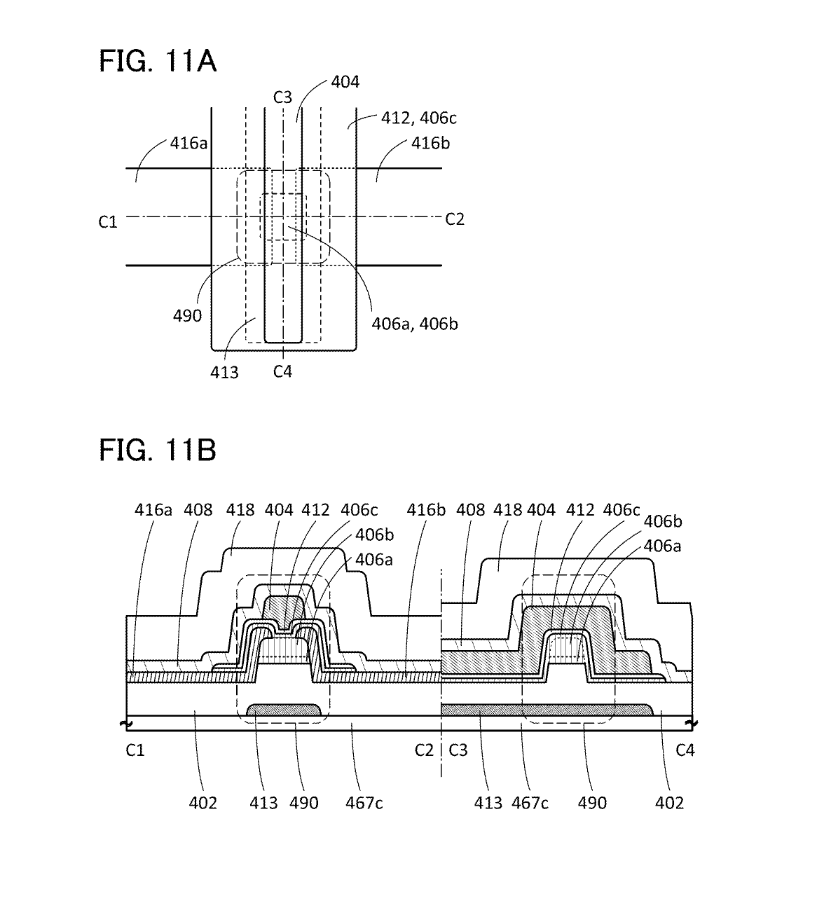

FIG. 11A is another example of the top view of the transistor 490. FIG. 11B is an example of a cross-sectional view taken along dashed-dotted line C1-C2 and dashed-dotted line C3-C4 in FIG. 11A. Note that some components such as an insulator are omitted in FIG. 11A for easy understanding.

Although FIG. 1 and the like show an example where any of the ends of the semiconductor 406c, the insulator 412, and the conductor 404 does not project, a transistor structure of one embodiment of the present invention is not limited thereto. For example, as illustrated in the top view in FIG. 9A and the cross-sectional view in FIG. 9B, the semiconductor 406c and the insulator 412 may be formed over the entire surface of the transistor. As illustrated in the top view in FIG. 10A, the semiconductor 406c may be provided to cover a channel formation region of a transistor and its periphery, and the insulator 412 may be provided over the entire surface of the transistor to cover the semiconductor 406c. In the cross-sectional view in FIG. 10B, the semiconductor 406c has a region whose end projects as compared with the conductor 404. Alternatively, as illustrated in the top view in FIG. 11A, the semiconductor 406c and the insulator 412 may be provided to cover a channel formation region of a transistor and its periphery. Note that in the cross-sectional view in FIG. 11B, ends of the semiconductor 406c and the insulator 412 each project as compared with the conductor 404.

When the transistor has any one of the structures illustrated in FIGS. 9A and 9B, FIGS. 10A and 10B, and FIGS. 11A and 11B, leakage current through a surface of the semiconductor 406c, a surface of the insulator 412, or the like can be reduced in some cases. In other words, the off-state current of the transistor can be reduced. At the time of etching of the insulator 412 and the semiconductor 406c, the conductor 404 is not necessarily used as a mask; thus, the conductor 404 is not exposed to plasma. Therefore, electrostatic damage of a transistor due to an antenna effect is less likely to occur, and thus, the semiconductor device can be manufactured with high yield. Since the degree of freedom of design of the semiconductor device is increased, the transistor is suitable for an integrated circuit such as a large scale integration (LSI) or very large scale integration (VLSI) having a complicated structure.

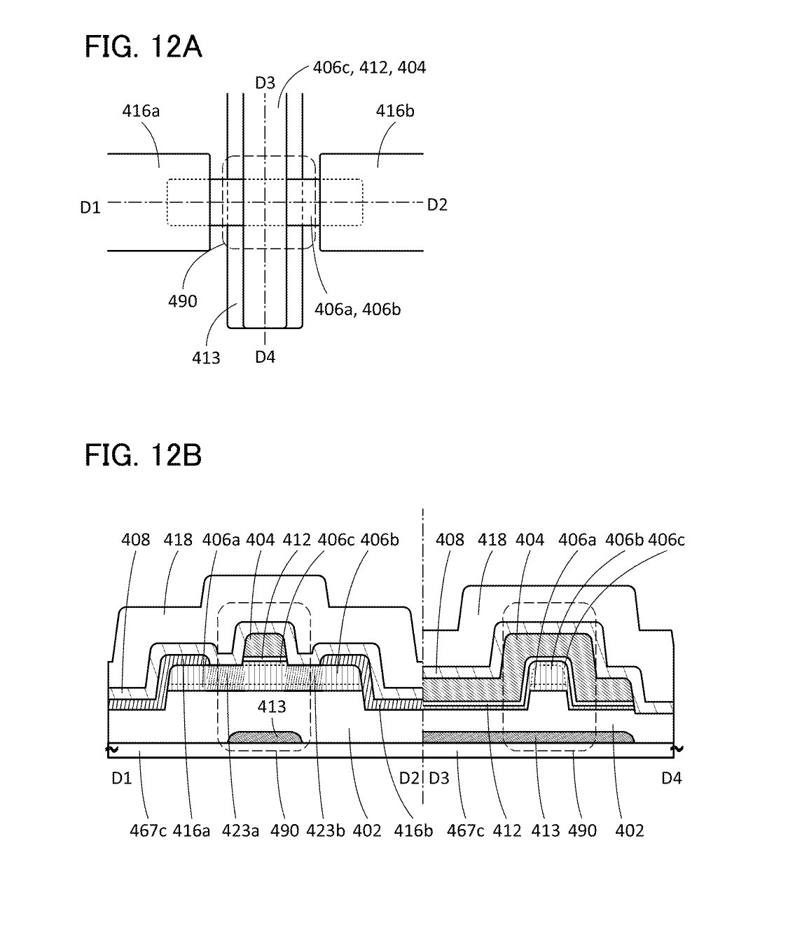

FIG. 12A is another example of the top view of the transistor 490. FIG. 12B is an example of a cross-sectional view taken along dashed-dotted line D1-D2 and dashed-dotted line D3-D4 in FIG. 12A. Note that some components such as an insulator are omitted in FIG. 12A for easy understanding.

Although FIG. 1 and the like show a structure in which a region where the conductors 416a and 416b functioning as a source electrode and a drain electrode and the conductor 404 functioning as a gate electrode overlap with each other is provided, a transistor structure of one embodiment of the present invention is not limited thereto. For example, as illustrated in FIGS. 12A and 12B, a region where the conductors 416a and 416b and the conductor 404 overlap with each other is not necessarily provided. With such a structure, a transistor with a small parasitic capacitance can be formed. Thus, a transistor with favorable switching characteristics and less noise can be obtained.

Note that the conductors 416a and 416b and the conductor 404 do not overlap with each other; thus, resistance between the conductor 416a and the conductor 416b becomes high in some cases. In such a case, the resistance is preferably as low as possible because the on-state current of the transistor might be low. For example, the distance between the conductor 416a (conductor 416b) and the conductor 404 may be made small. For example, the distance between the conductor 416a (conductor 416b) and the conductor 404 may be greater than or equal to 0 μm and less than or equal to 1 μm, preferably greater than or equal to 0 μm and less than or equal to 0.5 μm, more preferably greater than or equal to 0 μm and less than or equal to 0.2 μm, still more preferably greater than or equal to 0 μm and less than or equal to 0.1 μm.

A low-resistance region 423a (low-resistance region 423b) may be provided in the semiconductor 406b and/or the semiconductor 406a between the conductor 416a (conductor 416b) and the conductor 404. The low-resistance region 423a and the low-resistance region 423b each have, for example, a region whose carrier density is higher than that of the other region of the semiconductor 406b and/or that of the other region of the semiconductor 406a. Alternatively, the low-resistance region 423a and the low-resistance region 423b each have a region whose impurity concentration is higher than that of the other region of the semiconductor 406b and/or that of the other region of the semiconductor 406a. Alternatively, the low-resistance region 423a and the low-resistance region 423b each have a region whose carrier mobility is higher than that of the other region of the semiconductor 406b and/or that of the other region of the semiconductor 406a. The low-resistance region 423a and the low-resistance region 423b may be formed in such a manner that, for example, the conductor 404, the conductor 416a, the conductor 416b, and the like are used as masks and impurities are added to the semiconductor 406b and/or the semiconductor 406a.

The distance between the conductor 416a (conductor 416b) and the conductor 404 may be made short, and the low-resistance region 423a (low-resistance region 423b) may be provided in the semiconductor 406b and/or the semiconductor 406a between the conductor 416a (conductor 416b) and the conductor 404.

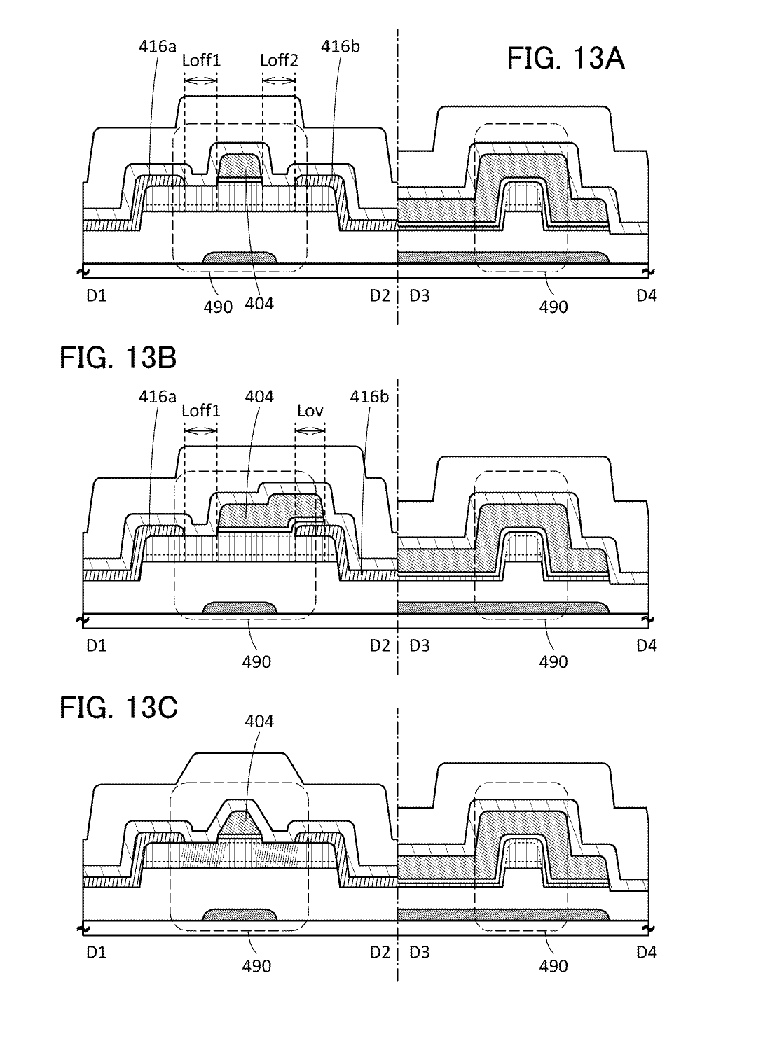

Alternatively, as in FIG. 13A, the transistor 490 does not necessarily include the low-resistance region 423a and the low-resistance region 423b, for example. In the transistor 490 without including the low-resistance region 423a and the low-resistance region 423b, the on-state current might be decreased but the short-channel effect can be reduced. Note that regions in FIG. 12B corresponding to the low-resistance region 423a and the low-resistance region 423b (a region between the conductor 416a and the conductor 404 and a region between the conductor 416b and the conductor 404) are referred to as an Loff1 region and an Loff2 region, respectively. For example, the length of each of the Loff1 region and the Loff2 region is preferably set to 50 nm or less, 20 nm or less, or 10 nm or less, in which case the on-state current of the transistor 490 hardly decreases even when the transistor 490 does not include the low-resistance region 423a and the low-resistance region 423b. Note that the areas of the Loff1 region and the Loff2 region may be different.

Alternatively, as in FIG. 13B, the transistor 490 may include only the Loff1 region without including the Loff2 region, for example. When the transistor 490 includes no Loff2 region, the on-state current and the short-channel effect are reduced. Note that a region where the conductor 416b and the conductor 404 overlap with each other is referred to as an Lov region. For example, the length of the Lov region is preferably shortened to 50 nm or less, 20 nm or less, or 10 nm or less, in which case degradation of switching characteristics of the transistor 490 due to parasitic capacitance hardly occurs.

Alternatively, the conductor 404 of the transistor 490 may have a taper angle as illustrated in FIG. 13C, for example. In that case, for example, the low-resistance region 423a and the low-resistance region 423b have slopes in the depth direction in some cases. Note that not only in FIG. 13C but also in another drawing, the conductor 404 may have a taper angle.

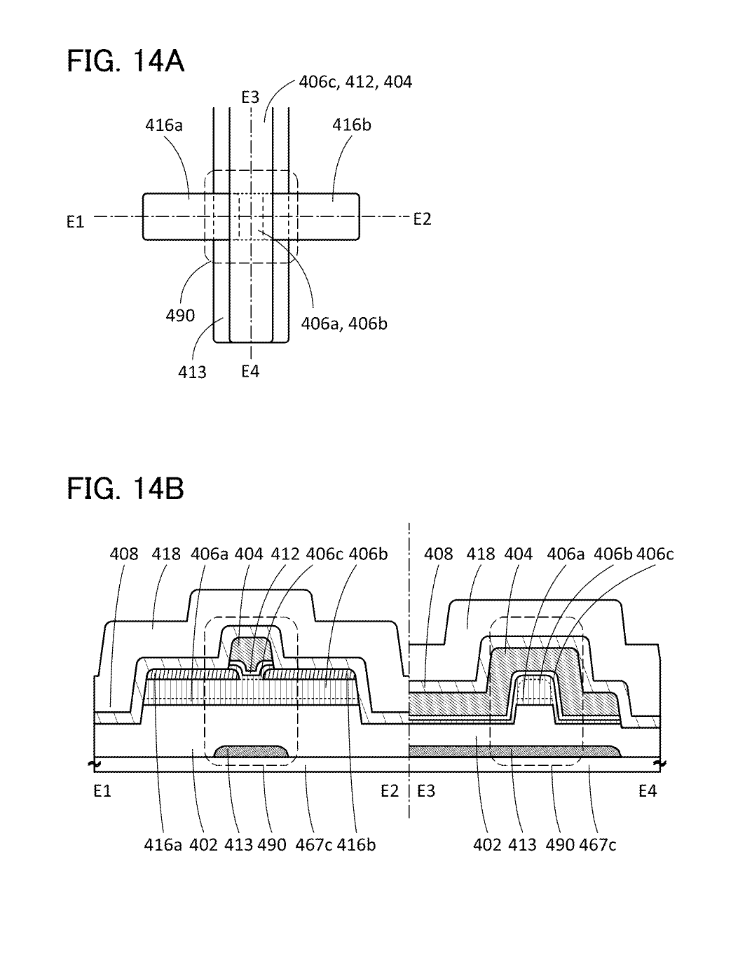

FIG. 14A is another example of the top view of the transistor 490. FIG. 14B is an example of a cross-sectional view taken along dashed-dotted line E1-E2 and dashed-dotted line E3-E4 in FIG. 14A. Note that some components such as an insulator are omitted in FIG. 14A for easy understanding.

Although FIG. 1 and the like show an example where the conductor 416a and the conductor 416b which function as a source electrode and a drain electrode are in contact with a top surface and a side surface of the semiconductor 406b, a top surface of the insulator 402, and the like, a transistor structure of one embodiment of the present invention is not limited thereto. For example, as illustrated in FIGS. 14A and 14B, the conductor 416a and the conductor 416b may be in contact with only the top surface of the semiconductor 406b.

In the transistor illustrated in FIGS. 14A and 14B, the conductor 416a and the conductor 416b are not in contact with side surfaces of the semiconductor 406b. Thus, an electric field applied from the conductor 404 functioning as a gate electrode to the side surfaces of the semiconductor 406b is less likely to be blocked by the conductor 416a and the conductor 416b. The conductor 416a and the conductor 416b are not in contact with a top surface of the insulator 402. Thus, excess oxygen (oxygen) released from the insulator 402 is not consumed to oxidize the conductor 416a and the conductor 416b. Accordingly, excess oxygen (oxygen) released from the insulator 402 can be efficiently used to reduce oxygen vacancies in the semiconductor 406b. In other words, the transistor having the structure illustrated in FIGS. 14A and 14B has excellent electrical characteristics such as a high on-state current, high field-effect mobility, a small subthreshold swing value, and high reliability.

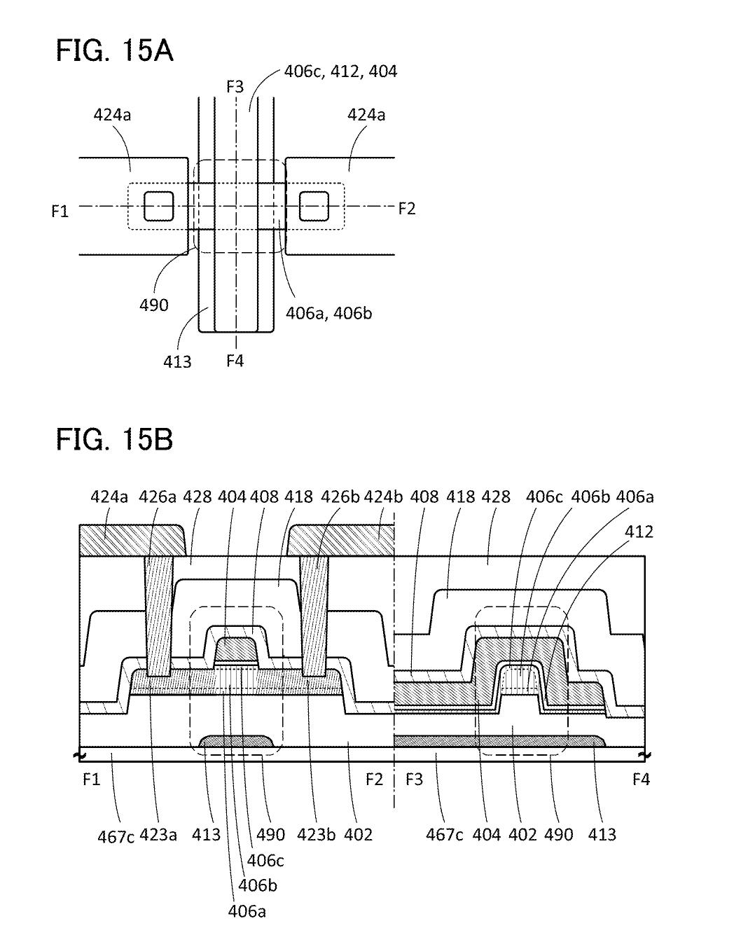

FIG. 15A is another example of the top view of the transistor 490. FIG. 15B is an example of a cross-sectional view taken along dashed-dotted line F1-F2 and dashed-dotted line F3-F4 in FIG. 15A. Note that some components such as an insulator are omitted in FIG. 15A for easy understanding.

The transistor 490 may have a structure in which, as illustrated in FIGS. 15A and 15B, the conductor 416a and the conductor 416b are not provided and the conductor 426a and the conductor 426b are in contact with the semiconductor 406b. In this case, the low-resistance region 423a (low-resistance region 423b) is preferably provided in a region in contact with at least the conductor 426a and the conductor 426b in the semiconductor 406b and/or the semiconductor 406a. The low-resistance region 423a and the low-resistance region 423b may be formed in such a manner that, for example, the conductor 404 and the like are used as masks and impurities are added to the semiconductor 406b and/or the semiconductor 406a. The conductor 426a and the conductor 426b may be provided in holes (portions which penetrate) or recessed portions (portions which do not penetrate) of the semiconductor 406b. When the conductor 426a and the conductor 426b are provided in holes or recessed portions of the semiconductor 406b, contact areas between the conductors 426a and 426b and the semiconductor 406b are increased; thus, the adverse effect of the contact resistance can be decreased. In other words, the on-state current of the transistor 490 can be increased.

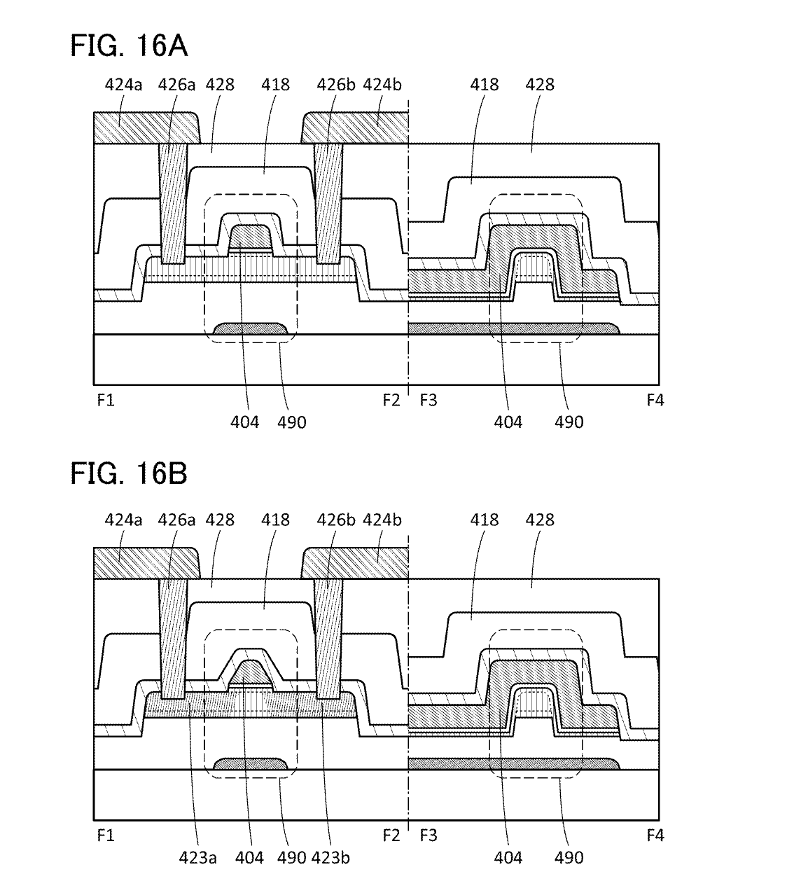

Alternatively, as in FIG. 16A, the transistor 490 does not necessarily include the low-resistance region 423a and the low-resistance region 423b, for example. When the transistor 490 does not include the low-resistance region 423a and the low-resistance region 423b, the on-state current might be decreased but the short-channel effect can be reduced. Note that regions in FIG. 15B corresponding to the low-resistance region 423a and the low-resistance region 423b (a region between the conductor 416a and the conductor 404 and a region between the conductor 416b and the conductor 404) are referred to as Loff regions. For example, the length of each of the Loff regions is set to 50 nm or less, 20 nm or less, or 10 nm or less, in which case the on-state current of the transistor 490 hardly decreases in some cases even when the transistor 490 does not include the low-resistance region 423a and the low-resistance region 423b.

Alternatively, the conductor 404 of the transistor 490 may have a taper angle as illustrated in FIG. 16B, for example. In that case, for example, the low-resistance region 423a and the low-resistance region 423b have slopes in the depth direction in some cases.

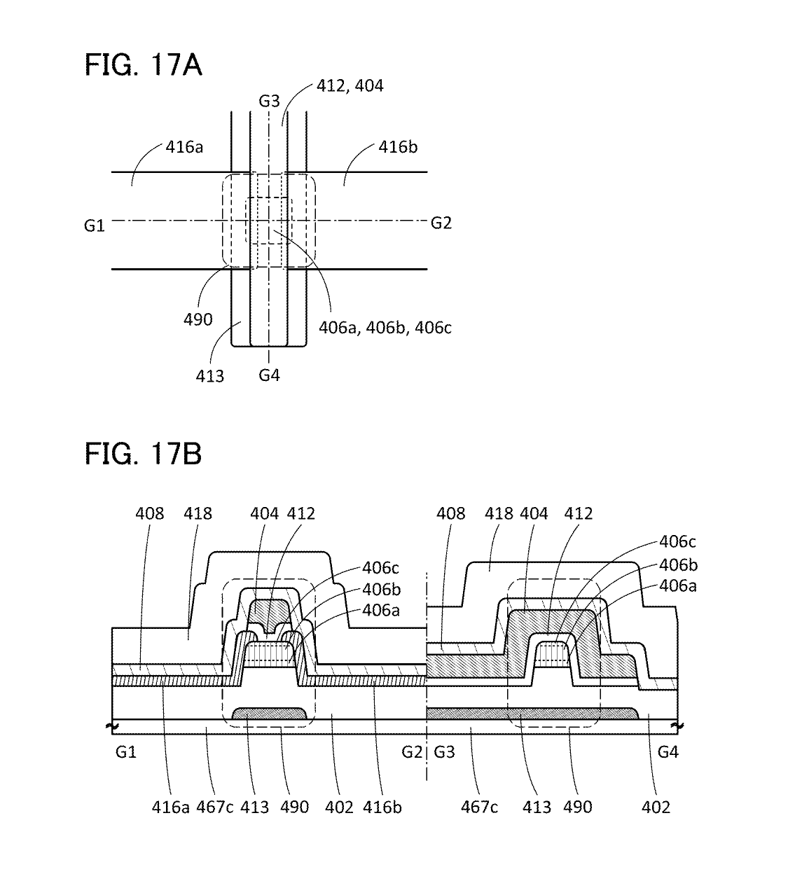

FIGS. 17A and 17B are a top view and a cross-sectional view of the transistor 490. FIG. 17A is the top view and FIG. 17B is the cross-sectional view taken along dashed-dotted line G1-G2 and dashed-dotted line G3-G4 in FIG. 17A. Note that for simplification of the drawing, some components are not illustrated in the top view of FIG. 17A.

The transistor 490 in FIGS. 17A and 17B includes the conductor 413 over the insulator 467c; the insulator 402 having a projection over the insulator 467c and the conductor 413; the semiconductor 406a over the projection of the insulator 402; the semiconductor 406b over the semiconductor 406a; the semiconductor 406c over the semiconductor 406b; the conductor 416a and the conductor 416b which are in contact with the semiconductor 406a, the semiconductor 406b, and the semiconductor 406c and which are arranged to be separated from each other; the insulator 412 over the semiconductor 406c, the conductor 416a, and the conductor 416b; the conductor 404 over the insulator 412; the insulator 408 over the conductor 416a, the conductor 416b, the insulator 412, and the conductor 404; and the insulator 418 over the insulator 408.

The insulator 412 is in contact with at least side surfaces of the semiconductor 406b in the cross section taken along line G3-G4. The conductor 404 is in contact with a top surface and the side surfaces of the semiconductor 406b with at least the insulator 412 provided therebetween in the cross section taken along line G3-G4. The conductor 413 faces a bottom surface of the semiconductor 406b with the insulator 402 provided therebetween. The insulator 402 does not necessarily include a projection. Furthermore, the semiconductor 406c, the insulator 408, or the insulator 418 is not necessarily provided.

The structure of the transistor 490 illustrated in FIGS. 17A and 17B is partly different from that of the transistor 490 in FIG. 1. Specifically, the structures of the semiconductors 406a to 406c of the transistor 490 illustrated in FIG. 1 are different from the structures of the semiconductors 406a to 406c of the transistor 490 in FIGS. 17A and 17B. Thus, for the transistor in FIGS. 17A and 17B, the description of the transistor in FIG. 1 can be referred to as appropriate.

Although FIGS. 17A and 17B show an example where the conductor 404 which is a first gate electrode of the transistor is not electrically connected to the conductor 413 which is a second gate electrode, a transistor structure of one embodiment of the present invention is not limited thereto. For example, the conductor 404 may be in contact with the conductor 413. With such a structure, the conductor 404 and the conductor 413 are supplied with the same potential; thus, switching characteristics of the transistor can be improved. Alternatively, the conductor 413 is not necessarily provided.

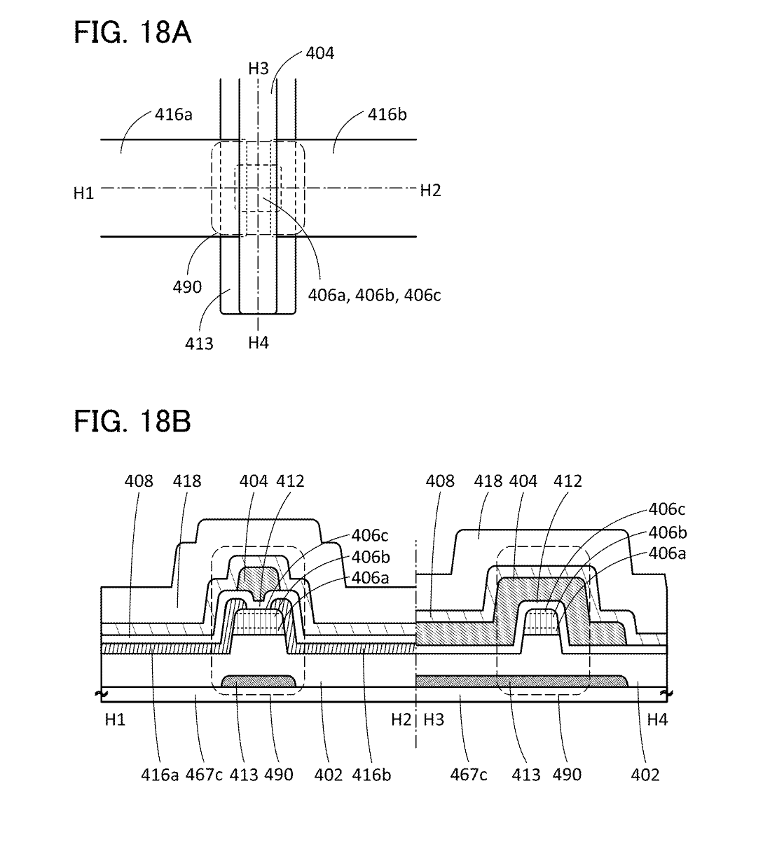

FIG. 18A is another example of the top view of the transistor. FIG. 18B is an example of a cross-sectional view taken along dashed-dotted line H1-H2 and dashed-dotted line H3-H4 in FIG. 18A. Note that some components such as an insulator are omitted in FIG. 18A for easy understanding.

Although an example where the insulator 412 and the conductor 404 have similar shapes in the top view in FIG. 17A is shown, a transistor structure of one embodiment of the present invention is not limited thereto. For example, as illustrated in FIGS. 18A and 18B, the insulator 412 may be provided over the insulator 402, the semiconductor 406c, the conductor 416a, and the conductor 416b.

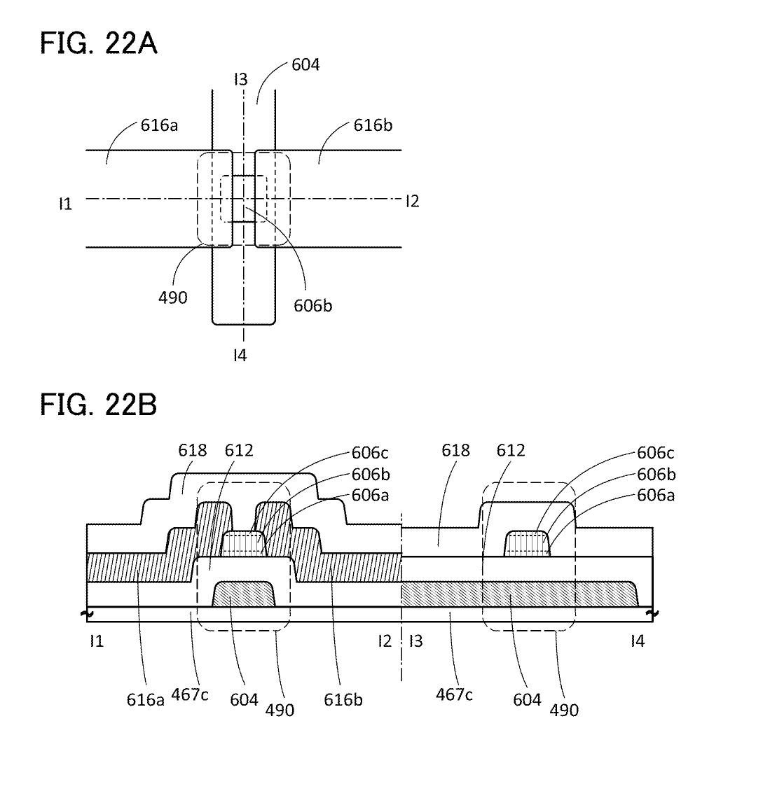

FIGS. 22A and 22B are a top view and a cross-sectional view of the transistor 490 in one embodiment of the present invention. FIG. 22A is the top view and FIG. 22B is the cross-sectional view taken along dashed-dotted line 11-12 and dashed-dotted line 13-14 in FIG. 22A. Note that for simplification of the drawing, some components are not illustrated in the top view of FIG. 22A.

The transistor 490 in FIGS. 22A and 22B includes a conductor 604 over the insulator 467c, an insulator 612 over the conductor 604, a semiconductor 606a over the insulator 612, a semiconductor 606b over the semiconductor 606a, a semiconductor 606c over the semiconductor 606b, a conductor 616a and a conductor 616b which are in contact with the semiconductor 606a, the semiconductor 606b, and the semiconductor 606c and which are arranged to be separated from each other, and an insulator 618 over the semiconductor 606c, the conductor 616a, and the conductor 616b. The conductor 604 faces a bottom surface of the semiconductor 606b with the insulator 612 provided therebetween. The insulator 612 may have a projection. The semiconductor 606a or the insulator 618 is not necessarily provided.

The semiconductor 606b serves as a channel formation region of the transistor 490. The conductor 604 serves as a first gate electrode (also referred to as a front gate electrode) of the transistor 490. The conductor 616a and the conductor 616b serve as a source electrode and a drain electrode of the transistor 490.

The insulator 618 is preferably an insulator containing excess oxygen.

For the conductor 604, the description of the conductor 404 is referred to. For the insulator 612, the description of the insulator 412 is referred to. For the semiconductor 606a, the description of the semiconductor 406c is referred to. For the semiconductor 606b, the description of the semiconductor 406b is referred to. For the semiconductor 606c, the description of the semiconductor 406a is referred to. For the conductor 616a and the conductor 616b, the description of the conductor 416a and the conductor 416b is referred to. For the insulator 618, the description of the insulator 402 is referred to.

Thus, the transistor 490 in FIGS. 22A and 22B can be regarded different from the transistor 490 in FIGS. 18A and 18B in only part of the structure in some cases. Specifically, the structure of the transistor 490 in FIGS. 22A and 22B is similar to the structure of the transistor 490 in FIGS. 18A and 18B in which the conductor 404 is not provided. Thus, for the transistor 490 in FIGS. 22A and 22B, the description of the transistor 490 in FIGS. 18A and 18B can be referred to as appropriate.

The transistor 490 may include a conductor that overlaps with the semiconductor 606b with the insulator 618 provided therebetween. The conductor functions as a second gate electrode of the transistor 490. For the conductor, the description of the conductor 413 is referred to. Furthermore, an s-channel structure may be formed using the second gate electrode.

Over the insulator 618, a display element may be provided. For example, a pixel electrode, a liquid crystal layer, a common electrode, a light-emitting layer, an organic EL layer, an anode electrode, a cathode electrode, or the like may be provided. The display element is connected to the conductor 616a or the like, for example.

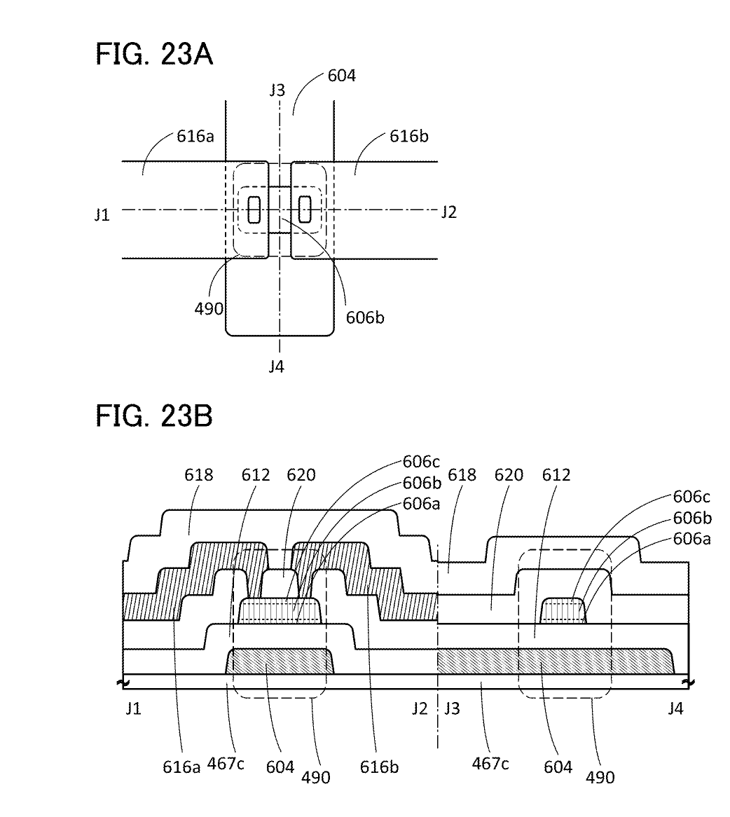

Over the semiconductor, an insulator that can function as a channel protective film may be provided. Alternatively, as illustrated in FIGS. 23A and 23B, an insulator 620 may be provided between the semiconductor 606c and the conductors 616a and 616b. In that case, the conductor 616a (conductor 616b) and the semiconductor 606c are connected to each other through an opening portion in the insulator 620. For the insulator 620, the description of the insulator 618 may be referred to.

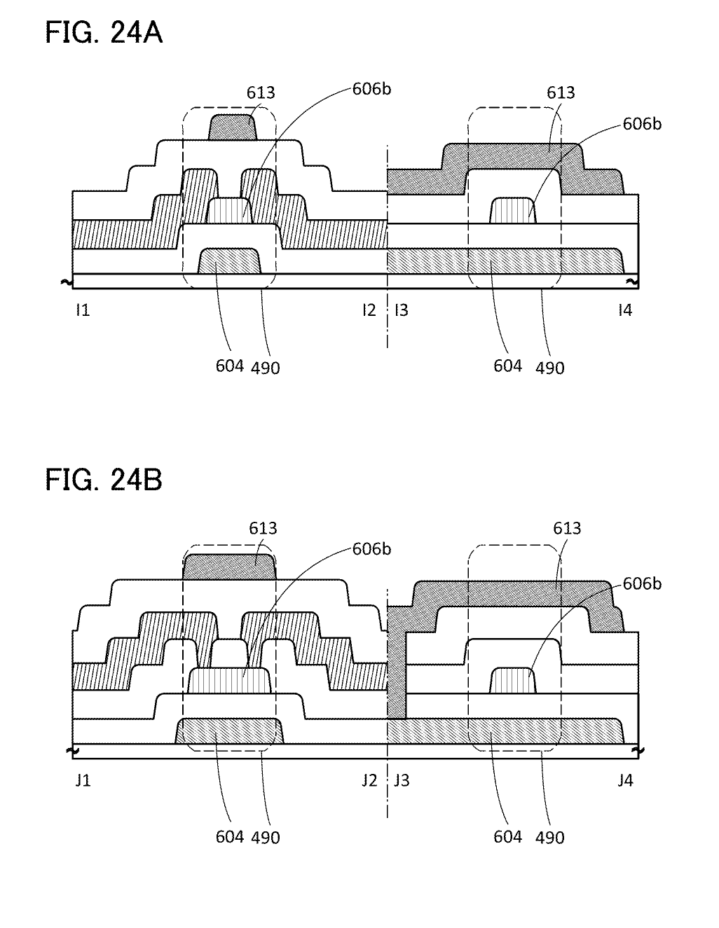

In FIG. 22B and FIG. 23B, a conductor 613 may be provided over the insulator 618. Examples in that case are shown in FIGS. 24A and 24B. For the conductor 613, the description of the conductor 413 is referred to. A potential or signal which is the same as that supplied to the conductor 604 or a potential or signal which is different from that supplied to the conductor 604 may be supplied to the conductor 613. For example, by supplying a constant potential to the conductor 613, the threshold voltage of the transistor 490 may be controlled. In other words, the conductor 613 can function as a second gate electrode.

### <Method of Manufacturing Semiconductor Device>

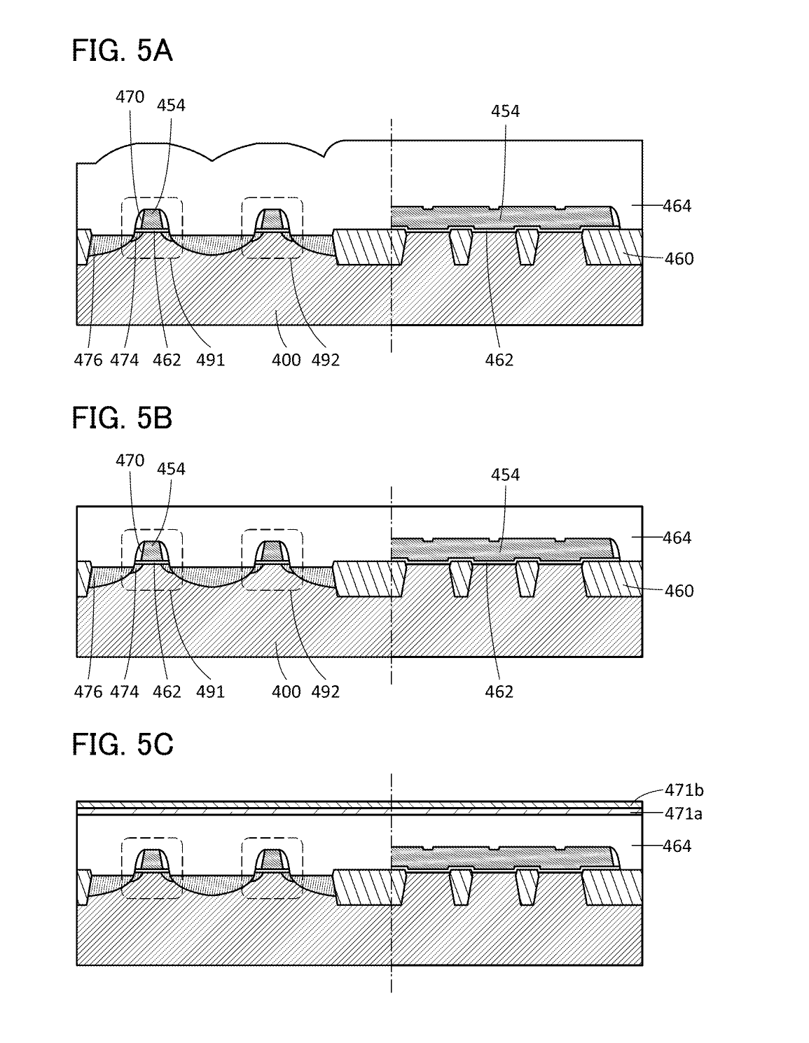

Next, a method of manufacturing the semiconductor device in FIG. 2 is described with reference to FIGS. 5A to 5C, FIGS. 6A to 6C, FIGS. 7A to 7C, and FIGS. 8A and 8B.

First, the transistors 491 and 492 are fabricated on the semiconductor substrate 400.

Next, the insulator 464 is deposited over the transistors 491 and 492 (see FIG. 5A). The insulator 464 can be deposited by a sputtering method, a CVD method, an MBE method, an ALD method, or a PLD method, for example. In particular, it is preferable that the insulator 464 be formed by a CVD method, further preferably a plasma CVD method because coverage can be further improved. To reduce plasma damage, a thermal CVD method, an MOCVD method, or an ALD method is preferably used.

Next, a surface of the insulator 464 is planarized (see FIG. 5B). As planarization treatment, for example, a CMP method is employed.

Next, heat treatment is performed. The heat treatment can be performed, for example, at a temperature higher than or equal to 400° C. and lower than the strain point of the substrate in an inert gas atmosphere such as a rare gas atmosphere or a nitrogen gas atmosphere or in a reduced-pressure atmosphere. The heat treatment enables hydrogen released from the insulator 464 to terminate dangling bonds in a semiconductor layer of the transistors 491 and 492, for example. Further, the heat treatment allows water and hydrogen to be released from the layers, which reduces the water content and the hydrogen content. The thorough removal of hydrogen and water contained in the layers below the insulator 471a before formation of the insulator 471a can reduce diffusion of water and hydrogen to the layers above the insulator 471a in a later step.

Next, the insulator 471a is deposited over the insulator 464. Then, the insulator 471b is deposited over the insulator 471a (see FIG. 5C). For the deposition of the insulators 471a and 471b, refer to the description of the deposition of the insulators 471a and 471b in Embodiment 1.

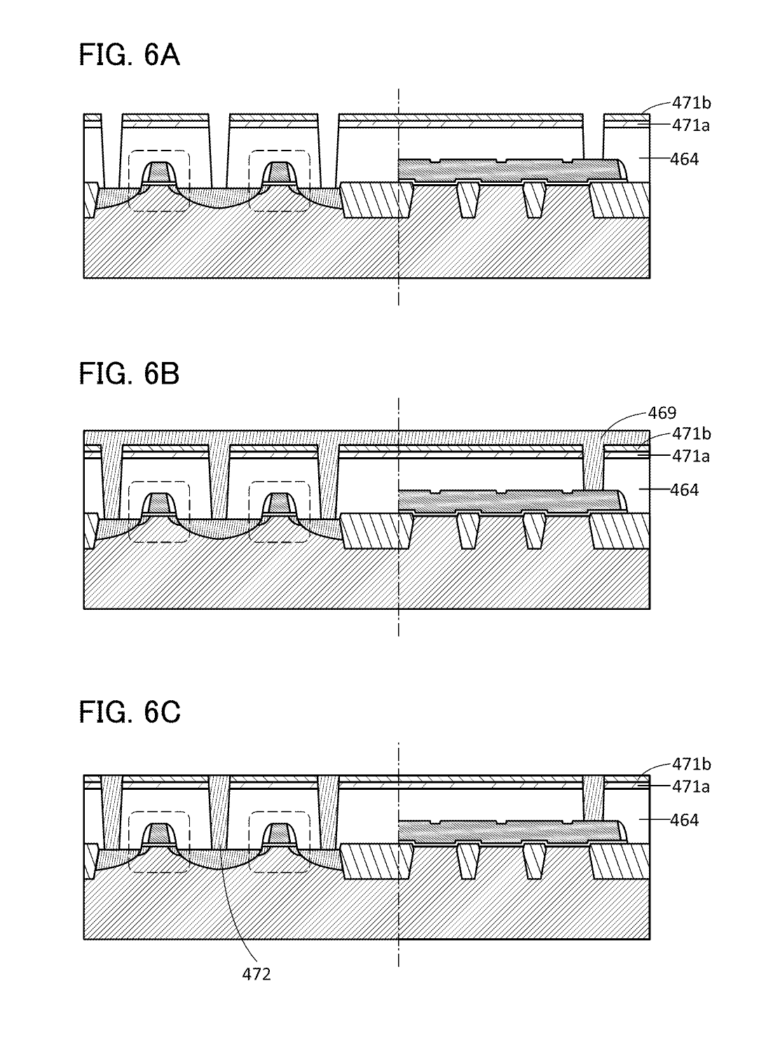

Next, opening portions are provided in the insulators 464, 471a, and 471b (see FIG. 6A). In the opening portions, preferably, the conductor 454, the region 476, and the like included in the transistor 490 and the like are exposed. To form the opening portion, for example, a mask is formed by a lithography method or the like, an unnecessary portion is removed by dry etching or the like, and then the mask is removed. As the mask, a hard mask formed of an inorganic film or a metal film may be used.

Next, the conductor 469 is deposited in the opening portions and over the insulator 471b (see FIG. 6B). For a material that can be used as a conductive film, refer to the description of the conductor 469 in Embodiment 1. For a deposition method of the conductor 469, refer to the description of the deposition method of the conductor 469 in Embodiment 1.

Next, part of the conductor 469 is removed to form the conductor 472 and the like with an upper surface parallel to a bottom surface of the semiconductor substrate 400, or the surface of the conductor 469 is planarized; thus, the insulator 471b is exposed and the conductor 472 and the like are formed (see FIG. 6C). For the removal of the conductor 469, refer to Embodiment 1.

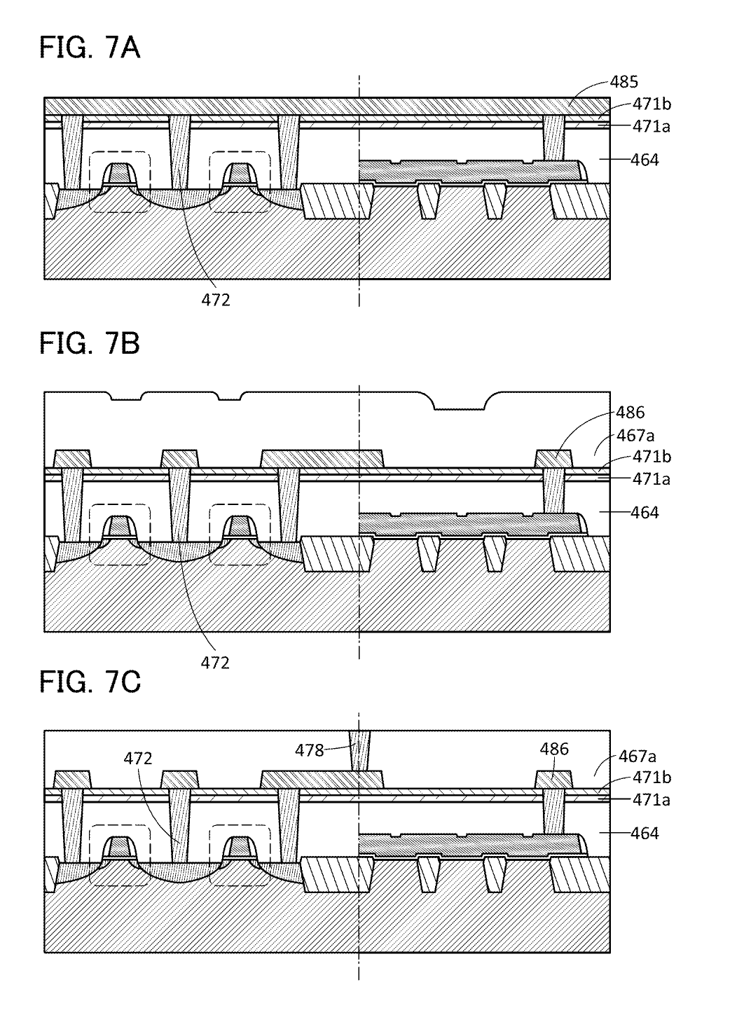

Next, a conductor 485 is deposited over the insulator 471b, the conductor 472, and the like (see FIG. 7A). For the conductor 485, for example, the material described for the conductor 469 can be used.

Next, a mask is formed over the conductor 485 by a lithography method or the like.

Next, unnecessary portions of the conductor 485 are removed, and the mask is removed, whereby the conductor 486 is formed. Next, the insulator 467a is deposited (see FIG. 7B).

Next, a surface of the insulator 467a is planarized. Then, an opening portion is provided in the insulator 467a, and a conductor to be the conductor 478 is formed in the opening portion and over the insulator 467a. The conductor 478 fills the opening portion in the insulator 467a. For the material and deposition method of the conductor to be the conductor 478, refer to the description of the conductor 485. Then, by a polishing method such as a CMP method, part of the conductor to be the conductor 478 is removed to expose the insulator 467a, so that the conductor 478 and the like can be formed (see FIG. 7C).

Next, the conductor 487 and the like are formed over the insulator 467a, the conductor 478, and the like. The conductor 487 and the like can be formed by a method similar to that of the conductor 486. Next, the insulator 467c is deposited over the insulator 467a and the conductor 487. For the insulator 467c, for example, silicon oxide, silicon oxynitride, or the like can be used. The insulator 467c can be formed by a sputtering method, a CVD method (including a thermal CVD method, an MOCVD method, a PECVD method, and the like), an MBE method, an ALD method, a PLD method, or the like.

Next, the insulator 467a is planarized. Next, the insulators 481a and 481b are deposited over the insulator 467c. For the insulator 481a, refer to the description of the insulator 471a. For the insulator 481b, refer to the description of the insulator 471b.

Next, an opening portion reaching the conductor 487 and the like is provided in the insulators 467c, 481a, and 481b. In the opening portion, the conductor 479 and the like are formed. For the formation of the conductor 479 and the like, a method similar to that of the conductor 472 can be used.

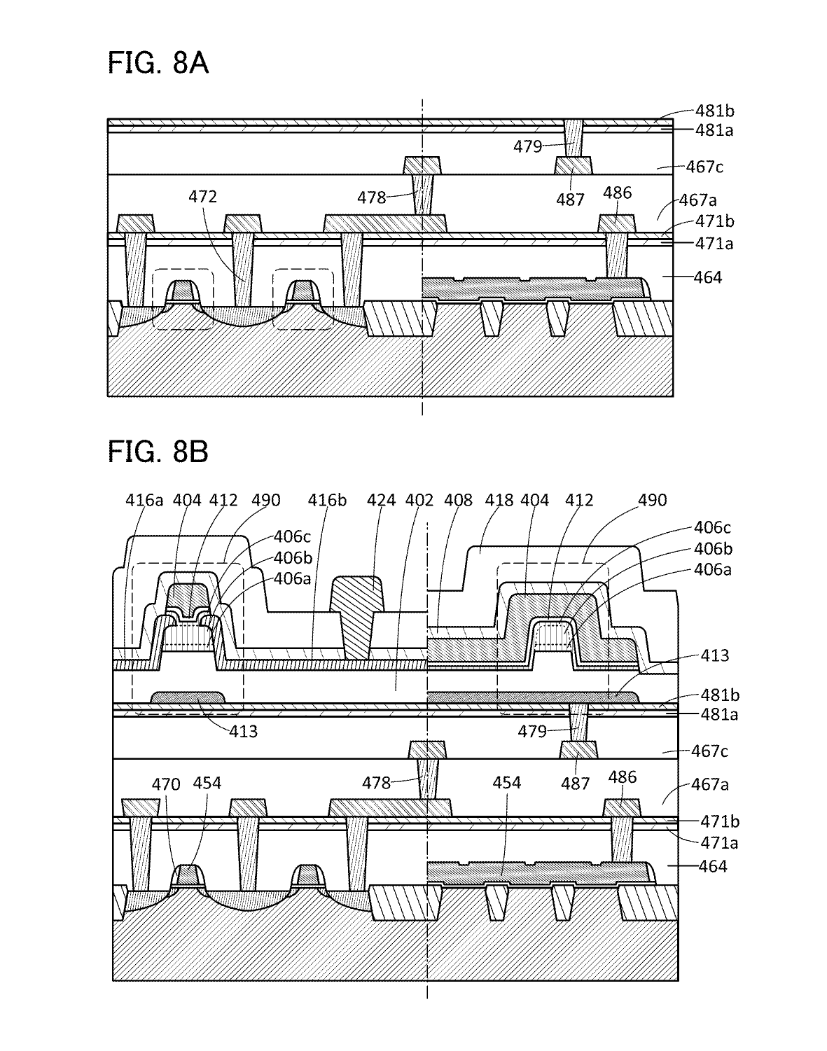

Next, the transistor 490 is formed. As the transistor 490, the transistor 490 in FIGS. 9A and 9B can be used. Next, the insulator 418 is deposited over the transistor 490. Next, an opening portion reaching the conductor 416b and the like is provided in the insulator 418, and the conductor 424 and the like are formed in the opening portion (see FIG. 8B). Through the above steps, the semiconductor device illustrated in FIG. 2 can be fabricated.

### <Method of Fabricating Transistor>

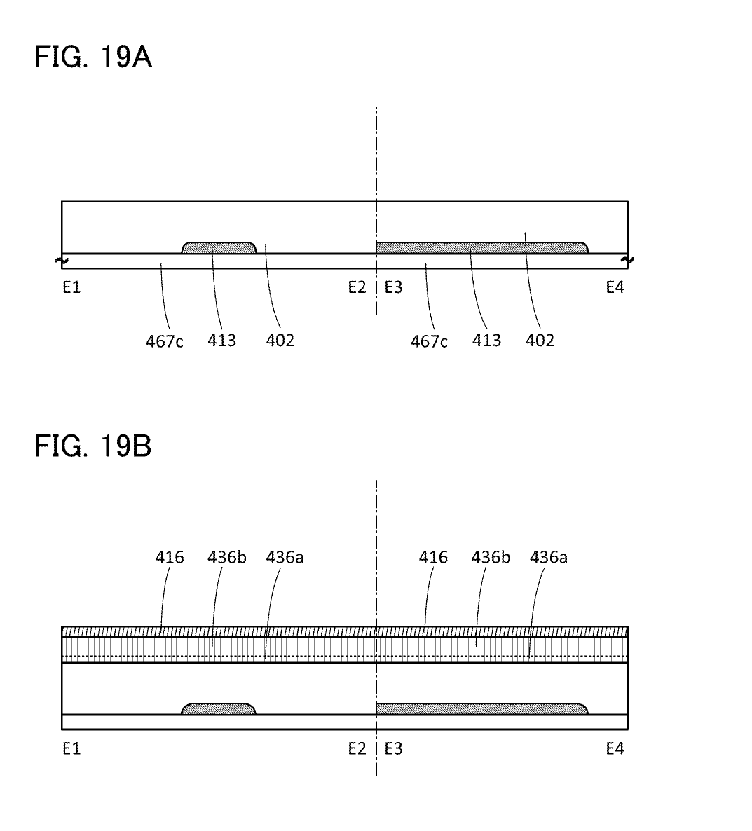

Next, a method of fabricating the transistor 490 is described. Here, a method of fabricating the transistor illustrated in FIGS. 14A and 14B is described using FIGS. 19A and 19B, FIGS. 20A and 20B, and FIGS. 21A to 21C2.

A conductor to be the conductor 413 is deposited over an insulator. As the insulator, for example, the insulator 467c illustrated in FIG. 1 or stacked layers of the insulators 467c, 481a, and 481b illustrated in FIG. 2 can be used. Although the transistor 490 is formed over the insulator 467c in the example below, the insulator is not limited to the insulator 467c.

The conductor to be the conductor 413 can be deposited by a sputtering method, a CVD method, an MBE method, a PLD method, an ALD method, or the like.

Next, part of the conductor to be the conductor 413 is etched, so that the conductor 413 is formed.

Next, the insulator 402 is deposited (see FIG. 19A). The insulator 402 may be deposited by a sputtering method, a CVD method, an MBE method, a PLD method, an ALD method, or the like. Note that here, the case where the top surface of the insulator 402 is planarized by a CMP method or the like is described. By planarizing the top surface of the insulator 402, the subsequent steps can be performed easily, and the yield of the transistor 490 can be increased. For example, by a CMP method, the RMS roughness of the insulator 402 is less than or equal to 1 nm, preferably less than or equal to 0.5 nm, more preferably less than or equal to 0.3 nm. The average surface roughness (Ra) with the measurement area of 1 μm×1 μm is less than 1 nm, preferably less than 0.6 nm, more preferably less than 0.5 nm, still more preferably less than 0.4 nm. The maximum difference (P−V) with the measurement area of 1 μm×1 μm is less than 10 nm, preferably less than 9 nm, more preferably less than 8 nm, still more preferably less than 7 nm. The transistor 490 in one embodiment of the present invention is not limited to a transistor when the top surface of the insulator 402 is planarized.

The insulator 402 may be deposited to contain excess oxygen. Alternatively, oxygen may be added after the insulator 402 is deposited. The addition of oxygen may be performed by an ion implantation method at an acceleration voltage higher than or equal to 2 kV and lower than or equal to 100 kV and at a dose greater than or equal to 5×10¹⁴ ions/cm² and less than or equal to 5×10¹⁶ ions/cm², for example.

Note that in the case where the insulator 402 is a stacked film, films in the stacked film may be formed using by different methods such as the above formation methods. For example, the first film may be formed by a CVD method and the second film may be formed by an ALD method. Alternatively, the first film may be formed by a sputtering method and the second film may be formed by an ALD method. When films are formed by different methods as described above, the films can have different functions or different properties. Furthermore, by stacking the films, a more appropriate film can be formed as a stacked film.

In other words, an n-th film (n is a natural number) is formed by at least one of a sputtering method, a CVD method, an MBE method, a PLD method, an ALD method, and the like, and an n+1-th film is formed by at least one of a sputtering method, a CVD method, an MBE method, a PLD method, an ALD method, and the like. Note that the n-th film and the n+1-th film may be formed by the same method or different methods. Note that the n-th film and the n+2-th film may be formed by the same method. Alternatively, all the films may be formed by the same method.

Next, a semiconductor 436a to be the semiconductor 406a and a semiconductor 436b to be the semiconductor 406b are formed in this order. The semiconductor to be the semiconductor 406a and the semiconductor to be the semiconductor 406b may be deposited by a sputtering method, a CVD method, an MBE method, a PLD method, an ALD method, or the like.

In the case where In—Ga-Zn oxide layers are formed as the semiconductor 436a and the semiconductor 436b by an MOCVD method, trimethylindium, trimethylgallium, dimethylzinc, and the like may be used as the source gases. The source gas is not limited to the combination of these gases, triethylindium or the like may be used instead of trimethylindium. Triethylgallium or the like may be used instead of trimethylgallium. Diethylzinc or the like may be used instead of dimethylzinc.

Next, first heat treatment is preferably performed. The first heat treatment is performed at a temperature higher than or equal to 250° C. and lower than or equal to 650° C., preferably higher than or equal to 300° C. and lower than or equal to 500° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, crystallinity of the semiconductor 436a and crystallinity of the semiconductor 436b can be increased and impurities such as hydrogen and water can be removed.

Next, a conductor 416 is deposited (see FIG. 19B). The conductor 416 may be deposited by a sputtering method, a CVD method, an MBE method, a PLD method, an ALD method, or the like.

The conductor 416a and the conductor 416b are formed in such a manner that the conductor 416 is deposited and then partly etched. Therefore, it is preferable to employ a deposition method by which the semiconductor 406b is not damaged when the conductor 416 is deposited. In other words, the conductor 416 is preferably deposited by an MCVD method or the like.

Note that in the case where the conductor 416 is formed to have a stacked-layer structure, films in the stacked film may be formed by different methods such as a CVD method (a plasma CVD method, a thermal CVD method, an MCVD method, an MOCVD method, or the like), an MBE method, a PLD method, and an ALD method. For example, the first film may be formed by an MOCVD method and the second film may be formed by a sputtering method. Alternatively, the first film may be formed by an ALD method and the second film may be formed by an MOCVD method. Alternatively, the first film may be formed by an ALD method and the second film may be formed by a sputtering method. Alternatively, the first film may be formed by an ALD method, the second film may be formed by a sputtering method, and the third film may be formed by an ALD method. When films are formed by different methods as described above, the films can have different functions or different properties. Furthermore, by stacking the films, a more appropriate film can be formed as a stacked film.

In other words, in the case where the conductor 416 is a stacked film, for example, an n-th film (n is a natural number) is formed by at least one of a CVD method (a plasma CVD method, a thermal CVD method, an MCVD method, an MOCVD method, or the like), an MBE method, a PLD method, an ALD method, and the like and an n+1-th film is formed by at least one of a CVD method (a plasma CVD method, a thermal CVD method, an MCVD method, an MOCVD method, or the like), an MBE method, a PLD method, an ALD method, and the like. Note that the n-th film and the n+1-th film may be formed by different methods. Note that the n-th film and the n+2-th film may be formed by the same method. Alternatively, all the films may be formed by the same method.

Note that the conductor 416 or at least one of the films in the stacked film of the conductor 416 and the semiconductor to be the semiconductor 406a or the semiconductor to be the semiconductor 406b may be deposited by the same method. For example, both of them may be deposited by an ALD method. Thus, they can be formed without exposure to the air. As a result, entry of impurities can be prevented.

Note that the conductor 416 or at least one of the films in the stacked film of the conductor 416, the semiconductor to be the semiconductor 406a or the semiconductor to be the semiconductor 406b, and the insulator 402 or at least one of the films in the stacked film of the insulator 402 may be deposited by the same method. For example, all of them may be deposited by a sputtering method. Thus, they can be formed without exposure to the air. As a result, entry of impurities can be prevented. Note that the method of manufacturing a semiconductor device of one embodiment of the present invention is not limited thereto.

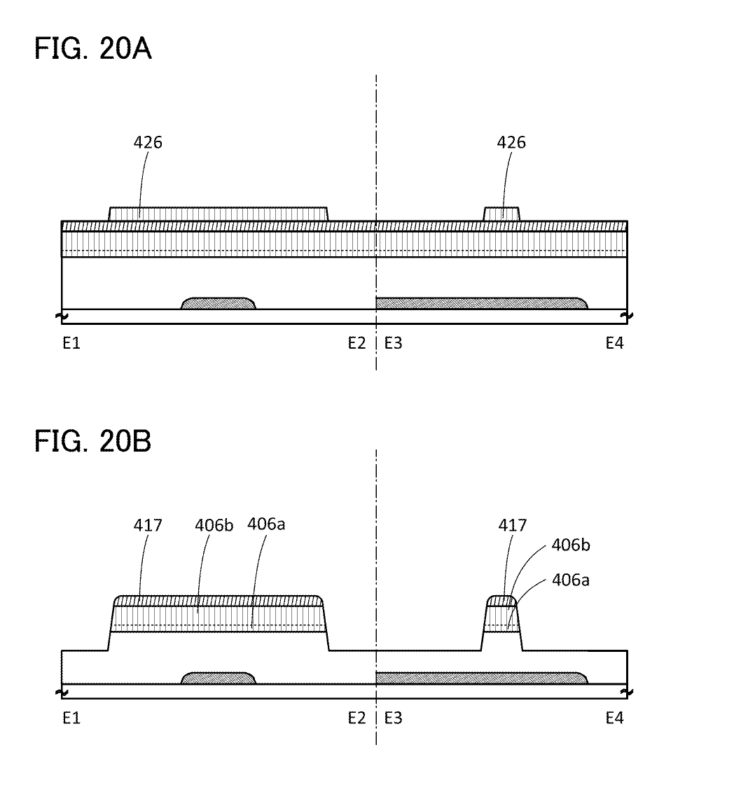

Next, a mask 426 is formed (see FIG. 20A). For the mask 426, a photoresist may be used. Note that for the mask 426, a bottom anti-reflective coating (BARC) film may be provided as a base of a photoresist. When the bottom anti-reflective coating film is provided, defects due to halation can be suppressed and a minute shape can be obtained.

Next, the conductor 416 is etched using the mask 426, whereby a conductor 417 is formed. To form the conductor 417 having a minute shape, the mask 426 having a minute shape needs to be formed. When the mask 426 having a minute shape is too thick, the mask might fall down; therefore, the mask 426 preferably includes a region with a thickness small enough to be self-standing. The conductor 416 to be etched using the mask 426 preferably has a thickness small enough to be etched under conditions that the mask 426 can withstand. Since the conductor 416 becomes the conductor 416a and the conductor 416b serving as the source electrode and the drain electrode of the transistor 490, the conductor 416 preferably has a certain thickness such that the on-state current of the transistor 490 is high. Accordingly, the conductor 416 includes a region with a thickness, for example, greater than or equal to 5 nm and less than or equal to 30 nm, preferably greater than or equal to 5 nm and less than or equal to 20 nm, more preferably greater than or equal to 5 nm and less than or equal to 15 nm.

Next, the semiconductor 436a and the semiconductor 436b are etched using the conductor 417 as a mask, so that the semiconductor 406a and the semiconductor 406b are formed. At this time, when the insulator 402 is etched, an s-channel structure is likely to be formed (see FIG. 20B).

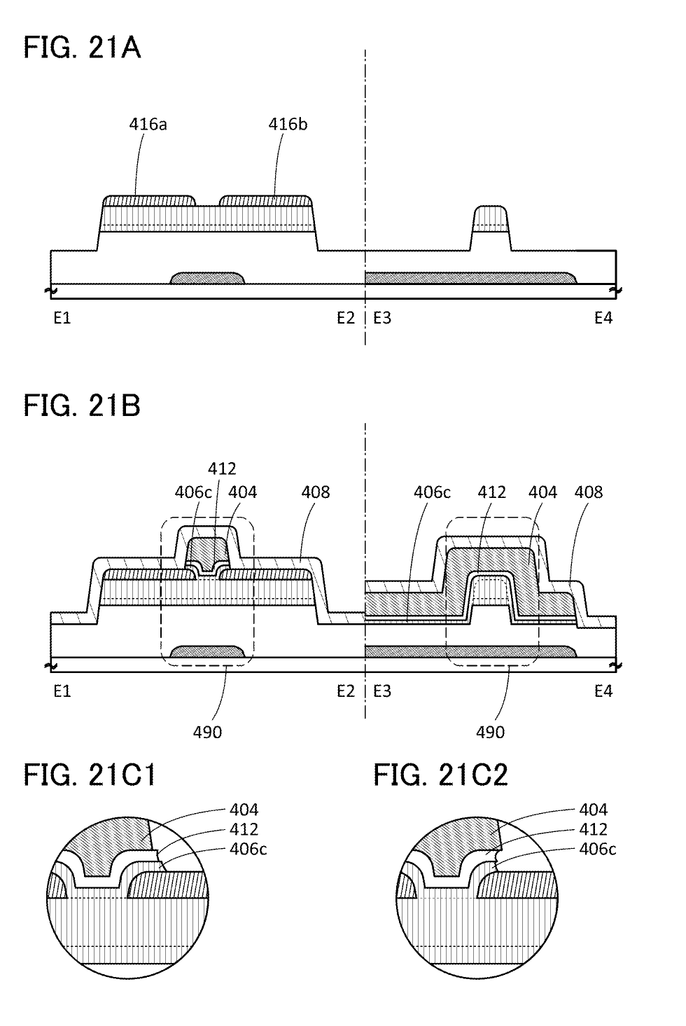

Next, part of the conductor 417 is etched, so that the conductor 416a and the conductor 416b are formed (see FIG. 21A). As described above, the conductor 416 formed as a mask for etching the semiconductor 436a and the semiconductor 436b becomes the conductor 416a and the conductor 416b serving as the source electrode and the drain electrode of the transistor 490. Since the conductor 416 to be the conductor 416a and the conductor 416b is also used as a mask, the number of steps for fabricating the transistor 490 can be reduced. The transistor 490 has a structure suitable for a miniaturized semiconductor device because the area occupied by the conductor 416a and the conductor 416b can be small.

Next, a semiconductor to be the semiconductor 406c is formed. The semiconductor to be the semiconductor 406c can be deposited by a sputtering method, a CVD method, an MBE method, a PLD method, an ALD method, or the like.

In the case where an In—Ga-Zn oxide layer is formed as the semiconductor to be the semiconductor 406c by an MOCVD method, trimethylindium, trimethylgallium, dimethylzinc, or the like may be used as the source gases. The source gas is not limited to the above combination of these gases, triethylindium or the like may be used instead of trimethylindium. Triethylgallium or the like may be used instead of trimethylgallium. Diethylzinc or the like may be used instead of dimethylzinc.

Next, second heat treatment may be performed. For example, as the semiconductor 406a, a semiconductor whose oxygen-transmitting property is higher than that of the semiconductor to be the semiconductor 406c is selected. That is, as the semiconductor to be the semiconductor 406c, a semiconductor whose oxygen-transmitting property is lower than that of the semiconductor 406a is selected. In other words, as the semiconductor 406a, a semiconductor having a function of passing oxygen is selected. As the semiconductor to be the semiconductor 406c, a semiconductor having a function of blocking oxygen is selected. In this case, by the second heat treatment, excess oxygen in the insulator 402 is moved to the semiconductor 406b through the semiconductor 406a. The semiconductor 406b is covered with the semiconductor to be the semiconductor 406c; thus, outward diffusion of excess oxygen is less likely to occur. Therefore, by performing the second heat treatment at this time, defects (oxygen vacancies) in the semiconductor 406b can be efficiently reduced. Note that the second heat treatment may be performed at a temperature such that excess oxygen (oxygen) in the insulator 402 is diffused to the semiconductor 406b. For example, the description of the first heat treatment may be referred to. The second heat treatment is preferably performed at a temperature lower than that of the first heat treatment. The difference between the temperature of the first heat treatment and that of the second heat treatment is higher than or equal to 20° C. and lower than or equal to 150° C., preferably higher than or equal to 40° C. and lower than or equal to 100° C. Accordingly, superfluous release of excess oxygen (oxygen) from the insulator 402 can be inhibited.

Next, an insulator to be the insulator 412 is deposited. The insulator to be the insulator 412 may be deposited by a sputtering method, a CVD method, an MBE method, a PLD method, an ALD method, or the like.

Note that in the case where the insulator to be the insulator 412 is formed to have a stacked-layer structure, films in the stacked film may be formed by different methods such as a CVD method (a plasma CVD method, a thermal CVD method, an MCVD method, an MOCVD method, or the like), an MBE method, a PLD method, and an ALD method. For example, the first film may be formed by an MOCVD method and the second film may be formed by a sputtering method. Alternatively, the first film may be formed by an ALD method and the second film may be formed by an MOCVD method. Alternatively, the first film may be formed by an ALD method and the second film may be formed by a sputtering method. Alternatively, the first film may be formed by an ALD method, the second film may be formed by a sputtering method, and the third film may be formed by an ALD method. When films are formed by different methods as described above, the films can have different functions or different properties. Furthermore, by stacking the films, a more appropriate film can be formed as a stacked film.

In other words, in the case where the insulator to be the insulator 412 is a stacked film, for example, an n-th film (n is a natural number) is formed by at least one of a CVD method (a plasma CVD method, a thermal CVD method, an MCVD method, an MOCVD method, or the like), an MBE method, a PLD method, an ALD method, and the like and an n+1-th film is formed by at least one of a CVD method (a plasma CVD method, a thermal CVD method, an MCVD method, an MOCVD method, or the like), an MBE method, a PLD method, an ALD method, and the like. Note that the n-th film and the n+1-th film may be formed by different methods. Note that the n-th film and the n+2-th film may be formed by the same method. Alternatively, all the films may be formed by the same method.

Next, third heat treatment may be performed. For example, as the semiconductor 406a, a semiconductor whose oxygen-transmitting property is higher than that of the semiconductor to be the semiconductor 406c is selected. That is, as the semiconductor to be the semiconductor 406c, a semiconductor whose oxygen-transmitting property is lower than that of the semiconductor 406a. As the semiconductor to be the semiconductor 406c, a semiconductor having a function of blocking oxygen is selected. For example, as the semiconductor 406a, a semiconductor whose oxygen-transmitting property is higher than that of the insulator to be the insulator 412 is selected. That is, as the insulator to be the insulator 412, a semiconductor whose oxygen-transmitting property is lower than that of the semiconductor 406a is selected. In other words, as the semiconductor 406a, a semiconductor having a function of passing oxygen is selected. As the insulator to be the insulator 412, an insulator having a function of blocking oxygen is selected. In this case, by the third heat treatment, excess oxygen in the insulator 402 is moved to the semiconductor 406b through the semiconductor 406a. The semiconductor 406b is covered with the semiconductor to be the semiconductor 406c and the insulator to be the insulator 412; thus, outward diffusion of excess oxygen is less likely to occur. Therefore, by performing the third heat treatment at this time, defects (oxygen vacancies) in the semiconductor 406b can be efficiently reduced. Note that the third heat treatment may be performed at a temperature such that excess oxygen (oxygen) in the insulator 402 is diffused to the semiconductor 406b. For example, the description of the first heat treatment may be referred to. The third heat treatment is preferably performed at a temperature lower than that of the first heat treatment. The difference between the temperature of the first heat treatment and that of the third heat treatment is higher than or equal to 20° C. and lower than or equal to 150° C., preferably higher than or equal to 40° C. and lower than or equal to 100° C. Accordingly, superfluous release of excess oxygen (oxygen) from the insulator 402 can be inhibited. Note that in the case where the insulator to be the insulator 412 has a function of blocking oxygen, the semiconductor to be the semiconductor 406c does not necessarily have a function of blocking oxygen.

Next, a conductor to be the conductor 404 is deposited. The conductor to be the conductor 404 may be deposited by a sputtering method, a CVD method, an MBE method, a PLD method, an ALD method, or the like.

The insulator to be the insulator 412 functions as the gate insulator of the transistor 490. Therefore, the conductor to be the conductor 404 is preferably formed by a deposition method by which the insulator to be the insulator 412 is not damaged when the conductor to be the conductor 404 is deposited. In other words, the conductor is preferably deposited by an MCVD method or the like.

Note that in the case where the conductor to be the conductor 404 is formed to have a stacked-layer structure, films in the stacked film may be formed by different methods such as a CVD method (a plasma CVD method, a thermal CVD method, an MCVD method, an MOCVD method, or the like), an MBE method, a PLD method, and an ALD method. For example, the first film may be formed by an MOCVD method and the second film may be formed by a sputtering method. Alternatively, the first film may be formed by an ALD method and the second film may be formed by an MOCVD method. Alternatively, the first film may be formed by an ALD method and the second film may be formed by a sputtering method. Alternatively, the first film may be formed by an ALD method, the second film may be formed by a sputtering method, and the third film may be formed by an ALD method. When films are formed by different methods as described above, the films can have different functions or different properties. Furthermore, by stacking the films, a more appropriate film can be formed as a stacked film.

In other words, in the case where the conductor to be the conductor 404 is a stacked film, for example, an n-th film (n is a natural number) is formed by at least one of a CVD method (a plasma CVD method, a thermal CVD method, an MCVD method, an MOCVD method, or the like), an MBE method, a PLD method, an ALD method, and the like and an n+1-th film is formed by at least one of a CVD method (a plasma CVD method, a thermal CVD method, an MCVD method, an MOCVD method, or the like), an MBE method, a PLD method, an ALD method, and the like. Note that the n-th film and the n+1-th film may be formed by different methods. Note that the n-th film and the n+2-th film may be formed by the same method. Alternatively, all the films may be formed by the same method.

Note that the conductor to be the conductor 404 or at least one of the films in the stacked film of the conductor to be the conductor 404 and the insulator to be the insulator 412 or at least one of the films in the stacked film of the insulator to be the insulator 412 may be deposited by the same method. For example, both of them may be deposited by an ALD method. Thus, they can be formed without exposure to the air. As a result, entry of impurities can be prevented. For example, the conductor to be the conductor 404 and the insulator to be the insulator 412 which are in contact with each other may be deposited by the same method. Thus, the deposition can be performed in the same chamber. As a result, entry of impurities can be prevented.

Note that the conductor to be the conductor 404 or at least one of the films in the stacked film of the conductor to be the conductor 404 and the insulator to be the insulator 412 or at least one of the films in the stacked film of the insulator to be the insulator 412 may be deposited by the same method. For example, all of them may be deposited by a sputtering method. Thus, they can be formed without exposure to the air. As a result, entry of impurities can be prevented.

Next, the conductor to be the conductor 404 is partly etched, so that the conductor 404 is formed. The conductor 404 is formed to overlap with at least part of the semiconductor 406b.

Next, in a manner similar to that of the conductor to be the conductor 404, the insulator to be the insulator 412 is partly etched, so that the insulator 412 is formed.

Next, in a manner similar to those of the conductor to be the conductor 404 and the insulator to be the insulator 412, the semiconductor to be the semiconductor 406c is partly etched, so that the semiconductor 406c is formed.

The conductor to be the conductor 404, the insulator to be the insulator 412, and the semiconductor to be the semiconductor 406c may be partly etched through the same photolithography process, for example. Alternatively, the insulator to be the insulator 412 and the semiconductor to be the semiconductor 406c may be etched using the conductor 404 as a mask. Thus, the conductor 404, the insulator 412, and the semiconductor 406c have similar shapes in the top view. The insulator 412 and/or the semiconductor 406c may project as compared with the conductor 404 as illustrated in FIG. 21 C1 or the conductor 404 may project as compared with the insulator 412 and/or the semiconductor 406c as illustrated in FIG. 21C2. With such a shape, shape defects are reduced and gate leakage current can be reduced in some cases.

Next, the insulator 408 is deposited (see FIG. 21B). The insulator 408 may be deposited by a sputtering method, a CVD method, an MBE method, a PLD method, an ALD method, or the like.

Next, fourth heat treatment may be performed. For example, as the semiconductor 406a, a semiconductor whose oxygen-transmitting property is higher than that of the semiconductor 406c is selected. In other words, as the semiconductor 406c, a semiconductor whose oxygen-transmitting property is lower than that of the semiconductor 406a is selected. As the semiconductor 406c, a semiconductor having a function of blocking oxygen is selected. For example, as the semiconductor 406a, a semiconductor whose oxygen-transmitting property is higher than that of the insulator 412 is selected. In other words, as the insulator 412, a semiconductor whose oxygen-transmitting property is lower than that of the semiconductor 406a is selected. For example, as the semiconductor 406a, a semiconductor whose oxygen-transmitting property is higher than that of the insulator 408 is selected. That is, as the insulator 408, a semiconductor whose oxygen-transmitting property is lower than that of the semiconductor 406a is selected. In other words, as the semiconductor 406a, a semiconductor having a function of passing oxygen is selected. As the insulator 408, an insulator having a function of blocking oxygen is selected. In this case, by the fourth heat treatment, excess oxygen in the insulator 402 is moved to the semiconductor 406b through the semiconductor 406a. The semiconductor 406b is covered with any of the semiconductor 406c, the insulator 412, and the insulator 408; thus, outward diffusion of excess oxygen is less likely to occur. Therefore, by performing the fourth heat treatment at this time, defects (oxygen vacancies) in the semiconductor 406b can be efficiently reduced. Note that the fourth heat treatment may be performed at a temperature such that excess oxygen (oxygen) in the insulator 402 is diffused to the semiconductor 406b. For example, the description of the first heat treatment may be referred to. The fourth heat treatment is preferably performed at a temperature lower than that of the first heat treatment. The difference between the temperature of the first heat treatment and that of the fourth heat treatment is higher than or equal to 20° C. and lower than or equal to 150° C., preferably higher than or equal to 40° C. and lower than or equal to 100° C. Accordingly, superfluous release of excess oxygen (oxygen) from the insulator 402 can be inhibited. Note that in the case where the insulator 408 has a function of blocking oxygen, the semiconductor 406c and/or the insulator 412 does not necessarily have a function of blocking oxygen.

One or more of the first heat treatment, the second heat treatment, the third heat treatment, and the fourth heat treatment are not necessarily performed.

Next, the insulator 418 is deposited. The insulator 418 may be deposited by a sputtering method, a CVD method, an MBE method, a PLD method, an ALD method, or the like.

Through the above steps, the transistor 490 illustrated in FIGS. 14A and 14B can be fabricated.

### <Structure Example of Semiconductor Device>

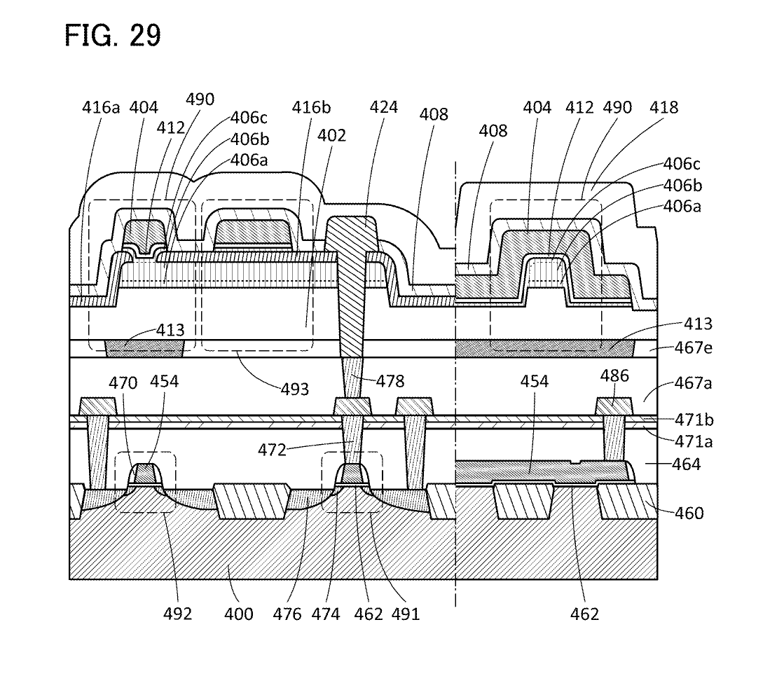

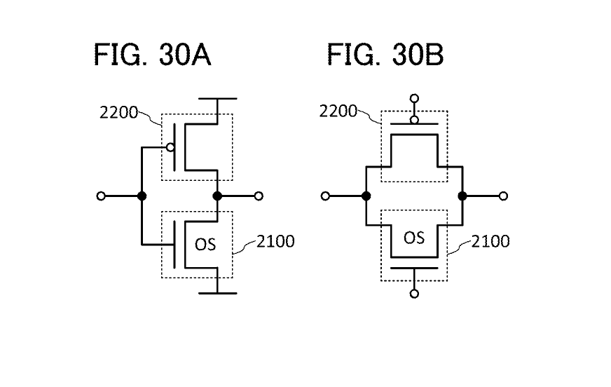

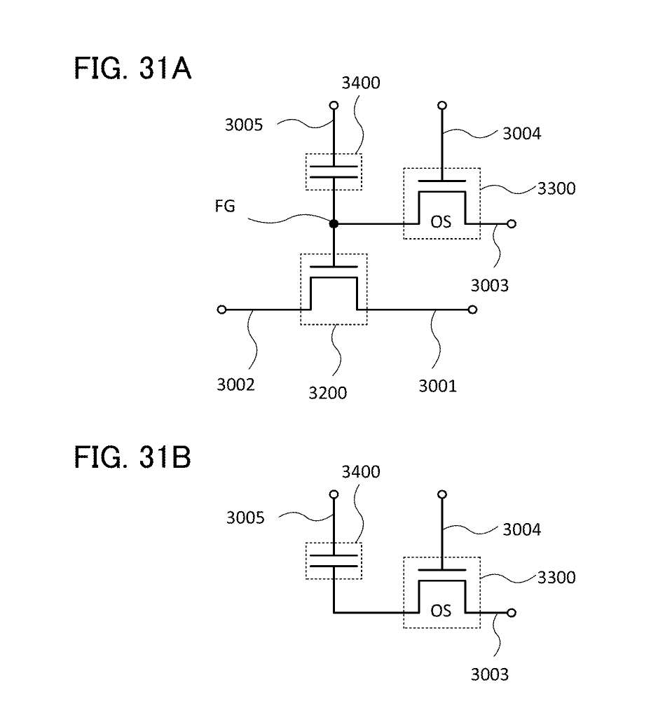

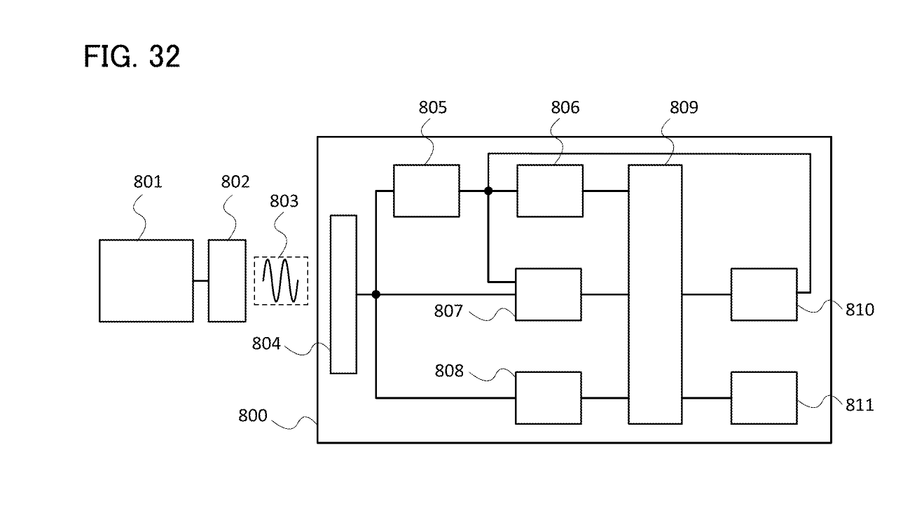

A semiconductor device illustrated in FIG. 29 includes the transistor 491, the transistor 490 using an oxide semiconductor, and a capacitor 493. The semiconductor device may further include the transistor 492. The structure of the semiconductor device illustrated in FIG. 29 can be used for, for example, the semiconductor device described in Embodiment 3 with reference to FIGS. 30A and 30B, FIGS. 31A and 31B, or FIG. 32.

Note that in this specification and the like, a transistor can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of a glass substrate include a barium borosilicate glass substrate, an aluminoborosilicate glass substrate, and soda lime glass substrate. Examples of the glass substrate are a barium borosilicate glass substrate, an aluminoborosilicate glass substrate, and a soda lime glass substrate. Examples of the flexible substrate, the attachment film, the base film, and the like are substrates of plastics typified by polyethylene terephthalate (PET), polyethylene naphthalate (PEN), polyether sulfone (PES), and polytetrafluoroethylene (PTFE). Another example is a synthetic resin such as acrylic. Furthermore, polypropylene, polyester, polyvinyl fluoride, and polyvinyl chloride can be given as examples. Furthermore, polyamide, polyimide, aramid, epoxy, an inorganic vapor a deposition film, and paper can be given as examples. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate, and the transistor may be provided directly on the flexible substrate. Alternatively, a separation layer may be provided between the substrate and the transistor. The separation layer can be used when part or the whole of a semiconductor device formed over the separation layer is separated from the substrate and transferred onto another substrate. In such a case, the transistor can be transferred to a substrate having low heat resistance or a flexible substrate as well. For the above separation layer, a stack including inorganic films, which are a tungsten film and a silicon oxide film, or an organic resin film of polyimide or the like formed over a substrate can be used, for example.

In other words, a transistor may be formed using one substrate, and then transferred to another substrate. Examples of a substrate to which a transistor is transferred include, in addition to the above substrate over which the transistor can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), and the like), a leather substrate, and a rubber substrate. When such a substrate is used, a transistor with excellent properties or a transistor with low power consumption can be formed, a device with high durability, high heat resistance can be provided, or reduction in weight or thickness can be achieved.

At least part of this embodiment can be implemented in combination with any of the embodiments described in this specification as appropriate.

### Embodiment 3

In this embodiment, the semiconductor device of one embodiment of the present invention, application examples thereof, and the like are described.

### <Semiconductor Device>

An example of the semiconductor device of one embodiment of the present invention is shown below.

A circuit diagram in FIG. 30A shows a configuration of a so-called CMOS circuit in which the p-channel transistor 2200 and the n-channel transistor 2100 are connected to each other in series and in which gates of them are connected to each other.

A circuit diagram in FIG. 30B shows a configuration in which sources of the transistors 2100 and 2200 are connected to each other and drains of the transistors 2100 and 2200 are connected to each other. With such a configuration, the transistors can function as a so-called analog switch.

For example, as the transistor 2100, the above-described transistor 490 or the like may be used. For example, as the transistor 2200, the above-described transistor 491 or the like may be used. An example of a semiconductor device (memory device) which can retain stored data even when not powered and which has an unlimited number of write cycles is shown in FIGS. 31A and 31B.

The semiconductor device illustrated in FIG. 31A includes a transistor 3200 using a first semiconductor, a transistor 3300 using a second semiconductor, and a capacitor 3400. Note that the transistor 490 or the like may be used as the transistor 3300. As the transistor 3200, the transistor 491 or the like may be used.

In the case where the transistor 3300 is a transistor using an oxide semiconductor, since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 31A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 31A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, whereby the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies in accordance with the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. On the other hand, in the case where the low-level charge is supplied to the node FG in writing, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell is read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 31B is different from the semiconductor device in FIG. 31A in that the transistor 3200 is not provided. Also in this case, writing and retaining operation of data can be performed in a manner similar to that of the semiconductor device in FIG. 31A.

Reading of data in the semiconductor device in FIG. 31B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies in accordance with the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁(=(C_{B}×V_{B0}+C×V₁)/(C_{B}+C)) is higher than the potential of the third wiring 3003 in the case of retaining the potential V₀(=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When a transistor using an oxide semiconductor and having an extremely low off-state current is used for the semiconductor device described above, the semiconductor device can retain stored data for a long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

In the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written in accordance with the state of the transistor (on or off), whereby high-speed operation can be easily achieved.

### <RF Tag>

An RF tag including the transistor or the memory device is described below with reference to FIG.

The RF tag of one embodiment of the present invention includes a memory circuit, stores data in the memory circuit, and transmits and receives data to/from the outside by using contactless means, for example, wireless communication. With these features, the RF tag can be used for an individual authentication system in which an object or the like is recognized by reading the individual information, for example. Note that the RF tag is required to have high reliability in order to be used for this purpose.

A configuration of the RF tag will be described with reference to FIG. 32. FIG. 32 is a block diagram illustrating a configuration example of the RF tag.

As shown in FIG. 32, an RF tag 800 includes an antenna 804 which receives a radio signal 803 which is transmitted from an antenna 802 connected to a communication device 801 (also referred to as an interrogator, a reader/writer, or the like). The RF tag 800 includes a rectifier circuit 805, a constant voltage circuit 806, a demodulation circuit 807, a modulation circuit 808, a logic circuit 809, a memory circuit 810, and a ROM 811. A semiconductor of a transistor having a rectifying function included in the demodulation circuit 807 may be a material which enables a reverse current to be low enough, for example, an oxide semiconductor. This can suppress the phenomenon of a rectifying function becoming weaker due to generation of a reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method in which a pair of coils is provided so as to face each other and communicates with each other by mutual induction, an electromagnetic induction method in which communication is performed using an induction field, and a radio wave method in which communication is performed using a radio wave. Any of these methods can be used in the RF tag 800.

Next, the structure of each circuit will be described. The antenna 804 exchanges the radio signal 803 with the antenna 802 which is connected to the communication device 801. The rectifier circuit 805 generates an input potential by rectification, for example, half-wave voltage doubler rectification of an input alternating signal generated by reception of a radio signal at the antenna 804 and smoothing of the rectified signal with a capacitor provided in a later stage in the rectifier circuit 805. Note that a limiter circuit may be provided on an input side or an output side of the rectifier circuit 805. The limiter circuit controls electric power so that electric power which is higher than or equal to certain electric power is not input to a circuit in a later stage if the amplitude of the input alternating signal is high and an internal generation voltage is high.

The constant voltage circuit 806 generates a stable power supply voltage from an input potential and supplies it to each circuit. Note that the constant voltage circuit 806 may include a reset signal generation circuit. The reset signal generation circuit is a circuit which generates a reset signal of the logic circuit 809 by utilizing rise of the stable power supply voltage.

The demodulation circuit 807 demodulates the input alternating signal by envelope detection and generates the demodulated signal. Furthermore, the modulation circuit 808 performs modulation in accordance with data to be output from the antenna 804.

The logic circuit 809 analyzes and processes the demodulated signal. The memory circuit 810 holds the input data and includes a row decoder, a column decoder, a memory region, and the like. Furthermore, the ROM 811 stores an identification number (ID) or the like and outputs it in accordance with processing.

Note that the decision whether each circuit described above is provided or not can be made as appropriate as needed.

Here, the above-described memory device can be used as the memory circuit 810. Since the memory device of one embodiment of the present invention can retain data even when not powered, the memory device is suitable for an RF tag. Furthermore, the memory device of one embodiment of the present invention needs power (voltage) needed for data writing lower than that needed in a conventional nonvolatile memory; thus, it is possible to prevent a difference between the maximum communication range in data reading and that in data writing. In addition, it is possible to suppress malfunction or incorrect writing which is caused by power shortage in data writing.

Since the memory device of one embodiment of the present invention can be used as a nonvolatile memory, it can also be used as the ROM 811. In this case, it is preferable that a manufacturer separately prepare a command for writing data to the ROM 811 so that a user cannot rewrite data freely. Since the manufacturer gives identification numbers before shipment and then starts shipment of products, instead of putting identification numbers to all the manufactured RF tags, it is possible to put identification numbers to only good products to be shipped. Thus, the identification numbers of the shipped products are in series and customer management corresponding to the shipped products is easily performed.

### <Application Examples of RF Tag>

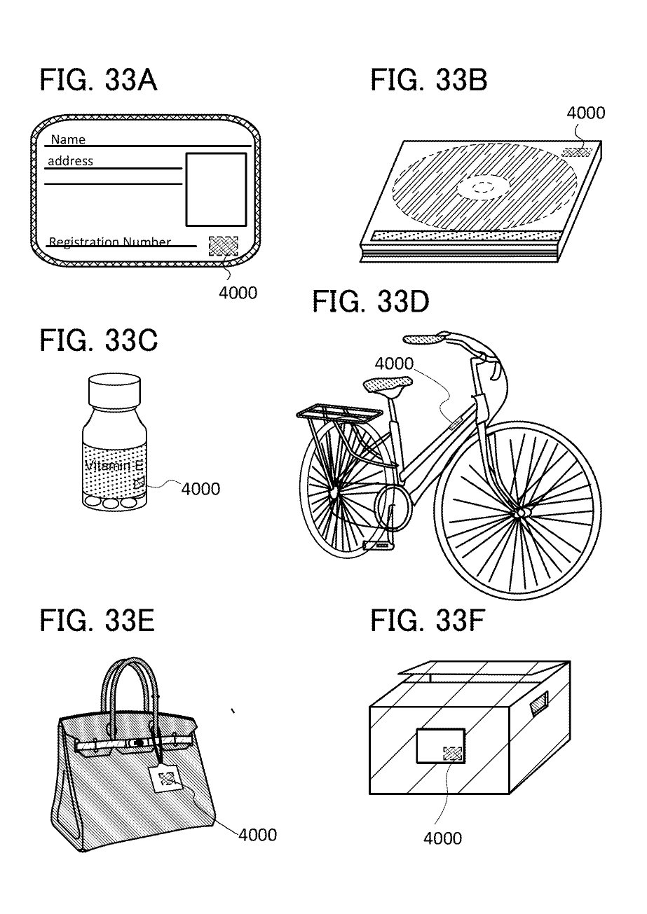

Application examples of the RF tag of one embodiment of the present invention are shown below with reference to FIGS. 33A to 33F. The RF tag is widely used and can be provided for, for example, products such as bills, coins, securities, bearer bonds, documents (e.g., driver's licenses or resident's cards, see FIG. 33A), packaging containers (e.g., wrapping paper or bottles, see FIG. 33C), recording media (e.g., DVDs or video tapes, see FIG. 33B), vehicles (e.g., bicycles, see FIG. 33D), personal belongings (e.g., bags or glasses), foods, plants, animals, human bodies, clothing, household goods, medical supplies such as medicine and chemicals, and electronic devices (e.g., liquid crystal display devices, EL display devices, television sets, or cellular phones), or tags on products (see FIGS. 33E and 33F).

An RF tag 4000 of one embodiment of the present invention is fixed on products by, for example, being attached to a surface thereof or being embedded therein. For example, the RF tag 4000 is fixed to each product by being embedded in paper of a book, or embedded in an organic resin of a package. The RF tag 4000 of one embodiment of the present invention is small, thin, and lightweight, so that the design of a product is not impaired even after the RF tag 4000 of one embodiment of the present invention is fixed thereto. Furthermore, bills, coins, securities, bearer bonds, documents, or the like can have identification functions by being provided with the RF tag 4000 of one embodiment of the present invention, and the identification functions can be utilized to prevent counterfeits. Moreover, the efficiency of a system such as an inspection system can be improved by providing the RF tag 4000 of one embodiment of the present invention for packaging containers, recording media, personal belongings, foods, clothing, household goods, electronic devices, or the like. Vehicles can also have higher security against theft or the like by being provided with the RF tag 4000 of one embodiment of the present invention.

As described above, the RF tag of one embodiment of the present invention can be used for the above-described purposes.

### <CPU>

A CPU including a semiconductor device such as any of the above-described transistors or the above-described memory device is described below.

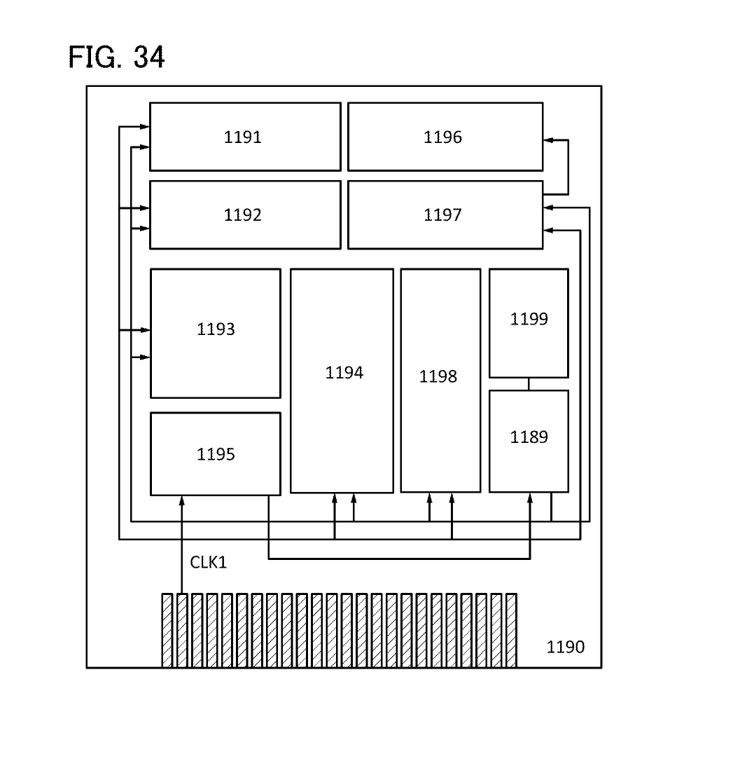

FIG. 34 is a block diagram illustrating a configuration example of a CPU including any of the above-described transistors as a component.

The CPU illustrated in FIG. 34 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and a ROM interface (ROM I/F) 1189. A semiconductor substrate, an SOI substrate, a glass substrate, or the like is used as the substrate 1190. The ROM 1199 and the ROM interface 1189 may be provided over a separate chip. Needless to say, the CPU in FIG. 34 is just an example in which the configuration has been simplified, and an actual CPU may have a variety of configurations in accordance with the application. For example, the CPU may have the following configuration: a structure including the CPU illustrated in FIG. 34 or an arithmetic circuit is considered as one core; a plurality of cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 34, a memory cell is provided in the register 1196. For the memory cell of the register 1196, any of the above-described transistors, the above-described memory device, or the like can be used.

In the CPU illustrated in FIG. 34, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

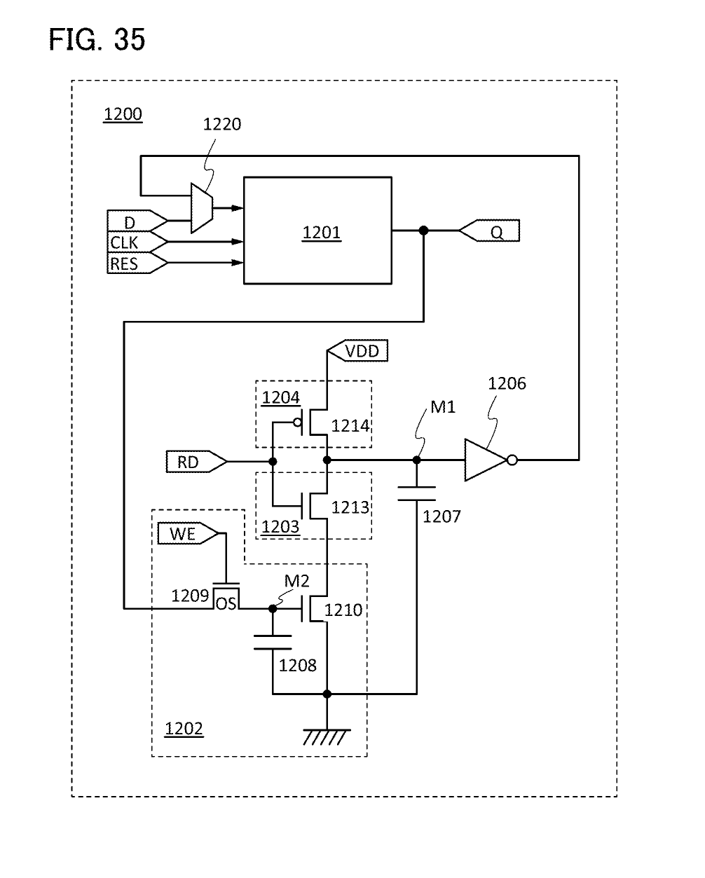

FIG. 35 is an example of a circuit diagram of a memory element 1200 that can be used as the register 1196. The memory element includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to a first gate (first gate electrode) of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 35 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 35, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 35, among the transistors used in the memory element 1200, the transistor 490 or the like may be used as the transistor 1209, for example. As the transistors other than the transistor 1209, the transistor 491, the transistor 492, or the like may be used, for example.

As the circuit 1201 in FIG. 35, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### CONFIGURATION EXAMPLE

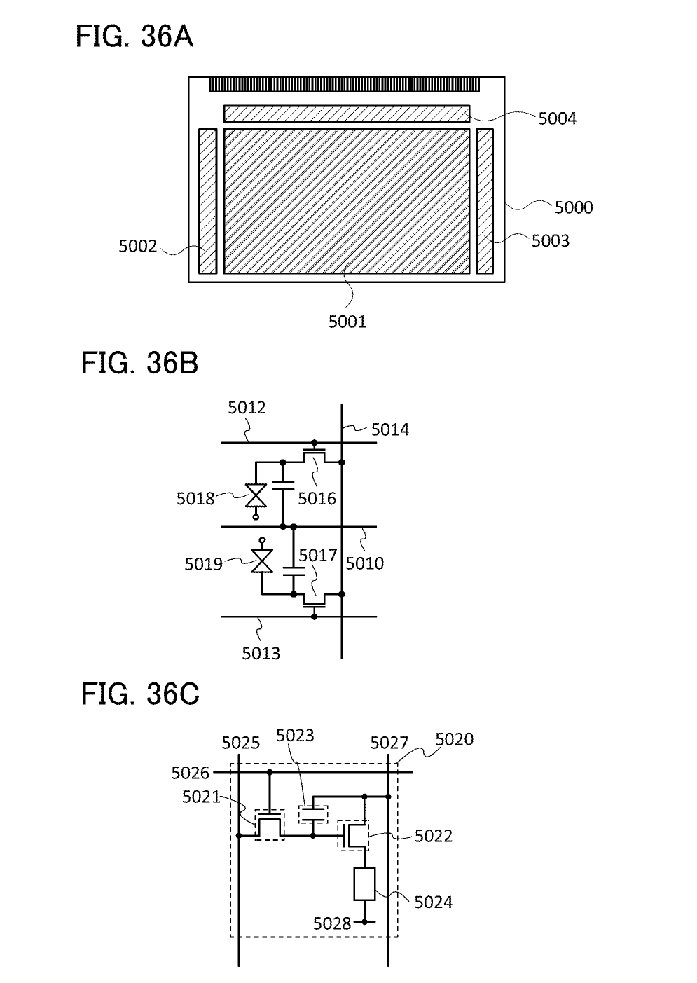

FIG. 36A is a top view of a display device of one embodiment of the present invention. FIG. 36B illustrates a pixel circuit where a liquid crystal element is used for a pixel of a display device of one embodiment of the present invention. FIG. 36C illustrates a pixel circuit where an organic EL element is used for a pixel of a display device of one embodiment of the present invention.

The transistor 490 or the like can be used as a transistor used for the pixel. Here, an example in which an n-channel transistor is used is shown. Note that a transistor manufactured through the same steps as the transistor used for the pixel may be used for a driver circuit. Thus, by using the above-described transistor for a pixel or a driver circuit, the display device can have high display quality and/or high reliability.

FIG. 36A illustrates an example of a top view of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Furthermore, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 36B illustrates an example of a circuit configuration of the pixel. Here, a pixel circuit which is applicable to a pixel of a VA liquid crystal display device, or the like is illustrated.

This pixel circuit can be used in a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A gate wiring 5012 of a transistor 5016 and a gate wiring 5013 of a transistor 5017 are separated so that different gate signals can be supplied thereto. In contrast, a source or drain electrode 5014 functioning as a data line is shared by the transistors 5016 and 5017. Any of the above-described transistors can be used as appropriate as each of the transistors 5016 and 5017. Thus, the liquid crystal display device can have high display quality and/or high reliability.

A first pixel electrode is electrically connected to the transistor 5016 and a second pixel electrode is electrically connected to the transistor 5017. The first pixel electrode and the second pixel electrode are separated. Shapes of the first pixel electrode and the second pixel electrode are not especially limited. For example, the first pixel electrode may have a V-like shape.

A gate electrode of the transistor 5016 is electrically connected to the gate wiring 5012, and a gate electrode of the transistor 5017 is electrically connected to the gate wiring 5013. When different gate signals are supplied to the gate wiring 5012 and the gate wiring 5013, operation timings of the transistor 5016 and the transistor 5017 can be varied. As a result, alignment of liquid crystals can be controlled.

Furthermore, a capacitor may be formed using a capacitor wiring 5010, a gate insulator functioning as a dielectric, and a capacitor electrode electrically connected to the first pixel electrode or the second pixel electrode.

The pixel structure is a multi-domain structure in which a first liquid crystal element 5018 and a second liquid crystal element 5019 are provided in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 36B. For example, a switch, a resistor, a capacitor, a transistor, a sensor, a logic circuit, or the like may be added to the pixel shown in FIG. 36B.

### [Organic EL Display Device]

FIG. 36C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 36C illustrates an example of a pixel circuit. Here, one pixel includes two n-channel transistors. Note that the transistor 490 or the like can be used as the n-channel transistor. Furthermore, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, the transistor 490 or the like can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply current to the light-emitting element 5024 in accordance with the video signal and perform analog grayscale driving.

Note that in the display device of one embodiment of the present invention, a pixel configuration is not limited to that shown in FIG. 36C. For example, a switch, a resistor, a capacitor, a sensor, a transistor, a logic circuit, or the like may be added to the pixel circuit shown in FIG. 36C.

In the case where the transistor 490 or the like is used for the circuit shown in FIGS. 36A to 36C, the source electrode (the first electrode) is electrically connected to the low potential side and the drain electrode (the second electrode) is electrically connected to the high potential side. Furthermore, the potential of the first gate electrode may be controlled by a control circuit or the like and the potential described above as an example, e.g., a potential lower than the potential applied to the source electrode, may be input to the second gate electrode.

In this specification and the like, a display element, a display device which is a device including a display element, a light-emitting element, and a light-emitting device which is a device including a light-emitting element can employ various modes or can include various elements. For example, the display element, display device, light-emitting element, or light-emitting device includes at least one of display elements using an EL element (e.g., an EL element including organic and inorganic materials, an organic EL element, or an inorganic EL element), an LED (e.g., a white LED, a red LED, a green LED, or a blue LED), a transistor (a transistor which emits light in accordance with current), an electron emitter, a liquid crystal element, electronic ink, an electrophoretic element, a grating light valve (GLV), a plasma display panel (PDP), a micro electro mechanical system (MEMS), a digital micromirror device (DMD), a digital micro shutter (DMS), an interferometric modulator display (IMOD) element, an electrowetting element, a piezoelectric ceramic display, or a carbon nanotube. Other than the above, display media whose contrast, luminance, reflectivity, transmittance, or the like is changed by electrical or magnetic effect may be included. Note that examples of a display device having an EL element include an EL display. Examples of a display device having an electron emitter include a field emission display (FED) and an SED-type flat panel display (SED: surface-conduction electron-emitter display). Examples of a display device having a liquid crystal element include a liquid crystal display (e.g., a transmissive liquid crystal display, a transflective liquid crystal display, a reflective liquid crystal display, a direct-view liquid crystal display, or a projection liquid crystal display). Examples of a display device having electronic ink or an electrophoretic element include electronic paper. Note that in the case of using an LED, graphene or graphite may be provided under an electrode or a nitride semiconductor of the LED. Graphene or graphite may be a multilayer film in which a plurality of layers are stacked. As described above, provision of graphene or graphite enables easy formation of a nitride semiconductor film thereover, such as an n-type GaN semiconductor layer including crystals. Furthermore, a p-type GaN semiconductor layer including crystals or the like can be provided thereover, and thus the LED can be formed. Note that an MN layer may be provided between the n-type GaN semiconductor layer including crystals and graphene or graphite. The GaN semiconductor layers included in the LED may be deposited by MOCVD. Note that when the graphene is provided, the GaN semiconductor layers included in the LED can also be formed by a sputtering method.

A coloring layer (also referred to as a color filter) may be used in order to obtain a full-color display device in which white light (W) for a backlight (e.g., an organic EL element, an inorganic EL element, an LED, or a fluorescent lamp) is used. As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using a self-luminous element such as an organic EL element or an inorganic EL element, elements may emit light of their respective colors R, G, B, Y, and W. By using a self-luminous element, power consumption can be further reduced as compared to the case of using the coloring layer in some cases.

### <Module>

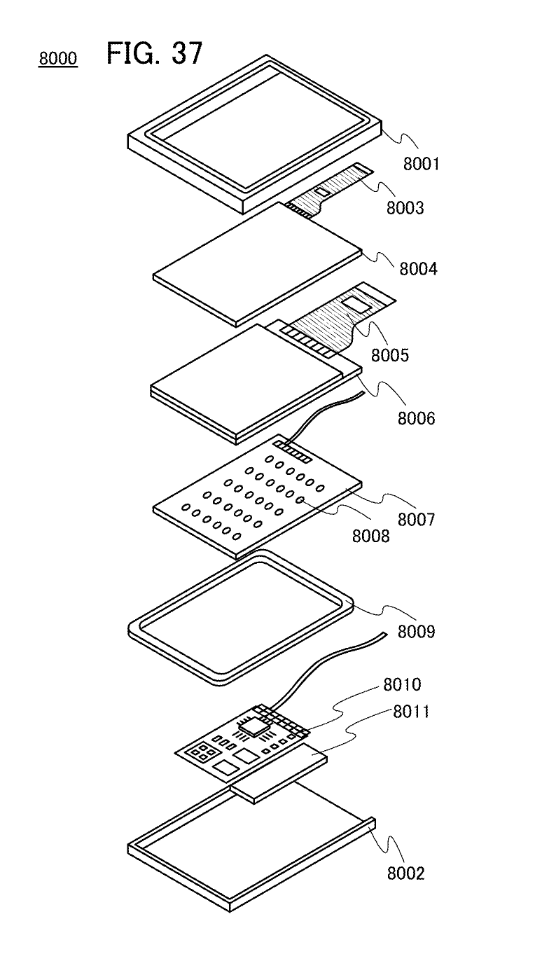

A display module using a semiconductor device of one embodiment of the present invention is described below with reference to FIG. 37.

In a display module 8000 in FIG. 37, a touch panel 8004 connected to an FPC 8003, a cell 8006 connected to an FPC 8005, a backlight unit 8007, a frame 8009, a printed board 8010, and a battery 8011 are provided between an upper cover 8001 and a lower cover 8002. Note that the backlight unit 8007, the battery 8011, the touch panel 8004, and the like are not provided in some cases.

The semiconductor device of one embodiment of the present invention can be used for the cell 8006, for example.

The shapes and sizes of the upper cover 8001 and the lower cover 8002 can be changed as appropriate in accordance with the sizes of the touch panel 8004 and the cell 8006.

The touch panel 8004 can be a resistive touch panel or a capacitive touch panel and may be formed to overlap with the cell 8006. A counter substrate (sealing substrate) of the cell 8006 can have a touch panel function. A photosensor may be provided in each pixel of the cell 8006 so that an optical touch panel is obtained. An electrode for a touch sensor may be provided in each pixel of the cell 8006 so that a capacitive touch panel is obtained.

The backlight unit 8007 includes a light source 8008. The light source 8008 may be provided at an end portion of the backlight unit 8007 and a light diffusing plate may be used.

The frame 8009 may protect the cell 8006 and also function as an electromagnetic shield for blocking electromagnetic waves generated by the operation of the printed board 8010. The frame 8009 may function as a radiator plate.

The printed board 8010 has a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 can be additionally provided with a member such as a polarizing plate, a retardation plate, or a prism sheet.

### <Electronic Device>

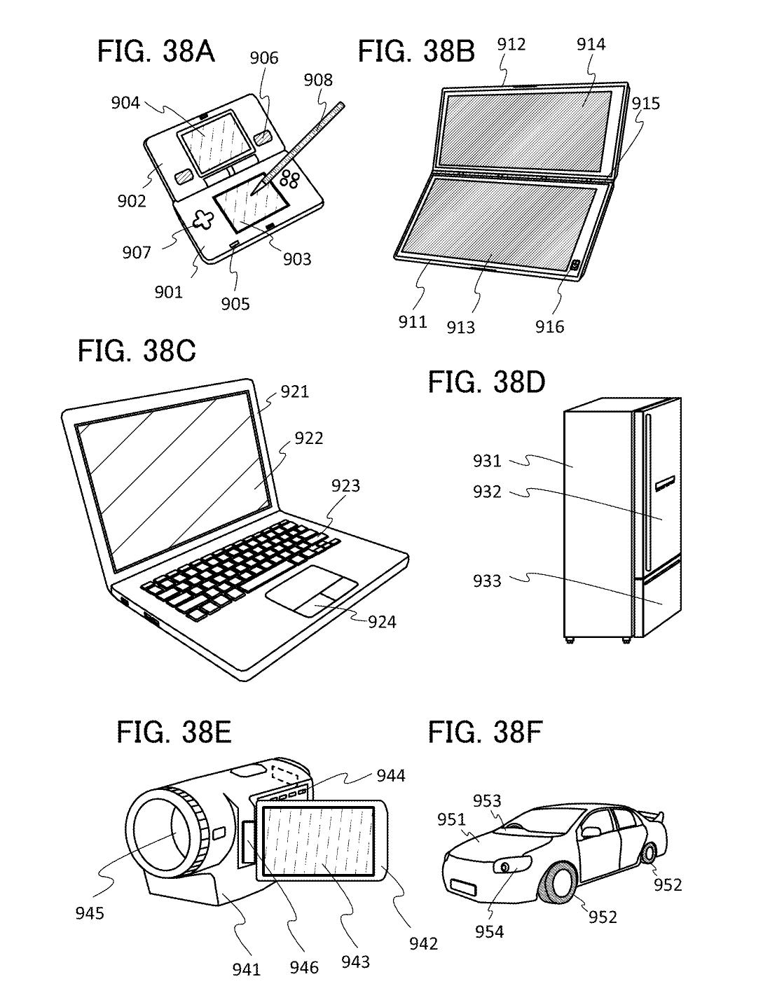

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data appliances, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 38A to 38F illustrate specific examples of these electronic devices.

FIG. 38A illustrates a portable game console including a housing 901, a housing 902, a display portion 903, a display portion 904, a microphone 905, a speaker 906, an operation key 907, a stylus 908, and the like. Although the portable game console in FIG. 38A has the two display portions 903 and 904, the number of display portions included in a portable game console is not limited to this.

FIG. 38B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched in accordance with the angle between the first housing 911 and the second housing 912 at the joint 915. A display device with a position input function may be used as at least one of the first display portion 913 and the second display portion 914. Note that the position input function can be added by providing a touch panel in a display device. Alternatively, the position input function can be added by provision of a photoelectric conversion element called a photosensor in a pixel portion of a display device.

FIG. 38C illustrates a laptop personal computer, which includes a housing 921, a display portion 922, a keyboard 923, a pointing device 924, and the like.

FIG. 38D illustrates the electric refrigerator-freezer including a housing 931, a refrigerator door 932, a freezer door 933, and the like.

FIG. 38E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 38F illustrates an automobile, a passenger car, or the like, which includes a car body 951, wheels 952, a dashboard 953, lights 954, and the like.

<Electronic Device with Curved Display Region or Curved Light-Emitting Region>

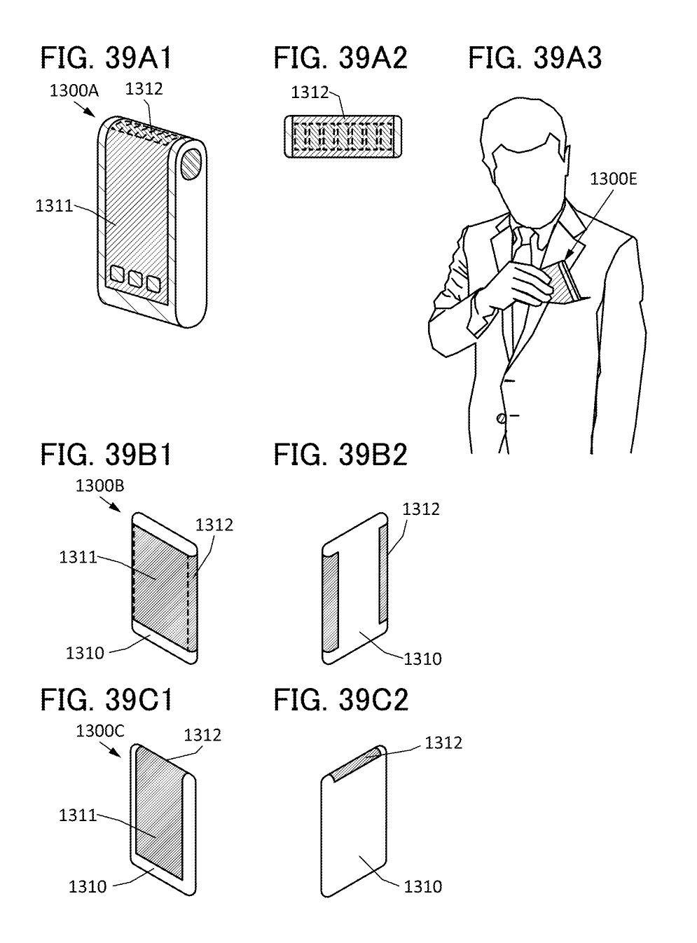

Electronic devices with a curved display region or a curved light-emitting region, which are embodiments of the present invention, are described below with reference to FIGS. 39A1 to 39C2. Here, information devices, in particular, portable information devices (portable devices) are described as examples of the electronic devices. The portable information devices include, for example, mobile phone devices (e.g., phablets and smartphones) and tablet terminals (slate PCs).

FIG. 39A1 is a perspective view illustrating an external shape of a portable device 1300A. FIG. 39A2 is a top view illustrating the portable device 1300A. FIG. 39A3 illustrates a usage state of the portable device 1300A.

FIGS. 39B1 and 39B2 are perspective views illustrating the outward form of a portable device 1300B.

FIGS. 39C1 and 39C2 are perspective views illustrating the outward form of a portable device 1300C.

### <Portable Device>

The portable device 1300A has one or more functions of a telephone, email creating and reading, a notebook, information browsing, and the like.

A display portion of the portable device 1300A is provided along plural surfaces. For example, the display portion may be provided by placing a flexible display device along the inside of a housing. Thus, text data, image data, or the like can be displayed on a first region 1311 and/or a second region 1312.

For example, images used for three operations can be displayed on the first region 1311 (see FIG. 39A1). Furthermore, text data and the like can be displayed on the second region 1312 as indicated by dashed rectangles in the drawing (see FIG. 39A2).

In the case where the second region 1312 is on the upper portion of the portable device 1300A, a user can easily see text data or image data displayed on the second region 1312 of the portable device 1300A while the portable device 1300A is placed in a breast pocket of the user's clothes (see FIG. 39A3). For example, the user can see the phone number, name, and the like of the caller of an incoming call, from above the portable device 1300A.

The portable device 1300A may include an input device or the like between the display device and the housing, in the display device, or over the housing. As the input device, for example, a touch sensor, a light sensor, or an ultrasonic sensor may be used. In the case where the input device is provided between the display device and the housing or over the housing, a touch panel may be, for example, a matrix switch type, a resistive type, an ultrasonic surface acoustic wave type, an infrared type, electromagnetic induction type, or an electrostatic capacitance type. In the case where the input device is provided in the display device, an in-cell sensor, an on-cell sensor, or the like may be used.

Note that the portable device 1300A can be provided with a vibration sensor or the like and a memory device that stores a program for shifting a mode into an incoming call rejection mode based on vibration sensed by the vibration sensor or the like. Thus, the user can shift the mode into the incoming call rejection mode by tapping the portable device 1300A over his/her clothes to apply vibration.

The portable device 1300B includes a display portion including the first region 1311 and the second region 1312 and a housing 1310 that supports the display portion.

The housing 1310 has a plurality of bend portions, and the longest bend portion in the housing 1310 is between the first region 1311 and the second region 1312.

The portable device 1300B can be used with the second region 1312 provided along the longest bend portion facing sideward.

The portable device 1300C includes a display portion including the first region 1311 and the second region 1312 and the housing 1310 that supports the display portion.

The housing 1310 has a plurality of bend portions, and the second longest bend portion in the housing 1310 is between the first region 1311 and the second region 1312.

The portable device 1300C can be used with the second region 1312 facing upward.

At least part of this embodiment can be implemented in combination with any of the embodiments described in this specification as appropriate.

### Example 1

In this example, results on evaluation of a polishing step of a conductor by a CMP method are described.

### <Fabrication of Samples>

Next, a method of fabricating samples is described. A silicon wafer was used as the substrate 401. Next, as the insulator 465, a silicon oxide film was formed to a thickness of 100 nm over the silicon wafer used as the substrate 401 by a CVD method. The deposition conditions of the silicon oxide were as follows: the substrate temperature was 300° C.; the pressure was 100 Pa; a 300 W RF power source (frequency: 27 MHz) was used as a power source; tetraethyl ortho silicate (TEOS) and oxygen were used as deposition gases; and the flow rates of TEOS and oxygen were 15 sccm and 750 sccm, respectively.

Next, the substrate was cleaned, and then the insulators 471a and 471b were formed such that the total thickness thereof was approximately 40 nm. First, as the insulator 471a, an aluminum oxide film was formed over the silicon oxide film by an ALD method. A solvent containing trimethylaluminum was vaporized and used. As oxidizers, ozone and oxygen were used. The temperature was set to 250° C.

Next, the substrate was cleaned, and then an aluminum oxide film was formed as the insulator 471b by a sputtering method. The deposition conditions of the aluminum oxide film were as follows: an aluminum oxide target was used; the substrate temperature was 250° C.; a 2.5 kW RF power source was used as a power source; oxygen was used as a deposition gas; and the oxygen flow rate was 50 sccm. The pressure was 0.4 Pa, and the distance between the substrate and the target was 60 mm.

Next, as the conductor 469, a 5-nm-thick titanium nitride film formed by an ALD method and a 150-nm-thick tungsten film formed by a CVD method were stacked. As deposition gases for the titanium nitride film, titanium chloride and ammonia were used. As a deposition gas for the tungsten film, tungsten hexafluoride or the like was used.

Next, the tungsten film and the titanium nitride film were polished by a CMP method and removed. The polishing conditions were as follows. As a polishing cloth, IC1000/SUBA (registered trademark) using polyurethane foam, which is produced by Nitta Haas Incorporated, was used. As slurry, W7300-B21 using colloidal silica, which is produced by Cabot Microelectronics, was used. The slurry flow rate was 0.2 L/min, and the polishing pressure was 0.02 MPa. The numbers of rotations of a polishing head and a table were 39 rpm and 35 rpm, respectively. The treatment was performed while the object to be processed was attached to the polishing head and the polishing cloth was attached to the table. The above polishing conditions were used. The polishing time was two minutes.

The polishing is followed by cleaning. Three steps were performed as the cleaning. In the first cleaning step, a sample was soaked in ozone water for 90 seconds. Next, in the second cleaning step, scrub cleaning was performed with a brush for one minute and then cleaning with pure water was performed. Next, in the third cleaning step, spin cleaning was performed as follows: treatment was performed with ozone water for 15 seconds, with 0.5 weight % hydrofluoric acid for 10 seconds, with ozone water for 6 seconds, with 0.5 weight % hydrofluoric acid for 10 seconds, and with ozone water for 99 seconds in this order; and finally drying was performed.

Through the above steps, the sample was fabricated. The fabricated sample is referred to as sample A.

### <Observation of Samples>

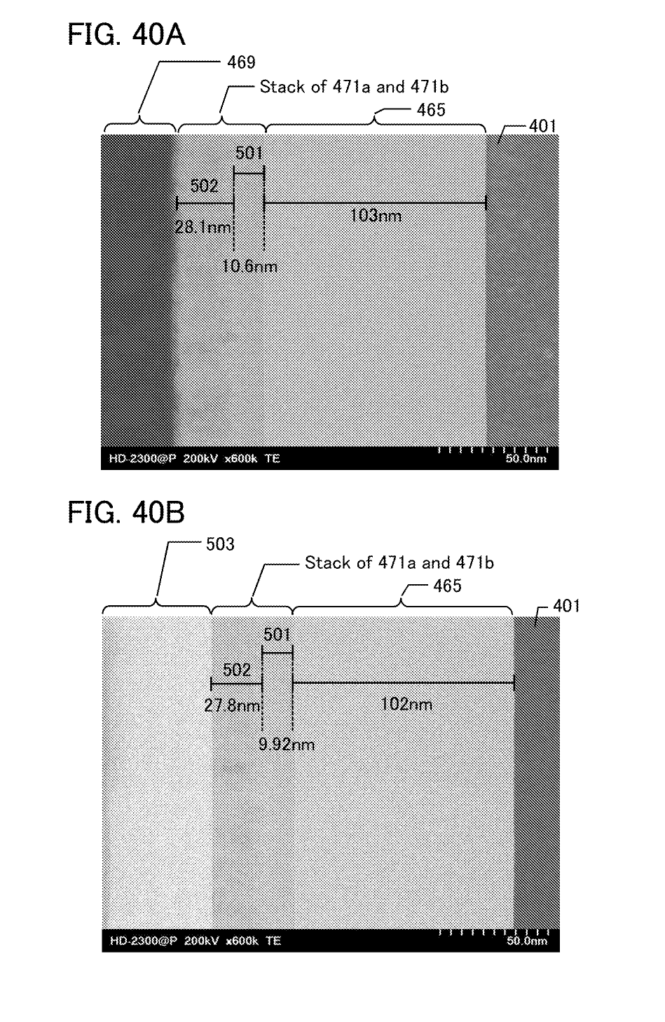

The fabricated sample was observed by scanning transmission electron microscopy (STEM). As a STEM apparatus, HD-2300 produced by Hitachi High-Technologies Corporation was used. The accelerating voltage was 200 kV, and the observation was performed at a magnification of 600,000 times. The observation result is shown in FIG. 40B. Furthermore, a sample in the state before the polishing step, i.e., after the formation of the tungsten film, was fabricated as sample B. Sample B was observed under conditions similar to those for sample A. The observation result is shown in FIG. 40A. To make the observation easier, a carbon film 503 was evaporated on the insulator 471b, as illustrated in FIG. 40B. As illustrated in FIGS. 40A and 40B, a layer 502 having crystallinity and a layer 501 in which a crystal was not clearly observed were observed. Thus, the layer 501 might have no clear grain boundaries. Further, the layer 501 might be amorphous, for example. In FIG. 40A, the thicknesses of the layer 502, the layer 501, and the insulator 465 are 28.1 nm, 10.6 nm, and 103 nm, respectively. In FIG. 40B, the thicknesses of the layer 502, the layer 501, and the insulator 465 are 27.8 nm, 9.92 nm, and 102 nm, respectively. Comparison between FIGS. 40A and 40B reveals that both the layers 501 and 502 did not decrease in thickness even after the polishing, and during the polishing step of the tungsten film and the titanium nitride film, the insulator 471b was hardly polished and functioned as a good stopper film.

### Example 2

In this example, the densities of the insulators used in Example 1 (i.e., aluminum oxide formed by the ALD method (hereinafter, “an ALD-AlOx film”) and aluminum oxide formed by the sputtering method (hereinafter, “a sp-AlOx film”)) and the polishing rates thereof in the case of using a CMP method are described.

### <Polishing Rate Evaluation>

First, the polishing rates of an ALD-AlOx film, a sp-AlOx film, and a tungsten film in the case of using a CMP method were evaluated.

The ALD-AlOx film was deposited to a thickness of approximately 150 nm over a silicon wafer. The deposition conditions were similar to those of sample A and sample B which are described in Example 1. The fabricated sample is referred to as sample C-1.

The sp-AlOx film was deposited to a thickness of approximately 150 nm over a silicon wafer. The deposition was performed under conditions described below. An aluminum oxide target was used; the substrate temperature was 250° C.; a 2.5 kW RF power source was used as a power source; oxygen and argon were used as deposition gases; and the flow rates of oxygen and argon were each 25 sccm. The pressure was 0.4 Pa, and the distance between the substrate and the target was 60 mm. The fabricated sample is referred to as sample C-2.

The tungsten film was formed to a thickness of approximately 150 nm over a silicon wafer. The deposition conditions were similar to those of sample A and sample B which are described in Example 1. The fabricated sample is referred to as sample C-3.

Next, samples C-1 to C-3 were each polished by a CMP method. The conditions for the CMP were the same as those in Example 1. The polishing times of sample C-1, sample C-2, and sample C-3 were one minute, one minute, and 30 seconds, respectively.

Next, cleaning was performed. The same cleaning treatment as that in the first to third steps described in Example 1 was performed.

The thicknesses of the films were measured with an optical interference type film thickness measuring device before and after the polishing. Next, the polishing rates were calculated from the measured thicknesses. The obtained polishing rates of sample C-1, sample C-2, and sample C-3 were 30 nm/min, 3 nm/min, and 97 nm/min, respectively.

The stack of the titanium nitride film and the tungsten film were used as the conductor 469 in Example 1. The tungsten film is thicker than the titanium nitride film, and the polishing rate of the conductor 469 is presumed to correspond to the polishing rate of the tungsten film.

The polishing rate of the ALD-AlOx film (sample C-1) was approximately one third of the polishing rate of the tungsten film (sample C-3). The polishing rate of the sp-AlOx film (sample C-2) was approximately one thirtieth of the polishing rate of the tungsten film. The polishing rate of the sp-AlOx film was low probably because its density is high as described later. Furthermore, slurry used for polishing of tungsten is acidic in many cases, and the sp-AlOx film might be highly resistant to, for example, an acidic solution.

The ALD-AlOx film is aluminum oxide in which no clear crystals are observed by TEM observation, as described in Example 1. Since the insulator 471b (the sp-AlOx film), the polishing rate of which was sufficiently lower than that of the tungsten film, was provided over the insulator 471a (the ALD-AlOx film), the insulator 471a was uniformly provided over the insulator 465 without being eliminated in the polishing step of the conductor 469, as shown in FIGS. 40A and 40B in Example 1.

### <Film Density Evaluation>

Next, the film densities of an ALD-AlOx film and a sp-AlOx film were evaluated.

First, a 100-nm-thick silicon oxide film was formed on a silicon wafer by thermal oxidation. Next, the ALD-AlOx film or the sp-AlOx film was formed to a thickness of 100 nm over the silicon oxide film.

The deposition conditions of the ALD-AlOx film were similar to those of sample C-1. The sample in which the ALD-AlOx film was deposited is referred to as sample D-1.

The deposition conditions of the sp-AlOx film were similar to those of sample C-2. The sample in which the sp-AlOx film was deposited is referred to as sample D-2.

Next, the film densities were evaluated by an X-ray reflectmetry (XRR) analysis method. The film density of sample D-1 was 3.1 g/cm³. The film density of sample D-2 was 3.6 g/cm³.

<Etching Rate Evaluation with Hydrofluoric Acid>

Next, a sample similar to the samples used for the evaluation of the polishing rates was fabricated and cleaned as in the first to third steps described in Example 1. The etching quantities of an ALD-ALOx film and a sp-AlOx film were evaluated, and found to be 11 nm and approximately 1 nm, respectively. In the cleaning, treatment was performed with 0.5 weight % hydrofluoric acid for 20 seconds in total. The ALD-ALOx film might be etched with hydrofluoric acid, for example, at a higher rate than the sp-AlOx film. The ALD-ALOx film might be etched more easily by cleaning with ozone water and hydrofluoric acid in combination, for example.

### REFERENCE NUMERALS

400: semiconductor substrate, 401: substrate, 402: insulator, 404: conductor, 406: semiconductor, 406a: semiconductor, 406b: semiconductor, 406c: semiconductor, 408: insulator, 412: insulator, 413: conductor, 413b: conductor, 416: conductor, 416a: conductor, 416b: conductor, 417: conductor, 418: insulator, 419: insulator, 423a: low-resistance region, 423b: low-resistance region, 424: conductor, 426: mask, 426a: conductor, 426b: conductor, 436a: semiconductor, 436b: semiconductor, 452: insulator region, 454: conductor, 460: insulator, 462: insulator, 464: insulator, 465: insulator, 467a: insulator, 467c: insulator, 469: conductor, 470: insulator, 471a: insulator, 471b: insulator, 472: conductor, 473: conductor, 474: region, 476: region, 478: conductor, 479: conductor, 480: conductor, 481a: insulator, 481b: insulator, 482a: insulator, 482b: insulator, 485: conductor, 486: conductor, 487: conductor, 488: wiring layer, 489: wiring layer, 490: transistor, 491: transistor, 492: transistor, 493: capacitor, 501: layer, 502: layer, 503: carbon film, 604: conductor, 606a: semiconductor, 606b: semiconductor, 606c: semiconductor, 612: insulator, 613: conductor, 616a: conductor, 616b: conductor, 618: insulator, 620: insulator, 800: RF tag, 801: communication device, 802: antenna, 803: radio signal, 804: antenna, 805: rectifier circuit, 806: constant voltage circuit, 807: demodulation circuit, 808: modulation circuit, 809: logic circuit, 810: memory circuit, 811: ROM, 901: housing, 902: housing, 903: display portion, 904: display portion, 905: microphone, 906: speaker, 907: operation key, 908: stylus, 911: housing, 912: housing, 913: display portion, 914: display portion, 915: joint, 916: operation key, 921: housing, 922: display portion, 923: keyboard, 924: pointing device, 931: housing, 932: refrigerator door, 933: freezer door, 941: housing, 942: housing, 943: display portion, 944: operation key, 945: lens, 946: joint, 951: car body, 952: wheel, 953: dashboard, 954: light, 1189: ROM interface, 1190: substrate, 1191: ALU, 1192: ALU controller, 1193: instruction decoder, 1194: interrupt: controller, 1195: timing controller, 1196: register, 1197: register controller, 1198: bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 1300A: portable device, 1300B: portable device, 1300C: portable device, 1310: housing, 1311: region, 1312: region, 2100: transistor, 2200: transistor, 3001: wiring, 3002: wiring, 3003: wiring, 3004: wiring, 3005: wiring, 3200: transistor, 3300: transistor, 3400: capacitor, 4000: RF tag, 5000: substrate, 5001: pixel portion, 5002: scan line driver circuit, 5003: scan line driver circuit, 5004: signal line driver circuit, 5010: capacitor wiring, 5012: gate wiring, 5013: gate wiring, 5014: drain electrode, 5016: transistor, 5017: transistor, 5018: liquid crystal element, 5019: liquid crystal element, 5020: pixel, 5021: switching transistor, 5022: driver transistor, 5023: capacitor, 5024: light-emitting element, 5025: signal line, 5026: scan line, 5027: power supply line, 5028: common electrode, 8000: display module, 8001: upper cover, 8002: lower cover, 8003: FPC, 8004: touch panel, 8005: FPC, 8006: cell, 8007: backlight unit, 8008: light source, 8009: frame, 8010: printed board, 8011: battery.

This application is based on Japanese Patent Application serial no. 2014-156746 filed with the Japan Patent Office on Jul. 31, 2014, the entire contents of which are hereby incorporated by reference.

1. A method of manufacturing a semiconductor device, comprising the steps of:
forming a first conductor over a substrate;
forming a first insulator over the first conductor;
forming a second insulator comprising aluminum oxide over the first insulator;
forming a third insulator in contact with a top surface of the second insulator;
providing, in the first insulator, the second insulator, and the third insulator, an opening portion reaching the first conductor;
forming a second conductor over the third insulator and in the opening portion;
forming a third conductor in the opening portion by removing part of the second conductor over the third insulator so that an upper surface of the third conductor is parallel to a bottom surface of the substrate; and
forming a first transistor comprising an oxide semiconductor over the third insulator.

2. A method of manufacturing a semiconductor device, comprising the steps of:
forming a first transistor comprising an oxide semiconductor over a substrate;
forming a first insulator over the first transistor;
forming a second insulator comprising aluminum oxide over the first insulator;
forming a third insulator in contact with a top surface of the second insulator;
providing an opening portion in the first insulator, the second insulator, and the third insulator;
forming a second conductor over the third insulator and in the opening portion;
forming a third conductor in the opening portion by removing part of the second conductor over the third insulator so that an upper surface of the third conductor is parallel to a bottom surface of the substrate; and
forming a fourth conductor over the third insulator.

3. A method of manufacturing a semiconductor device, comprising the steps of:
forming a second transistor over a substrate;
forming a first insulator over the second transistor;
forming a second insulator comprising aluminum oxide over the first insulator;
forming a third insulator in contact with a top surface of the second insulator;
providing an opening portion in the first insulator, the second insulator, and the third insulator;
forming a second conductor over the third insulator and in the opening portion;
forming a third conductor in the opening portion by removing part of the second conductor over the third insulator so that an upper surface of the third conductor is parallel to a bottom surface of the substrate; and
forming a first transistor comprising an oxide semiconductor over the third insulator.

4. The method of manufacturing a semiconductor device, according to claim 3,
wherein the second transistor comprises silicon.

5. The method of manufacturing a semiconductor device, according to claim 1,
wherein the third insulator comprises aluminum oxide, and
wherein a density of the third insulator is higher than a density of the second insulator.

6. The method of manufacturing a semiconductor device, according to claim 1,
wherein the third insulator comprises aluminum oxide, and
wherein the third insulator comprises crystallinity.

7. The method of manufacturing a semiconductor device, according to claim 1,
wherein the third insulator comprises aluminum oxide,
wherein the third insulator comprises crystallinity, and
wherein the second insulator comprises an amorphous structure.

8. The method of manufacturing a semiconductor device, according to claim 1,
wherein a density of the second insulator is less than 3.2 g/cm³.

9. The method of manufacturing a semiconductor device, according to claim 1,
wherein the third insulator comprises silicon oxide.

10. The method of manufacturing a semiconductor device, according to claim 1,
wherein a chemical mechanical polishing method is used for the removal of the second conductor over the third insulator.

11. The method of manufacturing a semiconductor device, according to claim 2,
wherein the third insulator comprises aluminum oxide, and
wherein a density of the third insulator is higher than a density of the second insulator.

12. The method of manufacturing a semiconductor device, according to claim 2,
wherein the third insulator comprises aluminum oxide, and
wherein the third insulator comprises crystallinity.

13. The method of manufacturing a semiconductor device, according to claim 2,
wherein the third insulator comprises aluminum oxide,
wherein the third insulator comprises crystallinity, and
wherein the second insulator comprises an amorphous structure.

14. The method of manufacturing a semiconductor device, according to claim 2,
wherein a density of the second insulator is less than 3.2 g/cm³.

15. The method of manufacturing a semiconductor device, according to claim 2,
wherein the third insulator comprises silicon oxide.

16. The method of manufacturing a semiconductor device, according to claim 3,
wherein the third insulator comprises aluminum oxide, and
wherein a density of the third insulator is higher than a density of the second insulator.

17. The method of manufacturing a semiconductor device, according to claim 3,
wherein the third insulator comprises aluminum oxide, and
wherein the third insulator comprises crystallinity.

18. The method of manufacturing a semiconductor device, according to claim 3,
wherein the third insulator comprises aluminum oxide,
wherein the third insulator comprises crystallinity, and
wherein the second insulator comprises an amorphous structure.

19. The method of manufacturing a semiconductor device, according to claim 3,
wherein the third insulator comprises silicon oxide.
